(19) United States
(12) Patent Application Publication
(10) Pub. No.: US 2007/0254558 A1
(43) Pub. Date: Nov. 1, 2007

(54) Polishing Apparatus and Polishing Method

(76) Inventors: Masako Kodera, Tokyo (JP); Yoshihiro Mochizuki, Fujisawa-shi (JP); Akira Fukuda, Fujisawa-shi (JP); Akira Kodera, Fujisawa-shi (JP); Hirokuni Hiyama, Fujisawa-shi (JP); Manabu Tsujimura, Tokyo (JP); Kazuto Hirokawa, Tokyo (JP); Akira Fukunaga, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/661,141

(22) PCT Filed: Aug. 26, 2005
(86) PCT No.: PCT/JP05/16063

§ 371 Date: May 3, 2007

(30) Foreign Application Priority Data
Aug. 27, 2004 (JP) 2004-249113
Sep. 14, 2004 (JP) 2004-267379
Dec. 27, 2004 (JP) 2004-377566
Jan. 31, 2005 (JP) 2005-024182

(51) Int. Cl. B24B 37/04; H01L 21/00

(52) U.S. Cl. 451/28; 451/64

(57) ABSTRACT

A polishing apparatus (30) has a polishing surface (32), a top ring (36) for holding a wafer (W), motors (46, 56) to move the polishing surface (32) and the wafer (W) relative to each other at a relative speed, and a vertical movement mechanism (54) to press the wafer (W) against the polishing surface (32) under a pressing pressure. The polishing apparatus (30) also has a controller (44) to adjust a polishing condition in a non-Preston range in which a polishing rate is not proportional to a product of the pressing pressure and the relative speed. The polishing apparatus (30) can simultaneously achieve uniform supply of a chemical liquid to a surface of the wafer (W) and a uniform polishing rate within the surface of the wafer (W).

### TECHNICAL FIELD

The present invention relates to a polishing apparatus and a polishing method, and more particularly to a polishing apparatus and a polishing method for polishing and planarizing a substrate such as a semiconductor wafer having an insulating film such as a low-k film and metal interconnections such as copper interconnections embedded in the insulating film.

### BACKGROUND ART

From the viewpoints of easy processing and productivity, aluminum or aluminum alloy is generally employed as an interconnection material for forming interconnection circuits on a semiconductor substrate. As semiconductor devices have been required in recent years to have finer interconnections capable of processing at a higher speed, there has been a significant trend that copper is employed as an interconnection material instead of aluminum or aluminum alloy. Since copper has an electric resistivity of 1.72 μΩcm, which is about 40% lower than that of aluminum, copper is effective in preventing signal delays. Additionally, copper has much higher resistance to electromigration than aluminum. Electromigration is a phenomenon in which atoms are moved by a flowing current so as to cause breakage of interconnections.

Copper is readily diffused into an adjacent insulating material. Accordingly, copper needs a diffusion prevention film to prevent diffusion of copper. In a case of copper interconnections, a diffusion prevention film is generally referred to as a barrier metal (BM). A dual damascene process is employed to form copper interconnections. Specifically, interconnection grooves or via holes are formed in an upper surface of an insulating material. A barrier metal (barrier material) is formed (deposited) on surfaces of the interconnection grooves or via holes. Copper is filled as an interconnection material in the interconnection grooves or via holes. Then, excessive metal is removed by a chemical mechanical polishing method (CMP method).

It is desired that a material having a low permittivity which prevents leakage of a current and is unlikely to form an excessive circuit resulting from a device structure be used as an insulating material adjacent to an interconnection material for enhanced speed. A low-k film or an ultra low-k film (ULK) has attracted attention to be used as a material having a low permittivity. Specifically, a SiO₂ film is generally used as an insulating material in a conventional device having aluminum interconnections. The relative permittivity of SiO₂ is 4.1. Accordingly, it is desired to use an insulating film having a relative permittivity lower than that of SiO₂ in a device having copper interconnections. Generally, a low-k film has a relative permittivity of 3.0 or less.

Inorganic materials and organic materials have been developed as materials having a low permittivity. Such inorganic materials include FSG based on SiOF, Black Diamond™ (Applied Materials, Inc.) based on SiOC, and Aurora™ (ASM International). Such organic materials include SiLK™ (Dow Chemical Company). Further, porous materials are considered to be used for reducing permittivity.

A dual damascene process to form a copper interconnection in a semiconductor wafer W will be described with reference to FIGS. 1A through 1F. First, as shown in FIG. 1A, a conductive layer 12 is deposited on a lower layer 10 of an interconnection, and an insulating film (insulating material) 14 such as an oxide film of SiO₂ or a low-k film (ULK film) of SiF, SiOH, porous silica, or the like is deposited on the conductive layer 12. Next, as shown in FIG. 1B, lithography and etching such as RIE are performed with a resist 16 to thereby form an interconnection recess (interconnection pattern) 18 such as an interconnection groove or a via hole in the insulating film 14. Thereafter, as shown in FIG. 1C, the resist 16 is removed, and the semiconductor wafer W is cleaned.

As shown in FIG. 1D, a barrier metal (barrier material) 20 is deposited as a diffusion prevention film, which serves to prevent copper from being diffused into silicon, on surfaces of the interconnection recess 18 by sputtering or the like. As shown in FIG. 1E, electrolytic plating or electroless plating is conducted to fill the entire interconnection recess 18 with copper. Thus, a copper film 22 is filled as an interconnection material in the interconnection recess 18 and also deposited on the barrier metal 20. Then, the copper film 22 and the barrier metal 20 on the insulating film 14 are removed by chemical mechanical polishing (CMP) so that a surface of the copper film 22 in the interconnection recess 18 is substantially on the same plane as a surface of the insulating film 14. Thus, as shown in FIG. 1F, an interconnection made of copper (copper interconnections) 24 is formed in the semiconductor wafer W.

As described above, a low-k material, which has a low mechanical strength, has recently been used as the insulating film 14. Accordingly, a process pressure cannot be made high during CMP. Thus, polishing should be conducted with a low process pressure. However, when a wafer is polished with a low process pressure, it is difficult to supply a chemical liquid (slurry) uniformly to an entire surface of the wafer and maintain a uniform polishing rate within the surface of the wafer at the same time.

Large-scale integrated circuits are required to have improved performance. Accordingly, multilayer structures and narrowed structures of metal interconnections formed on a semiconductor wafer have been developed in recent years. Particularly, narrowed structures, in which intervals between metal interconnections are reduced, are considered to contribute to formation of sophisticated integrated circuits because the narrowed structures can shorten paths to transmit signals and enhance a level of integration. However, when intervals between metal interconnections become smaller, electric capacity between adjacent interconnections is problematically increased. Specifically, signals are transmitted while charging and discharging electric capacity between interconnections. Thus, an increased electric capacity between interconnections may cause delay of signal so as to inhibit an operation speed of an integrated circuit from being improved.

In order to solve such drawbacks, materials having a low permittivity (low-k materials) have been developed as an insulating material between interconnections as described above. Further, multilayered interconnections have also been developed with such a material having a low permittivity. With conventional insulating materials, it is difficult to provide both of sufficiently low permittivity and insulation characteristics. Accordingly, a material having a low permittivity (porous low-k material) which includes a large number of holes having a low permittivity (e.g., a relative permittivity of about 1) in a material having a high permittivity (e.g., a relative permittivity of about 3) has been considered as one of the most favorable materials.

Generally, a damascene process is employed to produce large-scale integrated circuits having a multilayer structure and a narrowed structure. With the damascene process, via holes and interconnection grooves are first formed in a flattened insulating film. Then, a thin barrier film (barrier layer) made of tantalum (Ta) or tantalum nitride (TaN) having a thickness of about 20 nm is formed on the via holes and interconnection grooves by physical vapor deposition (PVD) or chemical vapor deposition (CVD). Next, copper (Cu) is embedded in the via holes and interconnection grooves by plating. Then, the embedded copper is polished with a chemical mechanical polishing apparatus (CMP apparatus) until a surface of the copper is substantially on the same plane as a flattened surface of the insulating film. At that time, the barrier layer is also removed.

In a damascene process, when a material having a low permittivity (low-k material) is used as an insulating material, a large number of defects (e.g., cracking, separation or removal of interconnections from the insulating film, or disconnection) are more likely to be caused in Cu interconnections as compared to a case of a conventional material. It is considered that such defects of Cu interconnections are caused because the porous low-k material has a low mechanical strength, a small elastic modulus, a low toughness, a low adhesiveness between an interconnection and a lower layer as it has a large number of holes therein as described above. Further, since the porous low-k material includes a large number of holes, the porous low-k material has characteristics similar to a heat insulator. Thus, the porous low-k material has a low heat conductivity. Accordingly, the porous low-k material suffers another problem that heat cannot be discharged from Cu interconnections.

### DISCLOSURE OF INVENTION

The present invention has been made in view of the aforementioned drawbacks which would be caused when a material having a low permittivity is used. It is, therefore, a first object of the present invention to provide a polishing apparatus and a polishing method which can simultaneously achieve uniform supply of a chemical liquid to a surface of a workpiece to be polished and a uniform polishing rate within the surface of the workpiece.

A second object of the present invention is to provide a polishing apparatus and a polishing method which can prevent defects of interconnections when an insulating material has a low mechanical strength.

According to a first aspect of the present invention, there is provided a polishing apparatus which can simultaneously achieve uniform supply of a chemical liquid to a surface of a substrate to be polished and a uniform polishing rate within the surface of the substrate. The polishing apparatus has a polishing surface, a top ring for holding a substrate, a drive mechanism configured to move the polishing surface and the substrate held by the top ring relative to each other at a relative speed, and a press mechanism configured to press the substrate held by the top ring against the polishing surface under a pressing pressure. The polishing apparatus also has a controller operable to adjust a polishing condition in a non-Preston range in which a polishing rate is not proportional to a product of the pressing pressure and the relative speed.

According to a second aspect of the present invention, there is provided a polishing apparatus which can simultaneously achieve uniform supply of a chemical liquid to a surface, of a substrate to be polished and a uniform polishing rate within the surface of the substrate. The polishing apparatus has a polishing surface, a top ring for holding a substrate, a drive mechanism configured to move the polishing surface and the substrate held by the top ring relative to each other at a relative speed, and a press mechanism configured to press the substrate held by the top ring against the polishing surface under a pressing pressure. The polishing apparatus also has a chemical liquid supply mechanism configured to supply a chemical liquid to a surface of the substrate held by the top ring. The chemical liquid is capable of oxidizing the surface of the substrate at a reaction rate. The polishing apparatus includes a controller operable to adjust a concentration or a temperature of the chemical liquid so that the reaction rate is lower than a process rate calculated from the pressing pressure and the relative speed by Preston equation.

According to a third aspect of the present invention, there is provided a polishing apparatus which can simultaneously achieve uniform supply of a chemical liquid to a surface of a substrate to be polished and a uniform polishing rate within the surface of the substrate. The polishing apparatus has a polishing surface, a top ring for holding a substrate, a drive mechanism configured to move the polishing surface and the substrate held by the top ring relative to each other at a relative speed, and a press mechanism configured to press the substrate held by the top ring against the polishing surface under a pressing pressure. The polishing apparatus also has a chemical liquid supply mechanism configured to supply a chemical liquid to a surface of the substrate held by the top ring. The chemical liquid is capable of oxidizing the surface of the substrate at a reaction rate. The polishing apparatus includes a controller operable to adjust at least one of the relative speed and the pressing pressure so that a polishing rate calculated from a product of the relative speed and the pressing pressure by Preston equation is higher than the reaction rate.

According to a fourth aspect of the present invention, there is provided a polishing apparatus which can simultaneously achieve uniform supply of a chemical liquid to a surface of a substrate to be polished and a uniform polishing rate within the surface of the substrate. The polishing apparatus has a polishing surface, a top ring for holding a substrate, a drive mechanism configured to move the polishing surface and the substrate held by the top ring relative to each other at a relative speed, and a press mechanism configured to press the substrate held by the top ring against the polishing surface under a pressing pressure. The polishing apparatus also has an electrode disposed so as to face the substrate, a power source for applying a voltage between the substrate and the electrode to oxidize a surface of the substrate held by the top ring at a reaction rate, and a chemical liquid supply mechanism configured to supply a chemical liquid of an electrolytic solution between the electrode and the surface of the substrate. The polishing apparatus includes a controller operable to adjust at least one of the relative speed and the pressing pressure so that a polishing rate calculated from a product of the relative speed and the pressing pressure by Preston equation is higher than the reaction rate.

According to a fifth aspect of the present invention, there is provided a polishing apparatus which can simultaneously achieve uniform supply of a chemical liquid to a surface of a substrate to be polished and a uniform polishing rate within the surface of the substrate. The polishing apparatus has a polishing surface, a top ring for holding a substrate, a drive mechanism configured to move the polishing surface and the substrate held by the top ring relative to each other at a relative speed, and a press mechanism configured to press the substrate held by the top ring against the polishing surface under a pressing pressure. The polishing apparatus also has an electrode disposed so as to face the substrate, a power source for applying a voltage between the substrate and the electrode, and a chemical liquid supply mechanism configured to supply a chemical liquid of an electrolytic solution between the electrode and a surface of the substrate. The polishing apparatus includes a controller operable to adjust the voltage so as to oxidize the surface of the substrate at a reaction rate lower than a polishing rate calculated from a product of the relative speed and the pressing pressure by Preston equation.

According to a sixth aspect of the present invention, there is provided a polishing method which can simultaneously achieve uniform supply of a chemical liquid to a surface of a substrate to be polished and a uniform polishing rate within the surface of the substrate. According to this method, a polishing surface and a substrate are moved relative to each other at a relative speed while the substrate is pressed against the polishing surface under a pressing pressure. A polishing condition is adjusted in a non-Preston range in which a polishing rate is not proportional to a product of the pressing pressure and the relative speed.

According to a seventh aspect of the present invention, there is provided a polishing method which can simultaneously achieve uniform supply of a chemical liquid to a surface of a substrate to be polished and a uniform polishing rate within the surface of the substrate. According to this method, a polishing surface and a substrate are moved relative to each other at a relative speed while the substrate is pressed against the polishing surface under a pressing pressure. A chemical liquid is supplied to a surface of the substrate. The chemical liquid is capable of oxidizing a surface of the substrate at a reaction rate. A concentration or a temperature of the chemical liquid is adjusted so that the reaction rate is lower than a process rate calculated from the pressing pressure and the relative speed by Preston equation.

According to an eighth aspect of the present invention, there is provided a polishing method which can simultaneously achieve uniform supply of a chemical liquid to a surface of a substrate to be polished and a uniform polishing rate within the surface of the substrate. According to this method, a polishing surface and a substrate are moved relative to each other at a relative speed while the substrate is pressed against the polishing surface under a pressing pressure. A chemical liquid is supplied to a surface of the substrate. The chemical liquid is capable of oxidizing the surface of the substrate at a reaction rate. At least one of the relative speed and the pressing pressure is adjusted so that a polishing rate calculated from a product of the relative speed and the pressing pressure by Preston equation is higher than the reaction rate.

According to a ninth aspect of the present invention, there is provided a polishing method which can simultaneously achieve uniform supply of a chemical liquid to a surface of a substrate to be polished and a uniform polishing rate within the surface of the substrate. According to this method, a polishing surface and a substrate are moved relative to each other at a relative speed while the substrate is pressed against the polishing surface under a pressing pressure. A chemical liquid of an electrolytic solution is supplied between an electrode and a surface of the substrate. The electrode is disposed so as to face the substrate. A voltage is applied between the substrate and the electrode to oxidize the surface of the substrate at a reaction rate. At least one of the relative speed and the pressing pressure is adjusted so that a polishing rate calculated from a product of the relative speed and the pressing pressure by Preston equation is higher than the reaction rate.

According to a tenth aspect of the present invention, there is provided a polishing method which can simultaneously achieve uniform supply of a chemical liquid to a surface of a substrate to be polished and a uniform polishing rate within the surface of the substrate. According to this method, a polishing surface and a substrate are moved relative to each other at a relative speed while the substrate is pressed against the polishing surface under a pressing pressure. A chemical liquid of an electrolytic solution is supplied between an electrode and a surface of the substrate. The electrode is disposed so as to face the substrate. A voltage is applied between the substrate and the electrode to oxidize the surface of the substrate at a reaction rate. The voltage is adjusted so that the reaction rate is lower than a polishing rate calculated from a product of the relative speed and the pressing pressure by Preston equation.

According to an eleventh aspect of the present invention, there is provided a polishing apparatus which can simultaneously achieve uniform supply of a chemical liquid to a surface of a substrate to be polished and a uniform polishing rate within the surface of the substrate. The polishing apparatus has a polishing surface, a top ring for holding a substrate, a drive mechanism configured to move the polishing surface and the substrate held by the top ring relative to each other at a relative speed, and a press mechanism configured to press the substrate held by the top ring against the polishing surface under a pressing pressure. The polishing apparatus also has a conditioner operable to condition the polishing surface during polishing of the substrate. The polishing apparatus includes a controller operable to adjust polishing and conditioning conditions in a non-Preston range in which a polishing rate is not proportional to a product of the pressing pressure and the relative speed.

According to a twelfth aspect of the present invention, there is provided a polishing method which can simultaneously achieve uniform supply of a chemical liquid to a surface of a substrate to be polished and a uniform polishing rate within the surface of the substrate. According to this method, a polishing surface and a substrate are moved relative to each other at a relative speed while the substrate is pressed against the polishing surface under a pressing pressure. The polishing surface is conditioned during polishing of the substrate. Polishing and conditioning conditions are adjusted in a non-Preston range in which a polishing rate is not proportional to a product of the pressing pressure and the relative speed.

According to a thirteenth aspect of the present invention, there is provided a polishing apparatus which can simultaneously achieve uniform supply of a chemical liquid to a surface of a substrate to be polished and a uniform polishing rate within the surface of the substrate. The polishing apparatus has a polishing surface, a top ring for holding a substrate, a drive mechanism configured to move the polishing surface and the substrate held by the top ring relative to each other at a relative speed, and a press mechanism configured to press the substrate held by the top ring against the polishing surface under a pressing pressure. The polishing apparatus also has a conditioner operable to condition the polishing surface before polishing of the substrate. The polishing apparatus includes a controller operable to adjust a polishing condition in a non-Preston range in which a polishing rate is not proportional to a product of the pressing pressure and the relative speed.

According to a fourteenth aspect of the present invention, there is provided a polishing method which can simultaneously achieve uniform supply of a chemical liquid to a surface of a substrate to be polished and a uniform polishing rate within the surface of the substrate. According to this method, a polishing surface is conditioned before polishing of a substrate. The polishing surface and the substrate are moved relative to each other at a relative speed while the substrate is pressed against the polishing surface under a pressing pressure. A polishing condition is adjusted in a non-Preston range in which a polishing rate is not proportional to a product of the pressing pressure and the relative speed.

According to the present invention as described above, polishing can be conducted under the polishing conditions in the non-Preston range. Accordingly, a polishing rate becomes constant at any point of the surface of the substrate even if a process pressure or a relative speed is uneven over the surface of the substrate. Thus, it is possible to achieve uniform polishing. A constant polishing rate can be achieved irrespective of the relative speed. Accordingly, uniform supply of a chemical liquid to the entire surface of the substrate and a uniform polishing rate within the surface of the substrate can be achieved at the same time.

Further, the polishing surface can be conditioned while polishing under conditions in the non-Preston range (in-situ conditioning). Alternatively, the polishing surface can be conditioned before polishing under conditions in the non-Preston range (ex-situ conditioning).

Meanwhile, a substrate having an interconnection pattern of a single layer was polished with a CMP apparatus. At that time, a state of the substrate was analyzed by a finite element method. As a result, a low-k film having a low mechanical strength was deformed due to a pressing force (polishing pressure) applied to the substrate mainly during a CMP process. Large tensile stresses were produced near an interface between a barrier layer and Cu interconnections. A distribution of tensile stress will be described with reference to FIGS. 2A through 9.

FIG. 2A is a cross-sectional view showing five Cu interconnections 1 (dense interconnections) embedded in a low-k film 2. FIG. 2B is a graph showing a tensile stress produced on surfaces of the low-k film 2 and the Cu interconnections 1 shown in FIG. 2A. FIG. 3A is a cross-sectional view showing a Cu interconnection 1 (isolated interconnection) embedded in a low-k film 2. FIG. 3B is a graph showing a tensile stress produced on surfaces of the low-k film 2 and the Cu interconnection I shown in FIG. 3A. In FIGS. 2A and 3A, the reference numeral 1 represents a Cu interconnection, the reference numeral 2 a low-k film, and the reference numeral 3 a Ta layer as a barrier layer. Each of the Cu interconnections 1 shown in FIG. 2A has a width of 0.18 μm, and the Cu interconnection shown in FIG. 3A also has a width of 0.18 μm.

In a case of the dense interconnections, as shown in FIG. 2B, it can be seen that large tensile stresses are produced at peripheral edges of the outermost Cu interconnections 1. In a case of the isolated interconnection, as shown in FIG. 3B, it can be seen that relative maximum tensile stresses are produced at both peripheral edges of the Cu interconnection 1. Further, as can be seen from FIGS. 2B and 3B, the case of the dense interconnections and the case of the isolated interconnection have substantially the same maximum values of tensile stresses. In FIGS. 2B and 3B, tensile stresses are calculated on the assumption that a uniform pressure of 13.8 kPa is applied to a surface of the device having the low-k film 2 and the Cu interconnection(s) 1.

Generally, when a polishing pad dressed by a dresser is used to polish a wafer, the wafer is not brought into contact with the entire surface of the polishing pad. The wafer is brought into contact with only slight portions of fluffed surfaces of the polishing pad via abrasive particles contained in a polishing liquid (slurry). FIG. 4 shows a state in which a polishing pad 25 and a substrate W are brought into contact with each other. As shown in FIG. 4, a large number of projections 25a are formed on a surface of the polishing pad 25. The projections 25a are brought into contact with a surface S₁ of the substrate W via abrasive particles 27 contained in a polishing liquid 26. It has been known that an actual contact area between the polishing pad 25 and the substrate W are extremely small (not more than 1% of a surface area of the substrate W). In consideration of these, the inventors have surmised that pressures much larger than a pressure applied to a rear face S₂ (usually an upper surface during polishing) of the substrate are locally applied to the surface of the substrate.

Additionally, in consideration of stress sensitivity of Cu to a polishing liquid, the inventors have believed that stress corrosion cracking is caused near an interface between a barrier layer and Cu interconnections, and that defects of the Cu interconnections are caused due to the stress corrosion cracking.

Locations of stress concentration, as shown in FIGS. 2B and 3B, analyzed by a finite element method considerably accord with locations of defects of Cu interconnections which are caused when a substrate is actually polished with a CMP apparatus, as shown by Nagai, et al., Proc. 2004 Int. Interconnect Tech. Conf., 2004, pages 145-147. Defects are intensively caused at both sides of an isolated interconnection or at areas outside of interconnections extending in parallel. Defects are unlikely to be caused when an insulating material having a high strength is used. Thus, the inventors have confirmed that most of causes of actual defects can be explained with the stress corrosion cracking.

Further, the inventors have found that a maximum value of tensile stress and a location of stress concentration are varied because of a surface shape of a Cu film and a thickness of a barrier layer. This phenomenon will be described below with reference to FIGS. 5A through 9. FIG. 5A is a cross-sectional view showing an isolated interconnection after plating, and FIG. 5B is a partial enlarged view of the isolated interconnection shown in FIG. 5A. In FIGS. 5A and 5B, the amount of change is multiplied by 50,000. In this example, an interlayer dielectric (ILD) 2 has a laminated structure including D-MSQ (high-density methylsiloxane low-k film) 2a and P-MSQ (porous methylsiloxane low-k film) 2b. A Ta layer 3 is formed as a barrier layer on the interlayer dielectric 2. A Cu film 7 is deposited on the Ta layer 3 by plating.

As shown in FIGS. 5A and 5B, a recess 7a is formed in an upper surface of the Cu film 7. The recess 7a is produced by a plating process and located right above an interconnection 1. When a substrate in which the recess 7a is formed is polished by CMP, a maximum tensile stress in a horizontal direction is produced at a portion X shown in FIG. 5B. Accordingly, stress corrosion cracking is most likely to be caused at the recess 7a.

FIG. 6 is a graph showing a tensile stress produced on a surface of the substrate in a horizontal direction when the barrier layer is polished after the Cu film has been removed. In FIG. 6, the reference numeral C1 represents a tensile stress when the barrier layer is thick (the Ta layer has a film thickness of 30 nm), and the reference numeral C2 represents a tensile stress when the barrier layer has completely been removed (the Ta layer has a film thickness of 0 nm). In this example, the interlayer dielectric has a two-layer structure including an upper layer and a lower layer. The upper layer includes a hard mask made of TEOS, which has a Young's modulus of 60 GPa, or SiOC (a low-k film containing carbon), which has a Young's modulus of 11 GPa. The lower layer includes P-MSQ, which has a Young's modulus of 5 GPa. As shown in FIG. 6, after the Cu film has been removed, maximum tensile stresses are produced at peripheral edges of the Cu interconnection. It can be seen from FIG. 6 that the maximum tensile stresses in the case where the barrier layer is thick are smaller than the maximum tensile stresses in the case where the barrier layer has completely been removed.

FIG. 7 is a cross-sectional view showing portions at which stress corrosion cracking is likely to be caused when a Cu interconnection is formed by CMP based on the above discussion. Specifically, at an initial stage of a polishing process, as shown by arrow A1, stress concentration is produced at a recess 7a located right above an interconnection 1. After the recess 7a has been removed by polishing, as shown by arrows A2 and A3, stress concentration is produced at peripheral edges of the interconnection 1. Thus, locations of stress concentration are varied according to progress of a CMP process.

FIG. 8 is a graph showing a relationship between variation of tensile stress according to progress of a CMP process and an optimum polishing pressure, which is a pressure to press a substrate against a polishing surface, in the CMP process in consideration of the above discussion. The finite element method shows that tensile stress has a linear relationship with a polishing pressure. Accordingly, a polishing pressure is lowered to reduce the tensile stress. Specifically, in order to prevent stress corrosion cracking, it is effective to lower a polishing pressure at an initial stage at which the recess is formed in the surface of the Cu film and at a final stage at which the barrier layer is exposed on the surface of the substrate.

FIG. 9 is a graph showing that maximum tensile stresses are varied according to a structure of an interlayer dielectric. In FIG. 9, lines L1, L4, L5 represent cases in which the interlayer dielectric has a laminated structure including D-MSQ and P-MSQ, and lines L2 and L3 represents cases in which the interlayer dielectric has a single-layer structure of D-MSQ. D-MSQ has a Young's modulus of 15 GPa to 20 GPa, and P-MSQ has a Young's modulus of 5 GPa to 8.5 GPa.

Intense stress corrosion cracking is caused in Cu interconnections when P-MSQ having a Young's modulus of 7 GPa is used. However, stress corrosion cracking is hardly caused when P-MSQ having a Young's modulus 8.5 GPa is used. In the latter case, the stress corrosion cracking is not distinguishable from other types of corrosion such as galvanic corrosion. Accordingly, as seen from FIG. 9, stress corrosion cracking is expected to be prevented when a maximum tensile stress is not more than 0.08 MPa (80 kPa). In fact, the maximum tensile stress at the recess of the Cu film shown in FIG. 5B is larger than 0.08 MPa. Stress corrosion cracking is considered to be caused at the recesses in the Cu interconnections.

In order to prevent stress corrosion cracking, as described above, it is effective to lower a polishing pressure at an initial stage of a CMP process. However, no stress corrosion cracking is caused when any recesses are formed in the surface of the Cu film. Accordingly, in order to prevent stress corrosion cracking, it also is effective to employ plating technology to improve flatness of a Cu film after a plating process. In the example shown in FIG. 5B, the maximum tensile stress is 80 to 90 kPa when the recess having a depth of 100 nm is located above the interconnection having a width of 200 nm. Specifically, stress corrosion cracking is considered to be caused when a ratio of the depth of the recess and the width of the interconnection is 0.5 (100 nm/200 nm). Accordingly, stress corrosion cracking can substantially be eliminated if a substrate is plated so that a ratio of the depth of the recess and the width of the interconnection is not more than a half of 0.5, i.e., 0.25.

Thus, defects of Cu interconnections are caused mainly for the following reasons. A low-k material is caved (greatly deformed) so as to produce large tensile stresses at recesses of the Cu film and near an interface between Cu interconnections and a barrier layer when a substrate is strongly pressed against a polishing pad. An actual contact area between the polishing pad and the substrate is small. Further, copper has stress sensitivity to a polishing liquid.

Accordingly, a first concept to prevent defects of metal interconnections such as Cu interconnections is to increase an actual contact area between a polishing pad and a substrate.

Specifically, according to a fifteenth aspect of the present invention, there is provided a polishing apparatus which can prevent defects of interconnections when an insulating material has a low mechanical strength. The polishing apparatus has a polishing pad, a top ring for bringing a substrate into sliding contact with the polishing pad to polish the substrate, and a dresser configured to dress the polishing pad so as to increase an actual contact area between the substrate and the polishing pad.

The dresser may be configured to dress the polishing pad so that a plurality of projections formed on a surface of the polishing pad have substantially the same height. With this arrangement, an actual contact area between the substrate (e.g., semiconductor wafer) and the polishing pad can be increased.

The dresser may be configured to dress the polishing pad so that a plurality of projections formed on a surface of the polishing pad have a height in a range of 0.3 to 10 μm. Thus, the heights of the projections (the roughness of the polishing pad) are reduced to bring large areas of the polishing pad into contact with the substrate via abrasive particles. Accordingly, a pressing force applied to the substrate from a rear face (upper surface) thereof can be dispersed so as to suppress stress corrosion cracking.

As a matter of course, when a pressing force applied to a substrate from a rear face (upper surface) thereof is reduced, large forces locally applied to the substrate can be reduced to prevent stress corrosion cracking. However, it is difficult to extremely lower a pressure from the rear face of the substrate with a conventional CMP apparatus. With the conventional CMP apparatus, a pressure from the rear face of the substrate is generally about 200 hPa. For example, a tenth of that pressure is 20 hPa. That value is no more than 2% of an atmospheric pressure and is readily changed by variation of the atmospheric pressure. Accordingly, it appears effective to increase an actual contact area between a polishing pad and a substrate in a range in which a pressure applied to the substrate from the rear face thereof can stably be controlled.

The polishing apparatus may have a polishing liquid supply mechanism configured to supply a polishing liquid including abrasive particles having different sizes to the polishing pad.

It is desirable to adjust a mixing ratio of abrasive particles having different sizes so that a particle size distribution of abrasive particles in the polishing liquid (slurry) is close to a surface roughness distribution of the polishing pad. If the surface roughness distribution of the polishing pad substantially accords with the particle size distribution of abrasive particles in slurry, small abrasive particles are distributed at higher portions of projections (near the substrate) while large abrasive particles are distributed at lower portions between the projections of the polishing pad. Thus, an actual contact area between the polishing pad and the substrate can be increased.

The polishing apparatus may have a polishing liquid supply mechanism configured to supply a polishing liquid including bubbles to the polishing pad.

According to the present invention as described above, the following two effects can be achieved. First, bubbles are introduced between the polishing pad and the abrasive particles or between the abrasive particles and the surface of the substrate. Concentration of forces is prevented on the surface of the substrate due to elasticity of the bubbles. Second, a large number of fine bubbles mixed in the polishing liquid are filled in a space between adjacent projections to fluff the projections. Thus, an actual contact area between the polishing pad and the substrate can be increased.

The polishing apparatus may have an ultrasonic vibrator for applying an ultrasonic wave to the polishing pad to vibrate a plurality of projections formed on a surface of the polishing pad.

According to the present invention as described above, the surface of the polishing pad can be fluffed by the ultrasonic wave to raise fallen projections of the polishing pad and to mix abrasive particles and move them upward. Thus, an actual contact area between the polishing pad and the substrate can be increased.

A second concept to prevent defects of metal interconnections is to disperse forces applied from a polishing pad via abrasive particles to be transmitted to a surface of a substrate.

According to a sixteenth aspect of the present invention, there is provided a polishing apparatus which can prevent defects of interconnections when an insulating material has a low mechanical strength. The polishing apparatus has a polishing pad, a top ring for bringing a substrate into sliding contact with the polishing pad to polish the substrate, and a polishing liquid supply mechanism configured to supply a polishing liquid including abrasive particles having an elasticity, hollow abrasive particles, or abrasive particles which are broken under a high pressure of 100 kPa to the polishing pad.

According to the present invention as described above, when forces are applied to abrasive particles sandwiched between the substrate and the polishing pad, the abrasive particles are deformed to increase a contact area with the substrate. Accordingly, forces applied to the surface of the substrate are dispersed to prevent high pressures from being applied to local areas of the substrate. Further, when large forces are applied to the abrasive particles during polishing, the abrasive particles are broken so as to prevent local forces from being applied to the substrate. Abrasive particles having an elasticity may comprise abrasive particles having an elastic body and a plurality of fine particles attached to a surface the elastic body or abrasive particles made of an elastic body.

According to a seventeenth aspect of the present invention, there is provided a polishing apparatus which can prevent defects of interconnections when an insulating material has a low mechanical strength. The polishing apparatus has a polishing pad, a top ring for bringing a substrate into sliding contact with the polishing pad to polish the substrate, and a polishing liquid supply mechanism configured to supply a polishing liquid including no abrasive particles to the polishing pad.

Generally, since abrasive particles are present between the polishing pad and the substrate, only limited areas of abrasive particles are brought into contact with the substrate. According to the present invention as described above, with use of a polishing liquid including no abrasive particles, the projections of the polishing pad is brought into direct contact with the substrate. Accordingly, as compared to a case of a polishing liquid including abrasive particles, it is possible to maintain a larger contact area between the polishing pad and the substrate. Thus, forces can be dispersed to suppress stress concentration.

A third concept to prevent defects of metal interconnections is to reinforce an insulating film in which tensile stresses are caused. Generally, when a substrate is pressed against the polishing pad, a low-k material is greatly caved at both sides of Cu interconnections so as to produce large tensile stresses on the surface of the substrate. Since stress corrosion cracking is caused by these large tensile stresses, it is effective to prevent the low-k film from being caved for preventing defects of metal interconnections.

Therefore, according to an eighteenth aspect of the present invention, there is provided a method of processing a substrate which can prevent defects of interconnections when an insulating material has a low mechanical strength. According to this method, a dummy interconnection is formed adjacent to a metal interconnection embedded in an insulating film formed on a substrate. The substrate is polished after the forming operation.

In this case, it is not necessary to provide dummy interconnections between congested metal interconnections. Dummy interconnections are provided only at locations adjacent to the outermost metal interconnections. The dummy interconnections have a line width required to reduce tensile stresses produced on the surface of the substrate. Accordingly, dummy interconnections having substantially the same line width as the metal interconnections have an effect to prevent defects of the metal interconnections. However, in consideration of insulation characteristics of the low-k material, it is desirable to form dummy interconnections having a large line width so as to serve as radiators. In this case, heat transfer is promoted so as to avoid a temperature increase in an integrated circuit.

According to a nineteenth aspect of the present invention, there is provided a method of processing a substrate which can prevent defects of interconnections when an insulating material has a low mechanical strength. According to this method, an insulating film formed on a substrate is hardened at a portion adjacent a metal interconnection embedded in the insulating film. The substrate is polished after the hardening operation.

For example, portions of the insulating film (e.g., a low-k film) are hardened at both sides of metal interconnections before a metal film is formed. In this case, when an electron beam is applied to the low-k film, a composition of the low-k film can be changed so as to enhance the mechanical strength of the low-k material. However, if an electron beam is applied to the entire surface of the substrate, then the composition of the low-k film is changed over the entire surface of the substrate so that a low permittivity and insulation characteristics of the low-k film may be deteriorated. Accordingly, after forming pattern grooves by etching, an electron beam is preferably applied to areas adjacent to the pattern grooves, in which the pattern is not formed, so as to increase the strength of those areas. Further, in order to prevent the low permittivity of the low-k film from being deteriorated, it is desirable that an electron beam is applied to outer areas spaced by substantially the same distance as intervals between the metal interconnections. In this case, it is desirable to apply an electron beam to an area having a width larger than two times the widths of the metal interconnections. Thus, according to the present invention as described above, it is possible to prevent deformation of the low-k film (insulating film) due to a pressing force and to maintain properties of the insulating film. Accordingly, defects of the metal interconnections can be prevented.

According to a twentieth aspect of the present invention, there is provided a polishing method which can prevent defects of interconnections when an insulating material has a low mechanical strength. According to this method, a polishing pad is dressed so that a plurality of projections formed on a surface of the polishing pad have substantially the same height. A substrate is brought into sliding contact with the polishing pad to polish the substrate.

The polishing pad may be dressed so that the plurality of projections formed on the surface of the polishing pad have a height in a range of 0.3 to 10 μm. A polishing liquid including abrasive particles having different sizes may be supplied to the polishing pad. A polishing liquid including bubbles may be supplied to the polishing pad. An ultrasonic wave may be applied to the polishing pad to vibrate the plurality of projections formed on the surface of the polishing pad.

According to a twenty first aspect of the present invention, there is provided a polishing method which can prevent defects of interconnections when an insulating material has a low mechanical strength. According to this method, a polishing liquid including abrasive particles having an elasticity, hollow abrasive particles, or abrasive particles which are broken under a high pressure of 100 kPa is supplied to a polishing pad. A substrate is brought into sliding contact with the polishing pad to polish the substrate.

According to a twenty second aspect of the present invention, there is provided a polishing method which can prevent defects of interconnections when an insulating material has a low mechanical strength. According to this method, a polishing liquid including no abrasive particles is supplied to a polishing pad. A substrate is brought into sliding contact with the polishing pad to polish the substrate.

A fourth concept to prevent defects of metal interconnections is to change a polishing pressure according to a surface shape and a thickness of a film on a substrate.

Specifically, according to a twenty third aspect of the present invention, there is provided a polishing method which can prevent defects of interconnections when an insulating material has a low mechanical strength. According to this method, it is detected whether or not a surface shape of a substrate meets a predetermined criteria. A polishing pressure is determined based on a result of the detecting operation. The substrate is pressed against a polishing surface under the determined polishing pressure to polish the substrate.

According to the present invention as described above, in a case where recesses are formed in a surface of a substrate (including a metal film), a polishing pressure can be lowered. Accordingly, defects (e.g., cracking) of the metal interconnections can be prevented.

The surface shape may be determined from a ratio of depth of a recess formed in a surface of the substrate and a width of an interconnection in the substrate. A type of a film exposed on a surface of the substrate may be detected. A thickness of a film on the substrate may be measured during polishing, and the polishing pressure may be changed based on the measured thickness of the film on the substrate. The film may have a laminated structure including a plurality of types of materials having different Young's moduli. The polishing pressure may be changed when at least one of the plurality of types of materials has been removed by polishing.

According to the present invention as described above, when the thickness of the substrate becomes a value at which a maximum tensile stress is likely to be large, a polishing pressure can be lowered. Accordingly, defects of the metal interconnections can be prevented.

According to a twenty fourth aspect of the present invention, there is provided a polishing apparatus which can prevent defects of interconnections when an insulating material has a low mechanical strength. The polishing apparatus has a polishing table having a polishing surface, a top ring for pressing a substrate under a polishing pressure, and a shape measurement unit configured to measure a surface shape of the substrate. The polishing apparatus also has a controller operable to control the polishing pressure by detecting whether or not the measured surface shape meets a predetermined criteria and determining the polishing pressure at an initial stage of a polishing process based on a result of detection.

The shape measurement unit may be configured to measure the surface shape based on a ratio of depth of a recess formed in a surface of the substrate and a width of an interconnection in the substrate. The shape measurement unit may be configured to detect a type of a film exposed on a surface of the substrate. The polishing apparatus may further include a film thickness measurement device for measuring a thickness of a film on the substrate during polishing. The controller may be operable to change the polishing pressure based on the measured thickness of the film on the substrate during polishing. The film may have a laminated structure including a plurality of types of materials having different Young's moduli. The controller may be operable to change the polishing pressure when at least one of the plurality of types of materials has been removed by polishing.

According to a twenty fifth aspect of the present invention, there is provided a semiconductor device having a reduced number of defects of interconnections when an insulating material has a low mechanical strength. The semiconductor device has a substrate, an insulating film formed on a surface of the substrate, and a metal interconnection embedded in the insulating film. The metal interconnection is necessary for a circuit. The semiconductor device also has a dummy interconnection disposed adjacent to the metal interconnection.

According to a twenty sixth aspect of the present invention, there is provided a semiconductor device having a reduced number of defects of interconnections when an insulating material has a low mechanical strength. The semiconductor device has a substrate, an insulating film formed on a surface of the substrate, and a metal interconnection embedded in the insulating film. The metal interconnection is necessary for a circuit. The semiconductor device also has a hardened portion of the insulating film located at a position adjacent to the metal interconnection.

According to the present invention as described above, even if a low-k material having a low mechanical strength is used for an insulating film, defects of the metal interconnections can be prevented during polishing.

The above and other objects, features, and advantages of the present invention will be apparent from the following description when taken in conjunction with the accompanying drawings which illustrate preferred embodiments of the present invention by way of example.

### BRIEF DESCRIPTION OF DRAWINGS

FIGS. 1A through 1F are cross-sectional views showing a dual damascene process to form a copper interconnection;

FIG. 2A is a cross-sectional view showing five Cu interconnections (dense interconnections) embedded in a low-k film;

FIG. 2B is a graph showing a tensile stress produced on surfaces of the low-k film and the Cu interconnections shown in FIG. 2A;

FIG. 3A is a cross-sectional view showing a Cu interconnection (isolated interconnection) embedded in a low-k film;

FIG. 3B is a graph showing a tensile stress produced on surfaces of the low-k film and the Cu interconnection shown in FIG. 3A;

FIG. 4 is a schematic view showing a state in which a polishing pad and a substrate are brought into contact with each other;

FIG. 5A is a cross-sectional view showing an isolated interconnection after plating;

FIG. 5B is a partial enlarged view of the isolated interconnection shown in FIG. 5A;

FIG. 6 is a graph showing a tensile stress produced on a surface a the substrate in a horizontal direction when a barrier layer is polished;

FIG. 7 is a cross-sectional view showing portions at which stress corrosion cracking is likely to be caused when a Cu interconnection is formed by CMP;

FIG. 8 is a graph showing a relationship between variation of tensile stress according to progress of a CMP process and an optimum polishing pressure;

FIG. 9 is a graph showing that a maximum tensile stress is varied according to a structure of an interlayer dielectric;

FIG. 10 is a schematic view showing a polishing apparatus according to a first embodiment of the present invention;

FIG. 11 is a schematic view showing a relationship between a wafer and a polishing table shown in FIG. 10;

FIG. 12 is a graph showing a relationship between a PV product and a polishing rate in the polishing apparatus shown in FIG. 10;

FIG. 13 is a schematic view showing an example of a mixing system to mix components in a chemical liquid used in the polishing apparatus shown in FIG. 10;

FIG. 14 is a schematic view showing another example of a mixing system to mix components in a chemical liquid used in the polishing apparatus shown in FIG. 10;

FIG. 15 is a plan view showing an example of a polishing pad used in a polishing apparatus according to the present invention;

FIG. 16 is an enlarged view showing an example of a helical groove in the polishing pad shown in FIG. 15;

FIG. 17 is a plan view showing another example of a polishing pad used in a polishing apparatus according to the present invention;

FIG. 18 is a schematic view showing a polishing apparatus according to a second embodiment of the present invention;

FIG. 19 is a schematic view showing a polishing apparatus according to a third embodiment of the present invention;

FIG. 20 is a schematic view showing a structure of a conditioner in the polishing apparatus shown in FIG. 19;

FIG. 21 is a bottom view of the conditioner shown in FIG. 20;

FIG. 22 is a perspective view showing a variation of the conditioner shown in FIG. 19;

FIG. 23 is a perspective view showing another variation of the conditioner shown in FIG. 19;

FIG. 24 is a perspective view showing another variation of the conditioner shown in FIG. 19;

FIG. 25 is a perspective view showing an example in which an ion exchange resin is provided in the polishing apparatus shown in FIG. 19;

FIG. 26 is a bottom view of the ion exchange resin shown in FIG. 25;

FIG. 27 is a perspective view showing an example in which a nozzle for supplying a chemical liquid is provided in the polishing apparatus shown in FIG. 19;

FIG. 28 is a perspective view showing an example in which a nozzle for supplying a chelating agent or a chelating resin is provided in the polishing apparatus shown in FIG. 19;

FIG. 29 is a schematic view showing an example in which the conditioner shown in FIG. 24 is subjected to a feed back control;

FIG. 30 is a perspective view showing a variation of the conditioner shown in FIG. 23;

FIG. 31 is perspective view showing another variation of the conditioner shown in FIG. 19;

FIG. 32 is a side view showing a main portion of a polishing apparatus according to a fourth embodiment of the present invention;

FIG. 33 is a cross-sectional view schematically showing a polishing pad after a dressing process;

FIG. 34 is an enlarged view showing an example of a dresser shown in FIG. 32;

FIG. 35 is a cross-sectional view schematically showing a polishing pad dressed by a dresser in which heights of diamond particles are regulated so as to be lower than a certain value;

FIG. 36 is a schematic view showing an example of a dresser for chemically dressing a polishing pad;

FIG. 37A is a schematic view showing another example of a dresser for chemically dressing a polishing pad;

FIG. 37B is a schematic view showing another example of a dresser for chemically dressing a polishing pad;

FIG. 38 is a schematic view showing a semiconductor wafer polished with a polishing liquid containing two types of abrasive particles having different sizes;

FIG. 39A is a schematic view showing an example of a polishing liquid supply mechanism for supplying a polishing liquid containing two types of abrasive particles having different sizes;

FIG. 39B is a schematic view showing another example of a polishing liquid supply mechanism for supplying a polishing liquid containing two types of abrasive particles having different sizes;

FIG. 40 is a schematic view showing a state in which a semiconductor wafer is polished with a polishing liquid containing bubbles;

FIG. 41 is a schematic view showing an example of a polishing liquid supply mechanism for supplying a polishing liquid containing bubbles onto the polishing pad;

FIG. 42 is a schematic view showing another example of a polishing liquid supply mechanism for supplying a polishing liquid containing bubbles onto the polishing pad;

FIG. 43 is a schematic view showing another example of a polishing liquid supply mechanism for supplying a polishing liquid containing bubbles onto the polishing pad;

FIG. 44 is a schematic view showing a main portion of a polishing apparatus having an ultrasonic wave application device;

FIG. 45A is a schematic view showing a state in which a semiconductor wafer is polished with a polishing liquid containing hollow abrasive particles;

FIG. 45B is an enlarged cross-sectional view showing the hollow abrasive particle shown in FIG. 45A;

FIG. 45C is an enlarged cross-sectional view showing the hollow abrasive particle that is deformed under forces;

FIG. 46A is an enlarged cross-sectional view showing an abrasive particle having an elastic body and a large number of fine particles fixed to the elastic body;

FIG. 46B is an enlarged cross-sectional view showing the abrasive particle shown in FIG. 46A which is deformed under forces;

FIG. 47 is a cross-sectional view showing a group of Cu interconnections (dense interconnections) embedded in a low-k film;

FIG. 48 is a cross-sectional view showing a Cu interconnection (isolated interconnection) embedded in a low-k film;

FIGS. 49A through 49F are schematic views showing a process to form a Cu interconnection on a surface of a semiconductor wafer;

FIG. 50 is a plan view showing a chip (integrated circuit) formed on a semiconductor wafer; and

FIG. 51 is a side view showing a polishing apparatus according to a fifth embodiment of the present invention.

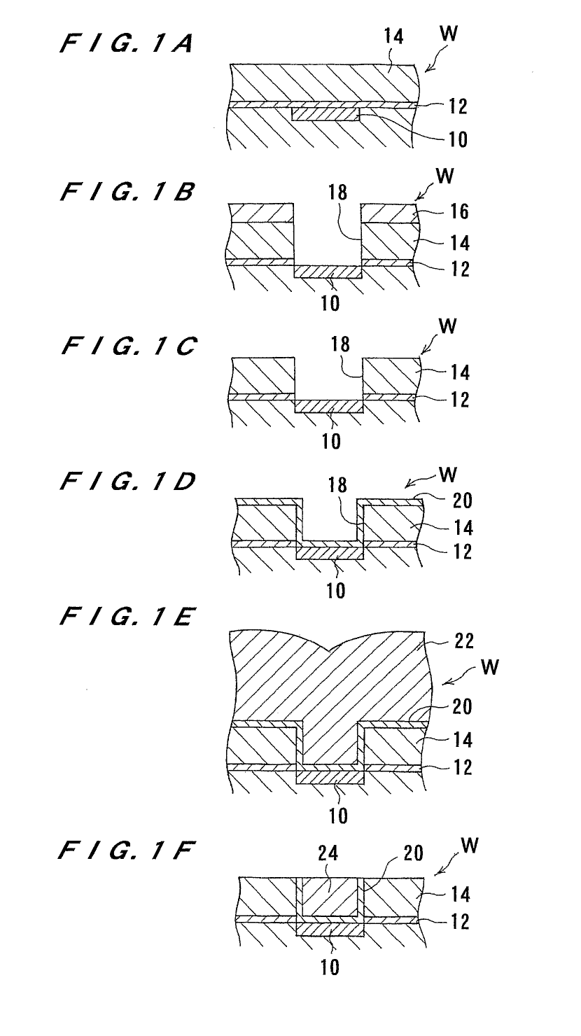

### BEST MODE FOR CARRYING OUT THE INVENTION

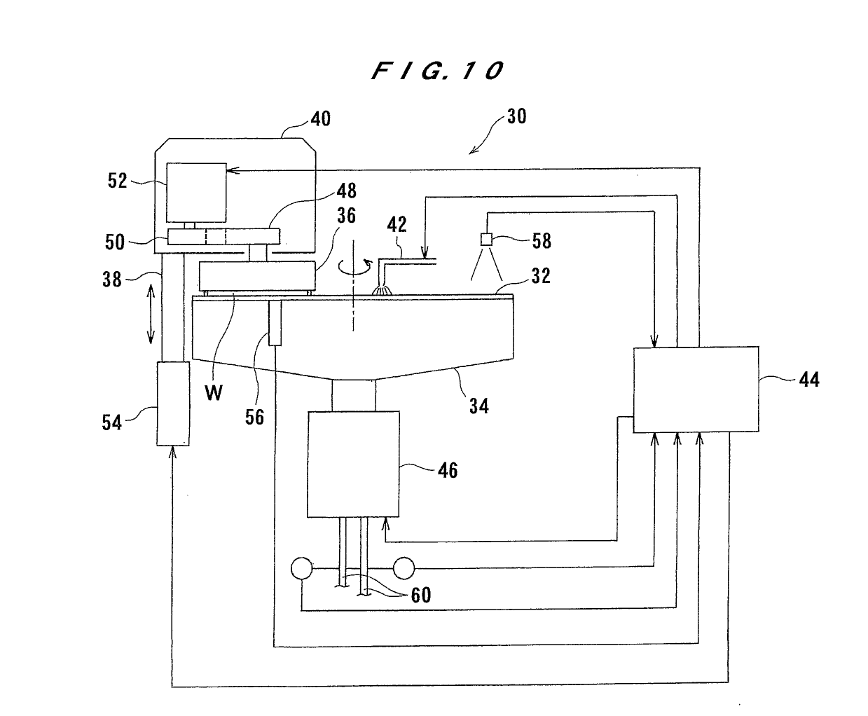

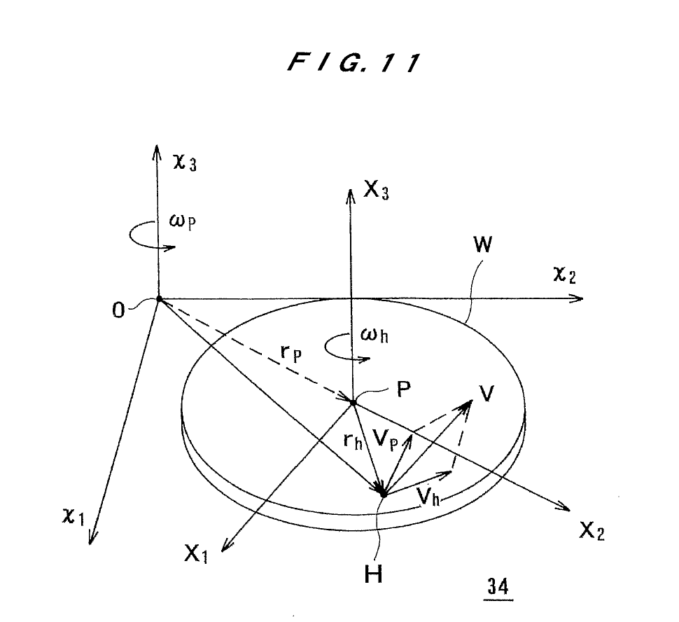

A polishing apparatus according to embodiments of the present invention will be described below with reference to FIGS. 10 through 51. Like or corresponding parts are denoted by like or corresponding reference numerals throughout drawings, and will not be described below repetitively.

FIG. 10 is a schematic view showing a polishing apparatus 30 according to a first embodiment of the present invention. As shown in FIG. 10, the polishing apparatus 30 includes a polishing table 34 having a polishing surface 32 attached on an upper surface thereof, a top ring 36 for holding a workpiece such as a semiconductor wafer W on a lower surface thereof, a top ring head 40 pivotable about a pivot shaft 38, a chemical liquid supply nozzle 42 which serves as a chemical liquid supply mechanism for supplying a chemical liquid (polishing liquid) onto the polishing surface 32, and a controller 44 for controlling operation of the polishing apparatus 30. The polishing surface 32 on the polishing table 34 is formed by polyurethane foam, a fixed abrasive, or an impregnated abrasive.

The polishing table 34 is coupled to a motor 46 located below the polishing table 34 and rotated by the motor 46. Thus, the motor 46 serves as a rotation mechanism to rotate the polishing table 34 and the polishing surface 32. The top ring 36 is coupled via timing belt pulleys 48 and 50 to a motor 52 located in the top ring head 40 and rotated by the motor 52. Thus, the motor 52 serves as a rotation mechanism to rotate the top ring 36.

The motors 46 and 52 are connected to the controller 44, which controls rotational speeds of the polishing table 34 and the top ring 36 at desired values. Thus, the motors 46 and 52 serve as a drive mechanism to move the polishing surface 32 and the wafer W held by the top ring 36 relative to each other at a desired relative speed.

Further, the pivot shaft 38 is coupled to a vertical movement mechanism 54. Thus, the top ring head 40 and the top ring 36 are vertically moved by the vertical movement mechanism 54. The vertical movement mechanism 54 is connected to the controller 44, which controls a pressure to press the wafer W held by the top ring 36 against the polishing surface 32 at a desired value. Thus, the vertical movement mechanism 54 serves as a press mechanism to press the wafer W held by the top ring 36 against the polishing surface 32 under a desired pressing pressure.

In the present embodiment, a chemical liquid (polishing liquid) supplied from the chemical liquid supply nozzle 42 includes an abrasive dispersion liquid in which abrasive particles such as silica are dispersed into pure water, an oxidizer such as a hydrogen peroxide solution or ammonia for oxidizing copper, and a chelating agent for producing a complex of oxidized copper. A dispersant may be added to the abrasive dispersion liquid as needed. The chemical liquid supply nozzle 42 is connected to the controller 44, which controls the amount, concentration, and temperature of a chemical liquid to be supplied. A dispersant, a selectivity adjustor, or an anticorrosive may be added to the chemical liquid in addition to the aforementioned abrasive dispersion liquid, oxidizer, and chelating agent. The abrasive particles are properly selected according to properties or structures of the polishing surface.

Generally, a process rate (polishing rate) in a polishing process is determined by the following Preston equation (1).
R=kPV (1)
In the above equation (1), R represents a process rate, P a pressure to press a workpiece to be polished against a polishing surface (process pressure), V a relative speed between the polishing surface and the workpiece, and k a Preston coefficient.

As can be seen from the Preston equation (1), when a workpiece is pressed against a polishing surface under a uniform pressure and polished, a relative speed between the polishing surface and the workpiece should be made uniform over a surface of the workpiece in order to make a polishing rate uniform over the surface of the workpiece. Accordingly, it is desirable that a rotational direction of the polishing table 34 is the same as a rotational direction of the top ring 36, and that a ratio of a rotational speed of the polishing table 34 to a rotational speed of the top ring 36 is equal to or close to 1.

Specifically, a relative speed V between a wafer W and a polishing surface at a desired point H shown in FIG. 11 is represented by
\vec{V}=\vec{v}ₚ+\vec{v}ₕ
=\vec{w}ₚ×(\vec{r}ₕ+\vec{r}ₚ)+[−\vec{w}ₕ×\vec{r}ₕ]
(\vec{w}ₚ−\vec{w}ₕ)×\vec{r}ₕ+\vec{w}ₚ×\vec{r}ₚ (2)
where vₚ represents a speed of the polishing table 34, vₕ a speed of the wafer W, wₚ a rotational speed of the polishing table 34, wₕ a rotational speed of the wafer W, rₚ a distance between a center O of the polishing table 34 and a center P of the wafer W, and rₕ a distance between the center P of the wafer and the desired point H.

As can be seen from the above equation (2), a relative speed at any desired point H of the wafer W can be made uniform when the rotational speed wₚ of the polishing table 34 is the same as the rotational speed wₕ of the wafer W.

Recently, a material having a low permittivity (low-k material) has been used for an insulating film of semiconductor devices in order to enhance an operational speed of the semiconductor devices. A low-k material has a low mechanical strength. Accordingly, the strength of a surface of a semiconductor device becomes lowered. A process pressure cannot be made high during CMP. Thus, polishing should be conducted with a low process pressure, e.g., 6.9 kPa (1.0 psi) or less. In order to maintain a certain process rate under such a low pressure, a relative speed between the polishing surface and the wafer should be increased as seen from the Preston equation (1).

In this case, when a relative speed is to be increased in a state such that a ratio of rotational speeds of the polishing table 34 and the top ring 36 is brought close to 1, a rotational speed of the top ring 36 should also be increased together with a rotational speed of the polishing table 34. However, when a rotational speed of the top ring 36 is increased, centrifugal forces are applied to a polishing liquid supplied to a surface of the wafer W, so that the polishing liquid is forced to flow from a central area of the wafer W to an outer area of the wafer W. Thus, polishing is inhibited at the central area of the wafer W. Specifically, the polishing liquid is unlikely to be supplied to the central area of the wafer W due to centrifugal forces. As a result, the central area of the wafer W is unlikely to be polished as compared to other areas of the wafer W.

When only a rotational speed of the polishing table 34 is increased while a rotational speed of the top ring 36 is set at a low value, centrifugal forces applied to the polishing liquid are reduced. Accordingly, the polishing liquid can be supplied to the central area of the wafer W. However, in this case, a ratio of a rotational speed of the polishing table 34 to a rotational speed of the top ring 36 becomes so high that the outer area and the central area of the wafer W have different relative speeds. Specifically, the outer area of the wafer W has a polishing rate higher than a polishing rate at the central area of the wafer W. Thus, the wafer W is polished unevenly.

As described above, when the wafer is polished under a low pressure, it is difficult to supply a polishing liquid uniformly to an entire surface of the wafer and maintain a uniform polishing rate within the surface of the wafer at the same time. The inventors have focused on the fact that polishing such as CMP proceeds by chemical action of oxidation (etching) and formation of a complex due to a polishing liquid (chemical liquid) and physical action of removal of the complex due to a polishing surface. The inventors have developed technology to achieve uniform supply of a polishing liquid to an entire surface of a wafer and a uniform polishing rate within the surface of the wafer at the same time.

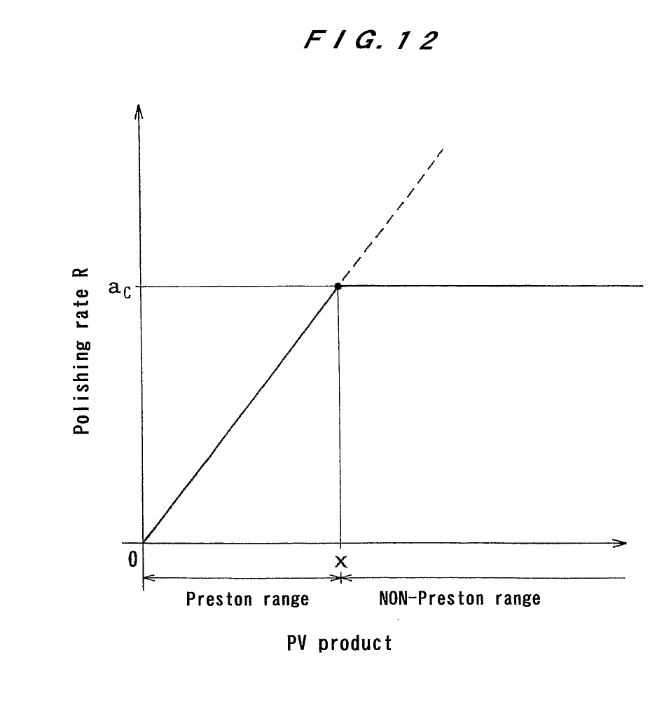

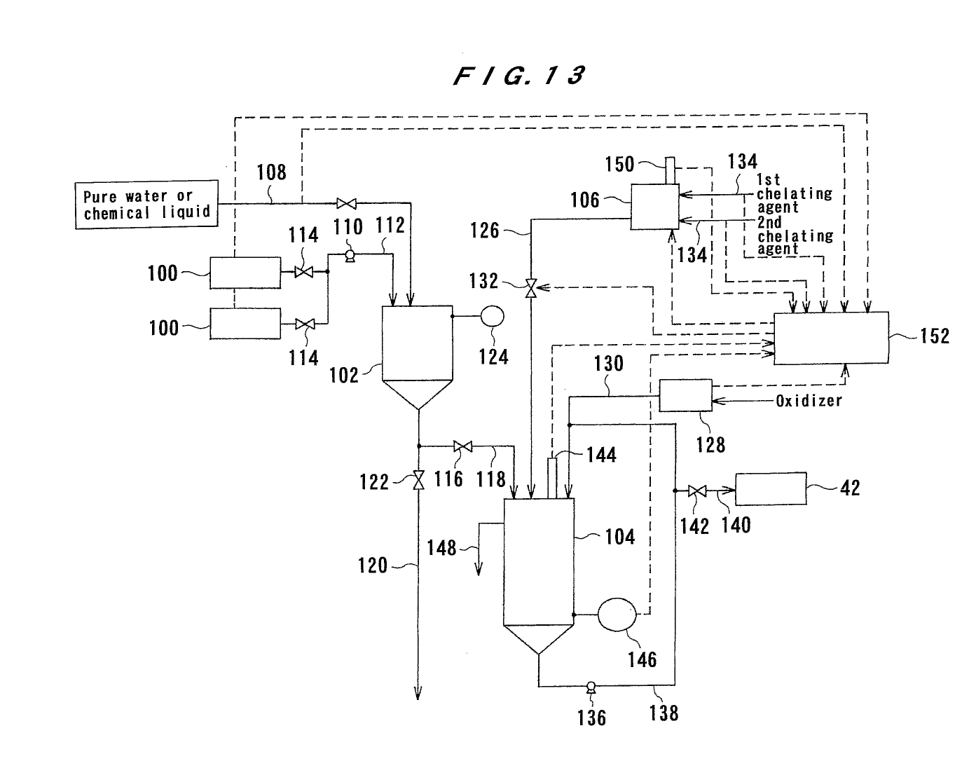

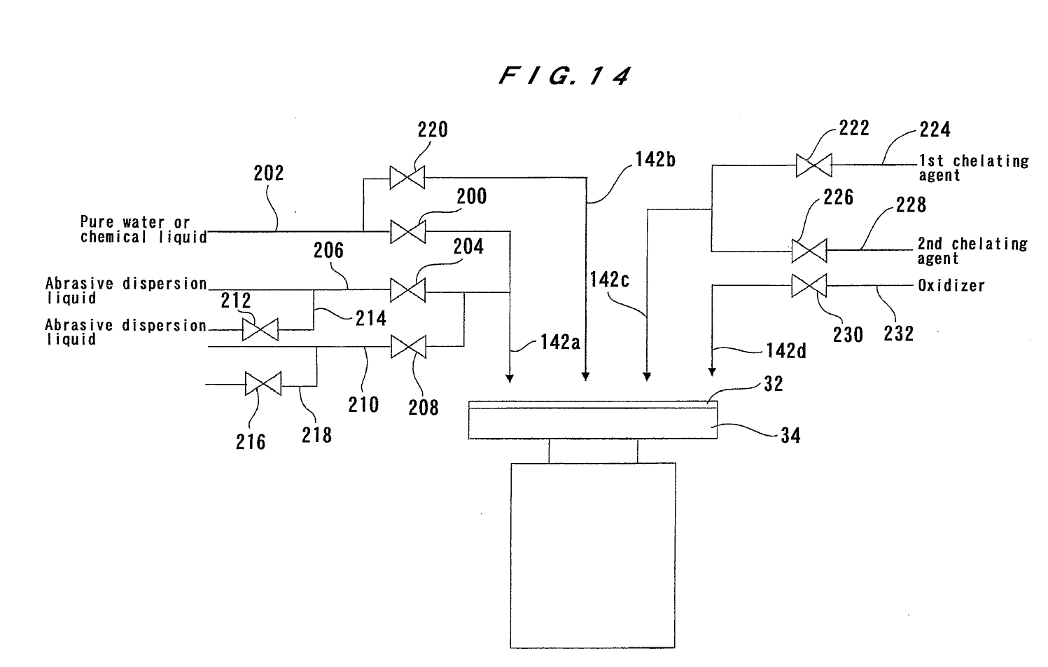

For example, copper is polished as follows. A surface of copper is oxidized by an oxidizer in a chemical liquid. At the same time, the oxidized copper is converted into a complex of copper by a chelating agent in the chemical liquid. The copper complex is mechanically removed by a polishing surface. Thus, copper is polished by the above chemical reaction and mechanical removal process. Accordingly, a rate of the mechanical removal process (polishing rate) cannot exceed a rate of the chemical reaction. For example, FIG. 12 shows a relationship between a product of a process pressure and a relative speed, which is hereinafter referred to as a PV product, and a polishing rate. In FIG. 12, a rate of the chemical reaction is represented by a_{c}. Specifically, in a range in which a PV product is smaller than x where a polishing rate is a_{c}, a polishing rate is proportional to a PV product according to the Preston equation. In a range in which a PV product is larger than x, a polishing rate does not exceed the chemical reaction rate a_{c} and thus becomes constant. In FIG. 12, the range in which a PV product is smaller than x is referred to as a Preston range, whereas the range in which a PV product is larger than x is referred to as a non-Preston range.

Accordingly, by polishing a workpiece under conditions in the non-Preston range, a polishing rate becomes constant (a_{c}) at any point of a surface of the workpiece even if a process pressure or a relative speed is uneven over the surface of the workpiece. Thus, it is possible to achieve uniform polishing. As described above, a constant polishing rate can be achieved irrespective of a relative speed. Accordingly, even if polishing is conducted under a low pressure with a low rotational speed of the top ring 36 and a high rotational speed of the polishing table 34, the outer area and the central area of the wafer W have the same polishing rate. Therefore, uniform supply of a polishing liquid to an entire surface of the wafer and a uniform polishing rate within the surface of the wafer can be achieved at the same time.

The chemical reaction rate a_{c} depends upon the amount, composition, concentration, temperature of the supplied chemical liquid and the like. Accordingly, by properly adjusting the amount, composition, concentration, temperature of the chemical liquid to be supplied, uniform supply of a chemical liquid (polishing liquid) to an entire surface of the wafer and a uniform polishing rate within the surface of the wafer can simultaneously be achieved under any polishing pressure.

The Preston coefficient k in the equation (1) depends upon properties of a film on a wafer, properties of abrasive particles, a dispersant, an oxidizer, a chelating agent used for polishing, a mixing rate and the amount of a mixture of these substances and pure water, properties of a polishing surface (polishing pad), and a temperature of an area being polished. Accordingly, the Preston equation is not determined in some polishing recipes. In such a case, it is necessary to determine a point (x, a_{c}) in FIG. 12 by gradually varying polishing conditions in which a relative speed, a process pressure, or a concentration or the amount of a mixture to be supplied is set as a parameter. For example, a point (x, a_{c}) in FIG. 12 can be determined in the following manners.

1) Conditions of a mixture and a PV product are set as two parameters. While one of these is fixed, another is gradually varied. Variations of a process amount (polishing amount) are measured. A point (x, a_{c}) is determined as a point at which the variations become deviated from a constant value.

2) Polishing is conducted in a state such that a ratio of a rotational speed of the top ring 36 to a rotational speed of the polishing table 34 is lower than 0.2, or in a state such that the top ring 36 and the polishing table 34 are rotated in opposite directions. Specifically, polishing is conducted within the Preston range in which a process rate is not constant over a surface of the wafer. Conditions of a mixture and a PV product are set as two parameters. While one of these is fixed, another is gradually varied. Variations of a process amount (polishing amount) are measured. A point (x, a_{c}) is determined as a point at which the process amount per unit time becomes uniform at desired points in a radial direction of the wafer.

More specifically, the above method 1) includes 1a) a PV product is varied while conditions of the mixture are fixed and 1b) conditions of the mixture are varied while a PV product is fixed. The above method 2) includes 2a) a PV product is varied while conditions of the mixture are fixed and 2b) conditions of the mixture are varied while a PV product is fixed.

1a) A ratio of a rotational speed of the top ring 36 to a rotational speed of the polishing table 34 is 1. At least one of a process pressure and a relative speed is gradually increased. Variations of an increasing rate of a polishing rate are measured. A point (x, a_{c}) is determined as a point at which the increasing rate of the polishing rate is reduced.

1b) A ratio of a rotational speed of the top ring 36 to a rotational speed of the polishing table 34 is 1. At least one of a process pressure and a relative speed is sufficiently increased. The amount of a mixture or a mixing rate of a chelating agent (including a first chelating agent and a second chelating agent described later), an oxidizer, a dispersant, an abrasive dispersion liquid, or pure water to be added into the mixture is varied near the increased point. A point (x, a_{c}) is determined as a point at which the variations of the polishing rate are not proportional to the variations of conditions of the mixture.

In the methods 1a) and 1b), a polishing rate near a central area of the wafer is liable to be influenced by a flow of slurry and is likely to be lowered at high speeds. When a film thickness measurement device described later continuously measures substantially the same points with respect to a radial direction of the wafer to calculate a polishing rate, a ratio of a rotational speed of the top ring 36 to a rotational speed of the polishing table 34 is not limited to 1 and may be any value.

2a) Polishing is conducted in a state such that a ratio of a rotational speed of the top ring 36 to a rotational speed of the polishing table 34 is lower than 0.2. Under these conditions, relative speeds are greatly different from point to point over a surface of the wafer. At least one of a process pressure and a relative speed is gradually increased. A point (x, a_{c}) is determined as a point at which a polishing rate per unit time becomes substantially uniform at desired points in a radial direction of the wafer.

2b) Polishing is conducted in a state such that a ratio of a rotational speed of the top ring 36 to a rotational speed of the polishing table 34 is lower than 0.2. Under these conditions, relative speeds are greatly different from point to point over a surface of the wafer. At least one of a process pressure and a relative speed is sufficiently increased. The amount of a mixture or a mixing rate of a chelating agent (including a first chelating agent and a second chelating agent described later), an oxidizer, a dispersant, an abrasive dispersion liquid, and pure water to be added into the mixture is varied near the increased point. A point (x, a_{c}) is determined as a point at which the process uniformity is not varied over a surface of the wafer.

The examples 1a), 1b), 2a), and 2b) presuppose that a temperature of an area being polished is maintained at a constant value. However, the temperature may be set as a parameter to determine a point (x, a_{c}) in FIG. 12 while a PV product, the amount of the mixture to be supplied, and a mixing rate are maintained at constant values. Further, in a composite electrolytic polishing process described later, a film on a wafer is oxidized by applying a voltage between the wafer and a cathode plate. Accordingly, a voltage is fixed at a predetermined value in the examples 1a) and 2a), and a voltage is varied in the examples 1b) and 2b).

The controller 44 includes a storage device or a storage medium having programs to control the top ring 36, the polishing table 34, a film thickness measurement device, a chemical liquid mixing system, and the like so as to achieve the aforementioned polishing process. Further, the storage device or the storage medium of the controller 44 includes information on properties of a film on a wafer, properties of abrasive particles, a dispersant, an oxidizer, a chelating agent used for polishing, a mixing rate and the amount of a mixture of these substances and pure water, properties of a polishing surface (polishing pad), and a temperature of an area being polished. When polishing is conducted according to a known recipe, the storage device or the storage medium may include information on a Preston equation corresponding to the recipe and a point (x, a_{c}) in FIG. 12. The controller 44 is operable to read the information from the storage device or the storage medium as needed and calculate to conduct polishing under conditions in the non-Preston range.

Practically, a process time for one wafer should be 2 minutes or less. Generally, an initial film thickness, i.e., a film thickness to be polished, is about 1000 nm. Accordingly, a required polishing rate is at least 500 nm/min. In the present embodiment, the chemical liquid supply nozzle 42 supplies a chemical liquid including an oxidizer that oxidizes a surface of a wafer at an oxidation rate of at least 500 nm/min. For example, hydrogen peroxide and ammonium persulfate may be used as an oxidizer.

Further, it is desirable that a chemical liquid to be supplied includes a chelating agent that can produce a complex capable of being removed at a pressure of 3.4 kPa (0.5 psi) or less by reaction with a surface of a wafer. Specifically, such a chelating agent produces a soft complex that can be removed at a pressure of 3.4 kPa (0.5 psi) or less. If a produced complex is not soft, an inclination of a polishing rate becomes greater in the Preston range shown in FIG. 12. Accordingly, polishing can be conducted under a lower pressure. Particularly, if polishing can be conducted at a pressure of 3.4 kPa (0.5 psi) or less, a low-k material having a low mechanical strength can be processed without any damage.

In the present embodiment, the controller 44 adjusts a pressure to press the wafer W against the polishing surface 32 by the vertical movement mechanism 54 so as to be 3.4 kPa (0.5 psi) or less. Further, the controller 44 controls a rotational speed of the top ring 36 rotated by the motor 52 and a rotational speed of the polishing table 34 rotated by the motor 46. The top ring 36 may have a rotational speed of 20 min⁻¹ or less, preferably 10 min⁻¹ or less, more preferably 5 min⁻¹ or less. Further, the rotation of the top ring 36 may be stopped during polishing. The top ring 36 may be rotated passively by frictional forces applied from the rotating polishing table 34. When an edge portion of the wafer W is to be polished, directions of friction against the polishing surface 32 are important in view of uniformity of polishing and reduction of scratches. Friction in various directions is effective. Accordingly, it is desirable that the top ring 36 is rotated to a certain degree. The top ring 36 may have a rotational speed of 10 min⁻¹ or less, preferably 5 min⁻¹ or less.

In order to readily replace a chemical liquid, it is desirable that the polishing table 34 have a high rotational speed, e.g., 100 min⁻¹ or more. It is desirable a ratio of a rotational speed of the polishing table 34 to a rotational speed of the top ring 36 is at least 5. It is desirable to adjust rotational speeds of the top ring 36 and the polishing table 34 so that a relative speed between the polishing surface 32 and the center of the wafer W is at least 1.7 m/s. Further, a rotational direction of the top ring 36 may be opposite to a rotational direction of the polishing table 34.

In the present embodiment, a chemical liquid adjustment mechanism adjusts the amount, composition, concentration, temperature of a chemical liquid to be supplied from the chemical liquid supply nozzle 42. The controller 44 controls the vertical movement mechanism 54 so as to adjust a pressure to press the wafer W. The controller 44 also controls the motors 52 and 46 so as to adjust rotational speeds (relative speed) of the top ring 36 and the polishing table 34. Thus, polishing can be conducted under conditions in the non-Preston range. As described above, uniform polishing in the non-Preston range can be achieved by use of a proper chemical liquid, a proper pressure, and a proper relative speed. Accordingly, while a rotational speed of the top ring 36 can be maintained at a low value, a polishing liquid can be introduced into a central area of the wafer W.

Further, even if a pressure applied to the wafer W is varied, uniform polishing can be achieved in the non-Preston range. Accordingly, it is not necessary to provide a plurality of pressure chambers on a surface of the top ring 3 6 which holds the wafer W so as to control pressures applied to the wafer W in a plurality of zones. Thus, only an air bag having a single pressure chamber can be provided on a surface of the top ring 36 which holds the wafer W.

The polishing table 34 has a measurement device for measuring a state of the surface of the wafer W. Specifically, as shown in FIG. 10, the polishing table 34 includes a film thickness measurement device 56 embedded therein for measuring a thickness of a film formed on the wafer W. The film thickness measurement device 56 may comprise an optical monitor for applying light to the wafer W to measure a film thickness of the wafer W, an eddy-current monitor for detecting an eddy current produced in the wafer W to measure a film thickness of the wafer W, a torque detection monitor for detecting rotation torque of the polishing table 34 to measure a film thickness of the wafer W, or an ultrasonic sensor for applying an ultrasonic wave to the wafer W to measure a film thickness of the wafer W.

For example, in the case where an optical monitor is used as the film thickness measurement device 56, a light-emitting element and a light-receiving element are provided in the film thickness measurement device 56. Light is applied to the surface of the wafer W from the light-emitting element. The light-receiving element receives light reflected from the surface of the wafer W. When the conductive film (Cu film) of the wafer W becomes a thin film having a certain thickness, a portion of light applied from the light-emitting element to the surface of the wafer W permeates the conductive film. Thus, reflected light includes light reflected from the oxide film (SiO₂) below the conductive film and light reflected from the surface of the conductive film. The light-receiving element receives and processes these two types of reflected light to measure the film thickness of the wafer W. Further, not only monochromatic light, but also light having a plurality of wavelengths such as white light may be used. In a case of light having a plurality of wavelengths, measurement can be performed for each wavelength. Films (materials) having various optical properties can be measured by such an optical monitor.

A thickness of the film to be polished is calculated from the film thickness detected by the film thickness measurement device 56. Based on the thickness of the film to be polished, the controller 44 adjusts the amount, concentration and temperature of a chemical liquid to be supplied from the chemical liquid supply nozzle 42 so that a polishing rate is equal to 500 nm/min. The film thickness measurement device 56 may be employed as an endpoint monitor for detecting an endpoint of polishing. Further, not only the film thickness measurement device 56, but also an analyzer for analyzing a used chemical liquid or a temperature measurement device for measuring a temperature of the chemical liquid may be employed as an endpoint monitor for detecting an endpoint of polishing. The controller 44 adjusts the amount of the chemical liquid to be supplied from the chemical liquid supply nozzle 42 to the polishing surface 32 so as to maintain a predetermined amount of chemical liquid. Thus, the controller 44 also serves as a liquid adjustment mechanism for maintaining a predetermined amount of chemical liquid supplied from the chemical liquid supply nozzle 42 to the polishing surface 32 during polishing.

In the present embodiment, temperatures of the polishing table 34 and a polishing liquid are adjusted so as to maintain a chemical reaction rate at a constant value. Particularly, the polishing table 34 includes components made of ceramics having high heat conductivity, such as alumina or SiC. Water pipes 60 are provided to supply water for temperature adjustment to the interior of the polishing table 34. Further, as shown in FIG. 10, a radiation thermometer 58 is disposed above the polishing table 34 to measure a surface temperature of the polishing surface 32. Output signals from the radiation thermometer 58 are transmitted into the controller 44. The radiation thermometer 58 may be used as an endpoint monitor for detecting an endpoint of polishing.

Two types of chelating agents having different rates of formation of complex may be mixed with each other. For example, a chemical liquid to be used may include a first chelating agent that produces a first complex capable of being removed at a pressure of 3.4 kPa (0.5 psi) or less and a second chelating agent that produces a second complex, which is different from the first complex. It is desirable that the second chelating agent has a stability constant of complex which is larger than the first chelating agent with respect to metal. Further, it is desirable that the produced second complex has a solubility lower than the produced first complex (intermolecular forces larger than the first complex).

Thus, two types of chelating agents produce a plurality of complexes so as to achieve uniform polishing. For example, in a case where copper is to be polished, the first chelating agent may comprise quinaldinic acid, and the second chelating agent may comprise benzotriazole. Alternatively, the first chelating agent may comprise glycine or lactic acid, and the second chelating agent may comprise quinaldinic acid. This case is suitable for use in polishing at a lower pressure because the produced complexes are unstable.

When polishing is conducted under a low pressure at a low speed, a metal surface of the wafer is covered with the second complex having larger intermolecular forces. A removal rate of the second complex is low. Further, the second chelating agent has a stability constant of complex which is larger than the first chelating agent. Accordingly, even if the first chelating agent more likely to be removed is coordinated on the metal surface, the second chelating agent is gradually substituted for the first chelating agent. Thus, the first complex cannot be formed on the metal surface of the wafer.

When a PV product is larger than a certain value, the first chelating agent is removed by friction against the polishing surface before the second chelating agent is substituted for the first chelating agent. Accordingly, polishing proceeds in a state such that the second complex having larger intermolecular forces, i.e., the second complex unlikely to be polished, is unlikely to be formed. In this case, a polishing rate is determined by a diffusion rate of the first chelating agent into the metal surface and a reaction rate of forming the first complex. Thus, since a polishing rate is determined by a diffusion rate of the first chelating agent into the metal surface, uniform polishing can be achieved irrespective of mechanical factors such as a process pressure and a relative speed unless the diffusion rate is influenced. By properly selecting types and concentrations of the second chelating agent and the first chelating agent, polishing can be achieved at an extremely low pressure of 3.4 kPa (0.5 psi) or less. A film thickness may be measured by the film thickness measurement device 56 to calculate a polishing rate and determine concentrations of the first chelating agent and the second chelating agent.

A chemical liquid mixing system for mixing a chelating agent, an oxidizer, an abrasive dispersion liquid, and pure water and supplying the mixture to the chemical liquid supply nozzle 42 will be described below. FIG. 13 is a schematic view showing an example of a chemical liquid mixing system. As shown in FIG. 13, the chemical liquid mixing system includes a plurality of abrasive dispersion liquid tanks 100 and 100 holding an undiluted abrasive dispersion liquid, an adjustment tank 102 for diluting the undiluted abrasive dispersion liquid with pure water (or a chemical liquid) to adjust a concentration of an abrasive dispersion liquid, a mixer 104 for mixing chelating agents and an oxidizer into the abrasive dispersion liquid adjusted in concentration by the adjustment tank 102 and supplying the mixture to the chemical liquid supply nozzle 42, and a chelating agent tank 106 for holding the second chelating agent and the first chelating agent and supplying a desired amount of chelating agents to the mixer 104. In FIG. 13, the chemical liquid mixing system has two abrasive dispersion liquid tanks 100 and 100.

A pure water supply line 108 is connected to the adjustment tank 102. The abrasive dispersion liquid tanks 100 and 100 and the adjustment tank 102 are connected by an abrasive dispersion liquid pipe 112 having an abrasive dispersion liquid pump 110. Each of the abrasive dispersion liquid tanks 100 has a valve 114 mounted near the abrasive dispersion liquid pump 110. The adjustment tank 102 and the mixer 104 are connected by a feed pipe 118.having a valve 116 mounted thereon. A discharge pipe 120 is connected to the adjustment tank 102 so as to branch from the feed pipe 118. The discharge pipe 120 has a discharge valve 122 mounted thereon. For example, the discharge pipe 120 and the discharge valve 122 are used to discharge a cleaning liquid when the interior of the adjustment tank 102 is cleaned. A liquid level sensor 124 is mounted on the adjustment tank 102 for measuring the amounts of the abrasive dispersion liquid and pure water.

A chelating agent supply pipe 126 extends from the chelating agent tank 106, and an oxidizer supply pipe 130 extends from an oxidizer tank 128. The chelating agent supply pipe 126 and the oxidizer supply pipe 130 are connected to the mixer 104. The chelating agent supply pipe 126 has a valve 132 mounted thereon. Chelating agent supply lines 134 and 134 are connected to the chelating agent tank 106. A chemical liquid pipe 138 is connected to the mixer 104. The chemical liquid pipe 138 has a chemical liquid supply pump 136 mounted on a discharge side of the mixer 104. The chemical liquid pipe 138 is configured to return to the mixer 104. Thus, the chemical liquid pipe 138 is formed as a circulation pipe. A pipe 140 branches from an intermediate portion of the chemical liquid pipe 138. The pipe 140 is connected via the valve 142 to the chemical liquid supply nozzle 42.

A liquid level sensor 144 is provided on an upper portion of the mixer 104 for measuring a height of a liquid level in the mixer 104. A concentration meter 146 is provided near a lower side wall of the mixer 104 for detecting a concentration of the chelating agent in the chemical liquid. For example, the concentration meter 146 may comprise a concentration meter using ultrasonic waves. Further, an overflow pipe 148 is connected to the mixer 104.

A liquid level sensor 150 is provided on an upper portion of the chelating agent tank 106. The liquid level sensor 150 measures a height of a liquid level of the chelating agent supplied to the chelating agent tank 106 through the chelating agent supply lines 134 and 134. Thus, a desired amount of chelating agent is supplied to the mixer 104.

Output signals from the liquid level sensor 144 and the concentration meter 146 are inputted into a mixing adjustment unit 152. The mixing adjustment unit 152 calculates the remaining amount of chemical liquid in the mixer 104 based on the signals from the liquid level sensor 144. Further, the mixing adjustment unit 152 calculates the amount of an undiluted chelating agent to be supplied to the mixer 104. The mixing adjustment unit 152 controls the chelating agent tank 106 and the valve 132 so as to supply a predetermined amount of the undiluted chelating agent to the mixer 104. Practically, the mixing adjustment unit 152 also controls operation of pumps and valves other than the valve 132. Thus, the mixing adjustment unit 152 controls the amounts of an oxidizer, chelating agents, an abrasive dispersion liquid, and pure water so as to prepare a chemical liquid that provides a polishing rate of 500 nm or more when a wafer is polished.

Next, operation of the chemical liquid mixing system will be described below. First, one of the valves 114 is opened, and the abrasive dispersion liquid pump 110 is operated to supply an undiluted abrasive dispersion liquid from the corresponding abrasive dispersion liquid tank 100 to the adjustment tank 102. Simultaneously, pure water is supplied through the pure water supply line 108 into the adjustment tank 102. Thus, the undiluted abrasive dispersion liquid is diluted with the pure water so as to have a predetermined concentration. In the illustrated example, a plurality of abrasive dispersion liquid tanks 100 are provided in the chemical liquid mixing system. Accordingly, even if one of the abrasive dispersion liquid tanks 100 becomes empty, a chemical liquid can continuously be supplied from the other of the abrasive dispersion liquid tanks 100 to the chemical liquid supply nozzle 42.

The abrasive dispersion liquid adjusted at a predetermined concentration in the adjustment tank 102 is supplied through the feed pipe 118 to the mixer 104 when the valve 116 is opened. A chelating agent is prepared in the chelating agent tank 106. A predetermined amount of chelating agent is supplied to the mixer 104 when the valve 132 is opened. Similarly, an oxidizer is prepared in the oxidizer tank 128 and supplied through the oxidizer supply pipe 130 to the mixer 104. Thus, these chemical liquids are mixed in the mixer 104. The prepared chemical liquid is circulated in the chemical liquid pipe 138 when the chemical liquid supply pump 136 is operated. The chemical liquid is supplied through the chemical liquid supply nozzle 42 onto the polishing surface 32 (see FIG. 10) when the valve 142 is opened at the time of polishing.

In the example shown in FIG. 13, components of the chemical liquid are mixed before introduction of the chemical liquid supply nozzle 42. However, a plurality of chemical liquid supply nozzles may be provided to mix components of the chemical liquid on the polishing surface 32. FIG. 14 is a schematic view showing a chemical liquid mixing system for individually supplying components of the chemical liquid to the polishing surface 32 and mixing the components on the polishing surface 32. A polishing apparatus shown in FIG. 14 has a plurality of chemical liquid supply nozzles 142a, 142b, 142c, and 142d. In the example shown in FIG. 14, four chemical liquid supply nozzles 142a, 142b, 142c, and 142d are provided in the polishing apparatus.

A pure water supply line 202 having a valve 200, a first abrasive dispersion liquid supply line 206 having a valve 204, and a second abrasive dispersion liquid supply line 210 having a valve 208 are connected to the chemical liquid supply nozzle 142a. An abrasive dispersion liquid circulation line 214 having a valve 212 is connected to the first abrasive dispersion liquid supply line 206. An abrasive dispersion liquid circulation line 218 having a valve 216 is connected to the second abrasive dispersion liquid supply line 210. When the valves 204 and 208 are opened while the valves 212 and 216 are closed, an abrasive dispersion liquid is supplied from the chemical liquid supply nozzle 142a onto the polishing surface 32. In a case where no abrasive dispersion liquid is to be supplied onto the polishing surface 32, the valves 204 and 208 are closed while the valves 212 and 216 are opened. Thus, the abrasive dispersion liquid can be returned to the exterior of the system and circulated.

The pure water supply line 202 is connected via a valve 220 to the chemical liquid supply nozzle 142b. When the valve 220 is opened, pure water is supplied through the chemical liquid supply nozzle 142b onto the polishing surface 32. A first chelating agent supply line 224 having a valve 222 and a second chelating agent supply line 228 having a valve 226 are connected to the chemical liquid supply nozzle 142c. When the valves 222 and 226 are opened, a first chelating agent and a second chelating agent are supplied through the chemical liquid supply nozzle 142c onto the polishing surface 32. An oxidizer supply line 232 having a valve 230 is connected to the chemical liquid supply nozzle 142d. When the valve 230 is opened, an oxidizer is supplied through the chemical liquid supply nozzle 142d onto the polishing surface 32.

Thus, in the example shown in FIG. 14, an abrasive dispersion liquid, pure water, a chelating agent, and an oxidizer are supplied through the respective chemical liquid supply nozzles 142a, 142b, 142c, and 142d onto the polishing surface 32 and mixed with each other on the polishing surface 32. After completion of polishing, pure water may be used instead of the abrasive dispersion liquid to polish or clean a wafer. In this case, only the valve 220 is opened to supply only pure water onto the polishing surface 32 while the valves 200, 204, 208, 222, 226, and 230 on the other supply lines are closed. Further, when the valve 200 is opened, the inside of the chemical liquid supply nozzle 142a can be cleaned with pure water so that an abrasive dispersion liquid is not dried and solidified in the chemical liquid supply nozzle 142a. This cleaning process may be performed for a predetermined period of time after each polishing process or when the polishing apparatus awaits a subsequent process.

According to properties of components of a chemical liquid to be used, it is possible to determine which one of chemical liquid mixing systems shown in FIGS. 13 and 14. Further, in the chemical liquid mixing system shown in FIG. 13 or 14, a mixing rate of components in the chemical liquid may be changed according to measurement results of an endpoint monitor such as the film thickness measurement device 56 or time. For example, a polishing state of the wafer W is measured during polishing by the film thickness measurement device 56, and a mixing rate of components in the chemical liquid may be changed into an optimal value. Further, a mixing rate of components in the chemical liquid may be changed at each CMP process. At that time, a polishing pressure or a relative speed between the polishing surface 32 and the wafer W may be changed by the controller 44 so as to change polishing conditions from the non-Preston range into the Preston range.

If an oxidation rate is known, variations of the film thickness are measured by the film thickness measurement device 56 to calculate a polishing rate. By monitoring variations of the polishing rate, a threshold value (x in FIG. 12) for the non-Preston range can be detected. Accordingly, a relative speed of the central area of the wafer W can be determined based on the threshold value. While a polishing rate is monitored, a relative speed between the wafer W and the polishing surface 32 may slightly be varied. At that time, when variations of the polishing rate are small, it can be confirmed that polishing is conducted under conditions in the non-Preston range. For example, when variations of the polishing rate are within a tolerance, it can be confirmed that polishing is conducted under conditions in the non-Preston range. According to this method, when controllability of the concentration of the chemical liquid is deteriorated, it can be confirmed that polishing is conducted under conditions in the non-Preston range.

In the chemical liquid mixing system shown in FIG. 13 or 14, types or concentration of components in the chemical liquid may be changed. When polishing is conducted under conditions in the non-Preston range, it is desirable to use a chemical liquid having a high etching capability. For example, in a case where a different type of material is exposed after a copper surface has been polished, when a chemical liquid having a high etching capability is used, dishing in which polishing amounts of a copper pattern are different between the central area and the pattern edge area is likely to be caused. Accordingly, it is necessary to change types or concentration of components in the chemical liquid. At that time, since a water soluble complex of the first chelating agent is unnecessary, the concentration of the first chelating agent may be lowered, or supply of the first chelating agent may be stopped. Further, when there is provided a supply system of a chemical liquid and an abrasive dispersion liquid suitable for processing different types of materials, the different types of materials can be processed with this supply system.

From the viewpoint of supply, discharge, replacement of the chemical liquid, it is desirable that the polishing pad forming the polishing surface 32 has a plurality of concentric grooves or a helical groove. Further, when the polishing table 34 is rotated at a high speed, the chemical liquid may flow out of the polishing table 34 due to centrifugal forces so as to inhibit uniform processing. Accordingly, a polishing pad having one or more grooves is effective in such a case. Further, from the viewpoint of holding the chemical liquid, it is desirable that the polishing table 34 has concentric grooves or a helical groove. It is desirable that the polishing pad is made of a material having properties effective in holding the chemical liquid or a hydrophilic material.

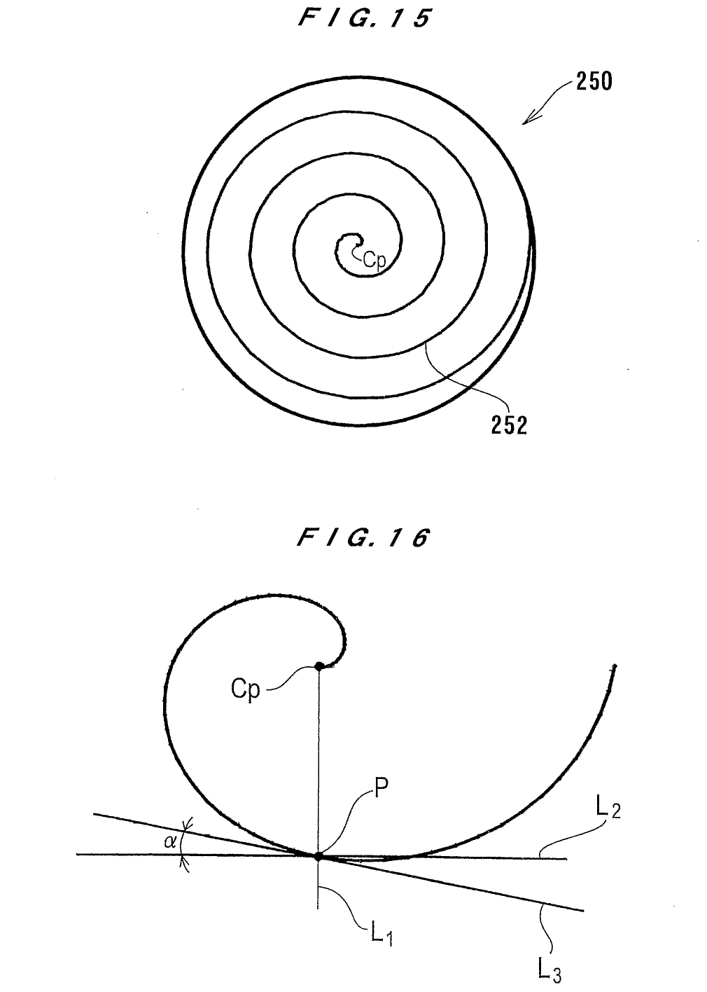

FIG. 15 is a plan view showing an example of the polishing pad 250 having a helical groove 252, and FIG. 16 is an enlarged view of the polishing pad 250 shown in FIG. 15. The polishing pad 250 shown in FIG. 15 has a helical groove 252 represented by an Archimedean spiral. An Archimedean spiral has a line defined by
X=a×T×cos(T)
Y=a×T×sin(T)
where a is a desired constant.

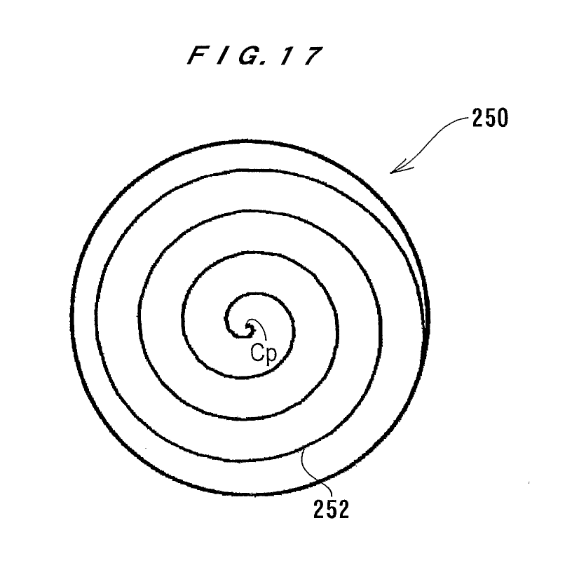

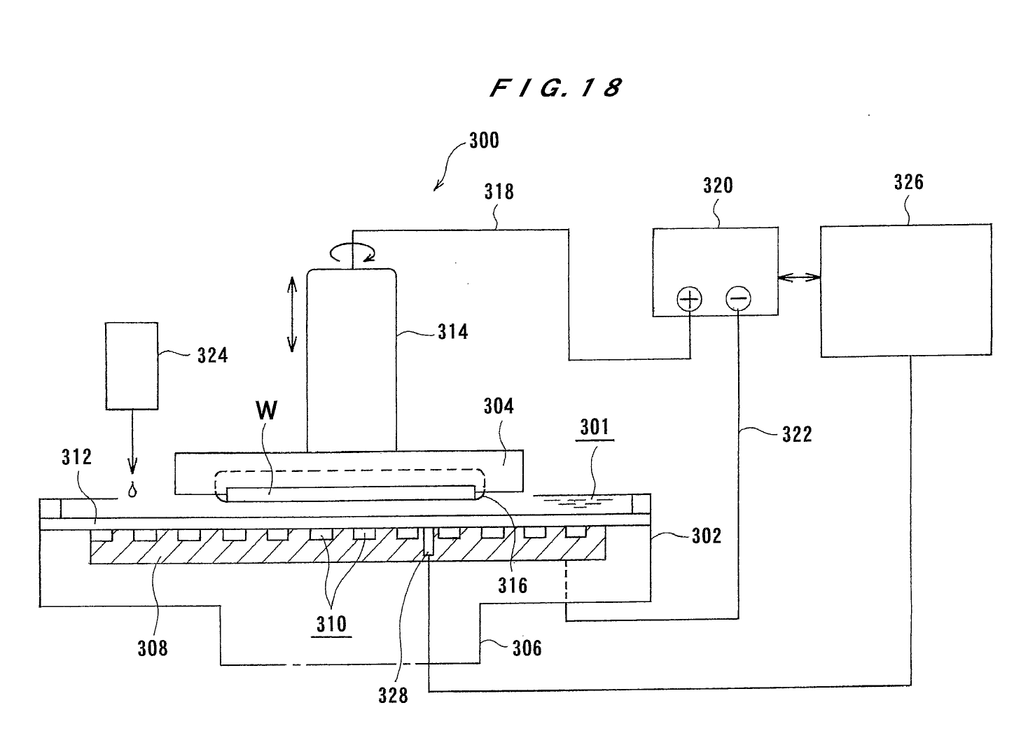

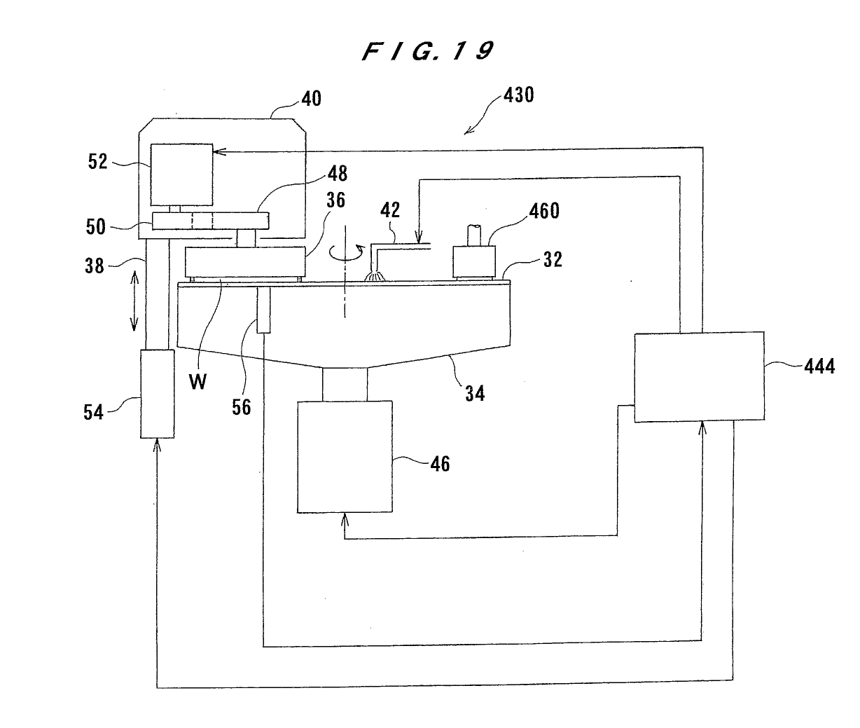

In order to hold the chemical liquid, it is desirable that the helical groove 252 has a shape close to concentric circles. As shown in FIG. 16, it is desirable that an angle α between a line L₂ perpendicular to a line L₁ interconnecting a desired point P on the helical groove 252 and a center C_{P} of the polishing pad 250 and a tangential line L₃ of the helical groove 252 at the point P is not more than 30°. For example, when α=10° and a radius of the polishing pad 250 is 400 mm, then a=70.5. FIG. 15 shows a helical groove of α=3°. Further, it is desirable that the helical groove 252 extends in a direction opposite to a direction of rotation of the polishing table 34 as shown in FIG. 17.

Although FIGS. 15 through 17 show Archimedean spirals, the helical groove 252 may be formed by a logarithmic spiral. Generally, Archimedean spirals are desirable for the helical groove in the polishing pad. Nevertheless, equiangular spirals may be used. Equiangular spirals are spirals having a constant angle between a line interconnecting a desired point on a spiral and the center of the polishing pad and a tangential line of the spiral (Bernoulli spirals). In Bernoulli spirals, intervals between spirals are increased at an outer portion. A Bernoulli spiral has a line defined by
X=a×exp(bT)×cos(T)
Y=a×exp(bT)×sin(T)
where a and b are desired constants.

With regard to a Bernoulli spiral, it is also desirable that an angle between a line L₂ perpendicular to a line L₁ interconnecting a desired point on the spiral and a center of the polishing pad and a tangential line of the spiral at the desired point is not more than 30°. In this case, the constant b may be a function of T. Although FIGS. 15 and 16 show a clockwise helical groove, a counterclockwise helical groove as shown in FIG. 17 may be used according to process conditions. Further, the polishing pad may have a plurality of helical grooves.

FIG. 18 is a schematic view showing a polishing apparatus 300 according to a second embodiment of the present invention. The polishing apparatus 300 perform a composite electrolytic polishing process. The polishing apparatus 300 has a cylindrical electrolytic cell 302 having a bottom and a top ring 304 disposed above the electrolytic cell 302. The electrolytic cell 302 has an opening at an upper portion thereof and holds an electrolytic solution 301 therein. The top ring 304 detachably holds a semiconductor wafer W in a state such that the semiconductor wafer W faces downward. The electrolytic solution 301 may comprise a chemical liquid including an oxidizer, a chelating agent, and abrasive particles.

The electrolytic cell 302 is coupled directly to the main shaft 306, which is rotated by a rotation mechanism such as a motor. A cathode plate (electrode) 308 is disposed horizontally at a lower portion of the electrolytic cell 302 and immersed in the electrolytic solution 301. The cathode plate 308 may be made of metal that is stable to the electrolytic solution and is not passivated by electrolysis, such as stainless, Pt/Ti, Ir/Ti, Ti, Ta, or Nb. An upper surface of the cathode plate 308 has long grooves 310 extending in longitudinal and transverse directions along the entire lengths of the upper surface. Thus, the long grooves 310 are formed in a grid pattern. Further, a polishing surface 312 is attached onto the upper surface of the cathode plate 308. The polishing surface 312 may be formed by a hard polishing pad of continuous foam and non-woven fabric (e.g. SUBA800™ of Rodel Nitta Company).

The electrolytic cell 302 is rotated integrally with the polishing surface 312 according to rotation of the main shaft 306. The supplied electrolytic solution 301 flows through the long grooves 310. By-products generated by electrolysis, hydrogen gas, oxygen gas, and the like are also discharged through the long grooves 310 between the wafer W and the polishing surface 312 to the exterior of the electrolytic cell 302.

In the example shown in FIG. 18, the electrolytic cell 302 is rotated. However, the electrolytic cell 302 may make a scroll movement (translational rotation movement) or a reciprocation movement. Further, when the electrolytic cell 302 makes a scroll movement, it is desirable that the long grooves 310 are formed in a grid pattern so as to prevent a difference of a current density between a central area and an outer area of the cathode plate 308 and to allow the electrolytic solution or hydrogen gas to smoothly flow through the long grooves 310. When the electrolytic cell 302 makes a reciprocation movement, it is desirable that the long grooves 310 are parallel to a direction of reciprocation.

The top ring 304 is coupled to a lower end of a support rod 314. The top ring 304 attracts the wafer W on a lower surface thereof by, for example, vacuum suction. The support rod 314 has a rotation mechanism to rotate the top ring 304 and a press mechanism to press the top ring 304 against the polishing surface 312 under a predetermined pressure.

An electric contact 316 is provided at a peripheral portion on a lower surface of the top ring 304. The electric contact 316 is brought into contact with a peripheral portion or a bevel portion of the wafer W so that a copper film formed on a surface of the wafer W serves as an anode when the wafer W is attracted and held by the top ring 304. The electric contact 316 is connected via a roll sliding connector mounted in the support rod 314 and a wire 318 to an anode terminal of a DC pulse power source 320. The cathode plate 308 is connected via a wire 322 to a cathode terminal of the power source 320. The power source 320 applies a low voltage. For 8-inch wafers, the power source 320 may have a capacity of 15 V -20 A. For 12-inch wafers, the power source 320 may have a capacity of 15 V-30 A. The power source 320 applies a voltage between the wafer W and the cathode plate 308 to oxidize a surface of the wafer W at a predetermined reaction rate.

Further, the polishing apparatus 300 has an electrolytic solution supply mechanism 324 disposed above the electrolytic cell 302. The electrolytic solution supply mechanism 324 supplies the electrolytic solution 301 between the cathode plate 308 in the electrolytic cell 302 and the wafer W. The polishing apparatus 300 includes a controller 326 for controlling and managing components in the polishing apparatus 300 and operation thereof and a safety device (not shown). The controller 326 is connected to the rotation mechanism and the press mechanism in the support rod 314, the rotation mechanism coupled to the main shaft 306, and the power source 326. The controller 326 is operable to control rotational speeds of the top ring 304 and the electrolytic cell 302, a pressure of the wafer W against the polishing surface 312, and a voltage applied between the wafer W and the cathode plate 308.

The cathode plate 308 has a measurement device for measuring a state of the surface of the wafer W. Specifically, as shown in FIG. 18, the cathode plate 308 includes a film thickness measurement device 328 embedded therein for measuring a thickness of a film formed on the wafer W. The film thickness measurement device 328 may comprise an optical monitor for applying light to the wafer W to measure a film thickness of the wafer W, an eddy-current monitor for detecting an eddy current produced in the wafer W to measure a film thickness of the wafer W, a torque detection monitor for detecting rotation torque of the electrolytic cell 302 to measure a film thickness of the wafer W, or an ultrasonic sensor for applying an ultrasonic wave to the wafer W to measure a film thickness of the wafer W.

An electrolytic solution 301 is supplied into the electrolytic cell 302. While the electrolytic solution 301 overflows the electrolytic cell 302, the electrolytic cell 302 and the polishing surface 312 are integrally rotated at a rotational speed of, for example, about 90 min⁻¹. A wafer W plated with copper is attracted and held by the top ring 304 so that the wafer W faces downward. At that time, while the wafer W is rotated in a direction opposite to a direction of rotation of the electrolytic cell 302 at, for example, about 90 min⁻¹, the wafer W is lowered to bring a (lower) surface of the wafer W into contact with the polishing surface 312 under a predetermined pressure of, for example, about 300 g/cm². At the same time, a direct current or a pulse current is supplied between the cathode plate 308 and the electric contact 316 by the power source 320. For example, such a pulse current may be formed by supplying a current at a current density of about 1 to 4 A/dm² per surface area of copper on the wafer for 10×10⁻³ second and interrupting the current for 10×10⁻³ second.

A copper film on the wafer W is effectively polished and planarized at a rate higher than in a conventional polishing apparatus. For example, when copper is to be polished, a polishing process is performed by an anodic oxidation reaction to oxidize a surface of the copper due to application of a voltage from the power source 320, a complex formation reaction to produce a complex of copper from the oxidized copper with a chelating agent in the chemical liquid, and a mechanical removal process to mechanically remove the copper complex with the polishing surface.

The anodic oxidation reaction depends upon a voltage to be applied by the power source 320. Accordingly, by properly adjusting a voltage of the power source 320 with the controller 326, polishing can be conducted under conditions in a non-Preston range. For example, a voltage of the power source 320 is adjusted so that the surface of the wafer W is oxidized at an oxidation rate of 500 nm/min or more. Thus, when the controller 326 adjusts a voltage of the power source 320 and rotational speeds (relative speed) of the top ring 36 and the polishing table 34, polishing can be conducted under conditions in the non-Preston range.

As with the first embodiment, the electrolytic solution (chemical liquid) may contain two types of chelating agents having different complex formation rates. For example, the electrolytic solution may include a first chelating agent that produces a first complex capable of being removed at a pressure of 3.4 kPa (0.5 psi) or less and a second chelating agent that produces a second complex, which is different from the first complex. It is desirable that the second chelating agent has a stability constant of complex which is larger than the first chelating agent with respect to metal. Further, it is desirable that the produced second complex has a solubility lower than the produced first complex (intermolecular forces larger than the first complex).

Further, a chemical liquid mixing system using a mixer as shown in FIG. 13 or a chemical liquid mixing system to mix components on a polishing surface as shown FIG. 14 may also be employed to prepare a chemical liquid (electrolytic solution) for the polishing apparatus 300 shown in FIG. 18.

The polishing apparatus 30 shown in FIG. 10 can calculate an oxidation rate to obtain a maximum polishing rate (a_{c} in FIG. 12) by measuring variations of concentration of the chemical liquid. The polishing apparatus 300 shown in FIG. 18 can calculate a reaction rate to obtain a maximum polishing rate (a_{c} in FIG. 12) by measuring variations of current flowing through the electrolytic solution 301. Accordingly, a threshold value (x in FIG. 12) for the non-Preston range can be calculated from the maximum polishing rate and the type of the complex. Thus, a proper pressure of the wafer W or a proper relative speed can be determined to conduct polishing under conditions in the non-Preston range.

In the above embodiments, the workpiece and the polishing surface makes a single circular movement, respectively. However, a relative movement between the workpiece and the polishing surface is not limited to a single circular movement. For example, a relative movement between the workpiece and the polishing surface may be an orbital movement (scroll movement or eccentric circular movement) or a linear movement. Further, a polishing tool having a polishing surface may comprise a tool having a small diameter, and the tool may be brought into contact with a workpiece and scanned on the workpiece. In this case, the diameter of the tool may be two times or less the diameter of the workpiece. Alternatively, a polishing tool having a polishing surface may comprise a drum, and the drum may be brought into line contact with the workpiece. When the workpiece and the polishing surface make a linear movement, it is desirable that the polishing surface has parallel linear grooves extending in a direction of the linear movement. In cases of other relative movements, it is desirable that the polishing surface has parallel linear grooves extending in a direction of a relative movement.

FIG. 19 is a schematic view showing a polishing apparatus 430 according to a third embodiment of the present invention. As shown in FIG. 19, the polishing apparatus 430 includes a polishing table 34 having a polishing surface 32 attached on an upper surface thereof, a top ring 36 for holding a workpiece such as a semiconductor wafer W on a lower surface thereof, a top ring head 40 pivotable about a pivot shaft 38, a chemical liquid supply nozzle 42 which serves as a chemical liquid supply mechanism for supplying a chemical liquid (polishing liquid) onto the polishing surface 32, and a controller 44 for controlling operation of the polishing apparatus 30. The polishing surface 32 on the polishing table 34 is generally formed by resin of polyurethane foam, a fixed abrasive, or an impregnated abrasive.

The polishing table 34 is coupled to a motor 46 located below the polishing table 34 and rotated by the motor 46. Thus, the motor 46 serves as a rotation mechanism to rotate the polishing table 34 and the polishing surface 32. The top ring 36 is coupled via timing belt pulleys 48 and 50 to a motor 52 located in the top ring head 40 and rotated by the motor 52. Thus, the motor 52 serves as a rotation mechanism to rotate the top ring 36.

The motors 46 and 52 are connected to the controller 444, which controls rotational speeds of the polishing table 34 and the top ring 36 at desired values. Thus, the motors 46 and 52 serve as a drive mechanism to move the polishing surface 32 and the wafer W held by the top ring 36 relative to each other at a desired relative speed.

Further, the pivot shaft 38 is coupled to a vertical movement mechanism 54. Thus, the top ring head 40 and the top ring 36 are vertically moved by the vertical movement mechanism 54. The vertical movement mechanism 54 is connected to the controller 444, which controls a pressure to press the wafer W held by the top ring 36 against the polishing surface 32 at a desired value. Thus, the vertical movement mechanism 54 serves as a press mechanism to press the wafer W held by the top ring 36 against the polishing surface 32 under a desired pressing pressure.

In the present embodiment, a chemical liquid (polishing liquid) supplied from the chemical liquid supply nozzle 42 includes an abrasive dispersion liquid in which abrasive particles such as metal oxides (silica, ceria, zirconia, and the like) or polymeric materials are dispersed into pure water, an oxidizer such as a hydrogen peroxide solution or ammonia for oxidizing copper, and a chelating agent for producing a complex of oxidized copper. A dispersant may be added to the abrasive dispersion liquid as needed. The chemical liquid supply nozzle 42 is connected to the controller 444, which controls the amount, concentration, and temperature of a chemical liquid to be supplied. A dispersant, a selectivity adjustor, or an anticorrosive may be added to the chemical liquid in addition to the aforementioned abrasive dispersion liquid, oxidizer, and chelating agent. The abrasive particles are properly selected according to properties or structures of the polishing surface.

For example, when a film having a thickness of 500 nm or more is to be polished, a polishing process is performed by oxidation of the film, complex formation of the film, and removal of the complex. Accordingly, polishing by-products such as abrasive particles, polishing wastes, and complexes are continuously generated on the polishing surface 32. Thus, a large amount of polishing by-products is attached to the polishing surface 32. When a large amount of polishing by-products is attached to the polishing surface 32, properties of the polishing surface 32 is changed so as to degrade polishing performance of the polishing surface 32. Accordingly, in order to achieve stable polishing, it is necessary to stabilize performance (properties) of the polishing surface 32.

In order to prevent performance of the polishing surface 32 from changing during polishing, the following methods are effective. For example, the polishing surface 32 may be made large in size to reduce the amount of by-products attached per unit area. Alternatively, one or more grooves may be formed in the polishing surface 32 to discharge by-products. A chemical liquid may be applied to the polishing surface 32 to prevent by-products from being attached to the polishing surface 32. A conditioner may be provided to condition the polishing surface 32 so as to remove by-products from the polishing surface 32.

In the present embodiment, as shown in FIG. 19, the polishing apparatus 430 has a mechanical conditioner 460 for removing by-products from the polishing surface 32. The conditioner 460 has a conditioning member attached on a lower surface thereof. The conditioning member is pressed against the polishing surface 32 to remove by-products from the polishing surface 32. Thus, the conditioner 460 removes polishing by-products attached to the polishing surface 32 and flattens the entire polishing surface 32. As described below, a chemical conditioner using dissolution or an electrochemical conditioner using electrolysis or electrification may be employed instead of a mechanical conditioner.

As described above, under conditions in a non-Preston range, uniform polishing can be achieved in a state such that a rotational speed of the top ring 36 is reduced while a rotational speed of the polishing table 34 is increased. In the present embodiment, the conditioner 460 conditions the polishing surface 32 during polishing under conditions in a non-Preston range (in-situ conditioning).

Generally, a conditioner for conditioning a polishing surface is rotated at a rotational speed 0.5 to 2 times a rotational speed of a polishing table to flatten the polishing surface. As described above, the polishing table 34 is rotated at a high speed during polishing under conditions in a non-Preston range. In order to conduct in-situ conditioning, the conditioner 460 should be rotated at a speed 1 to 2 times as high as a rotational speed of the polishing table 34. However, if the conditioner 460 is rotated at a high speed, the amount of polishing surface 32 removed by the conditioner 460 may be increased so as to shorten a lifetime of the polishing surface 32. Further, it is difficult to control flatness or surface roughness of the polishing surface 32.

For example, when the conditioner 460 is rotated at a high speed, the amount of removal of the polishing surface 32 may be increased near a centrode of the conditioner 460 so that the polishing surface 32 becomes recessed. If the polishing surface 32 is recessed, a surface pressure at an inner area of the semiconductor wafer pressed against a recessed portion of the polishing surface 32 may be lowered so that polishing cannot be conducted under conditions in a non-Preston range. Further, when the semiconductor wafer includes a device structure having a low mechanical strength, the device structure may be broken at a peripheral portion of the semiconductor wafer because of a high surface pressure.

Accordingly, it is necessary to prevent the conditioner 460 from excessively removing the polishing surface 32. For example, a rotational speed of the conditioner 460 is reduced as compared to a rotational speed of the polishing table 34. Alternatively, a conditioner having a considerably low removal rate is used as the conditioner 460.

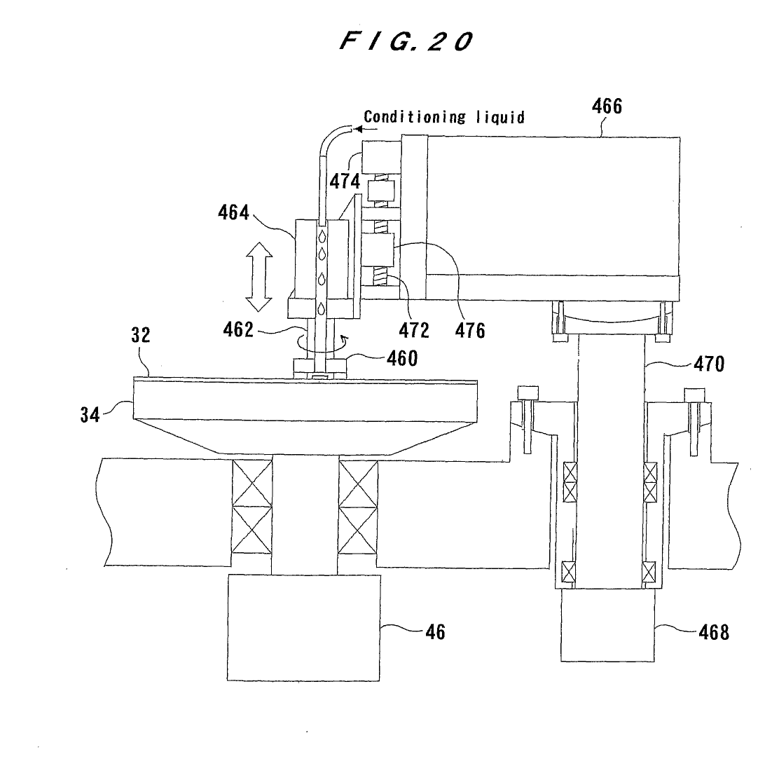

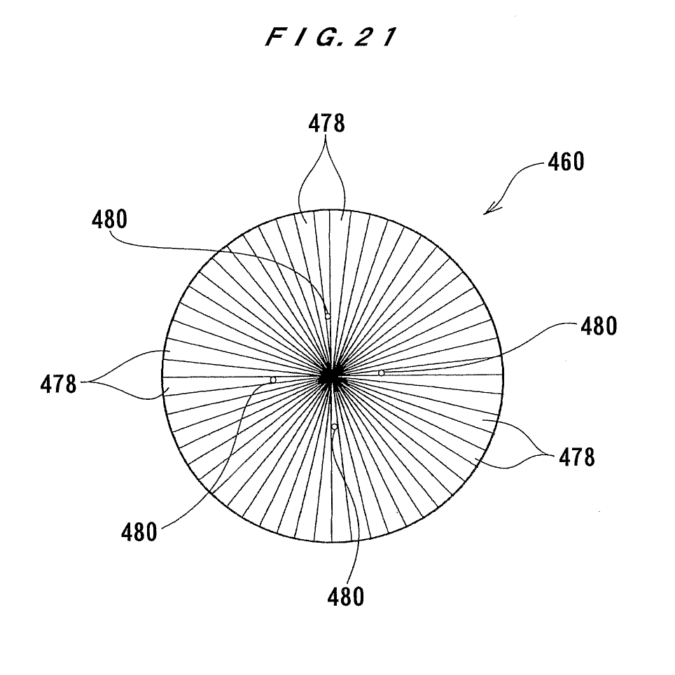

FIG. 20 is a schematic view showing a structure of the conditioner 460. In the present embodiment, the conditioner 460 comprises a disk conditioner having a small diameter of 40 to 125 mm. As shown in FIG. 20, a hollow shaft 462 is attached to the conditioner 460. The hollow shaft 462 is coupled to a motor 464. Thus, the conditioner 460 is rotated by the motor 464.

The hollow shaft 462 is attached to a conditioner head 466, which is mounted on an upper end of a pivot shaft 470. The pivot shaft 470 is rotated by a motor 468. The conditioner 460 is horizontally moved by the motor 468. Thus, the motor 468, the pivot shaft 470, and the conditioner head 466 serve as a swing mechanism for swinging the conditioner 460 above the polishing surface 32.

The conditioner head 466 has a ball screw 472 for adjusting a vertical position of the conditioner 460 and a motor 474 for rotating the ball screw 472. A nut 476 is mounted on an upper end of the hollow shaft 462 and threaded with the ball screw 472. Thus, the conditioner 460 is vertically moved by the motor 474. In the present embodiment, the aforementioned ball screw mechanism controls the height of the conditioner 460 so as to adjust pressing of the conditioner 460 against the polishing surface 32 (height control). A pressure to press the conditioner 460 against the polishing surface 32 may be controlled so as to adjust pressing of the conditioner 460 against the polishing surface 32 (pressure control).

For example, the conditioner 460 is moved downward by the ball screw mechanism so as to be brought into contact with the polishing surface 32. When the conditioner 460 is brought into contact with the polishing surface 32, a load is applied to the motor 464 to rotate the conditioner 460. Torque applied to the motor 464 is detected, and a downward position of the conditioner 460 to be moved is controlled based on the detected torque. Specifically, the position of the conditioner 460 is controlled so that torque to be detected becomes a predetermined threshold value. Thus, excessive removal and insufficient removal of the polishing surface 32 are prevented.

When pressing of the conditioner 460 is adjusted by height control, the polishing surface 32 can be flattened after conditioning by providing the conditioner 460 fixedly with respect to the hollow shaft 462. For example, the conditioner 460 and the hollow shaft 462 are connected to each other without any balls, and the conditioner 460 is fixed to the hollow shaft 462 in a state such that a lower surface of the conditioner 460 is substantially perpendicular to the hollow shaft 462. With this configuration, a surface to press the semiconductor wafer can be made flat. Accordingly, even if the polishing table 34 is rotated at a high speed, polishing is not inhibited by occurrence of vibration. Further, height control can also be achieved by measuring the amount of downward movement (or upward movement) of the conditioner 460 by the ball screw mechanism. Specifically, a current to drive the motor 474 (e.g., a pulse current) is monitored to control a vertical position of the conditioner 460.

FIG. 21 is a bottom view of the conditioner 460. As shown in FIG. 21, the conditioner 460 includes a plurality of sectorial conditioning members 478 having diamond attached on a lower surface thereof. The conditioning members 478 are spaced at predetermined intervals. Further, a plurality of through-holes 480 (e.g., four through-holes) are formed near a rotation center in a lower surface of the conditioner 460. The through-holes 480 are communicated with a hollow space in the hollow shaft 462. As shown in FIG. 20, a conditioning liquid (e.g., pure water (DIW) or a chemical liquid) is supplied into the hollow space in the hollow shaft 462. Thus, the conditioning liquid is supplied from the through-holes 480 of the conditioner 460 to the lower surface of conditioner 460. The conditioning liquid may be supplied from surfaces of the conditioning members 478.

In the present embodiment, the conditioner 460 has a plurality of sectorial conditioning members 478. However, conditioning members used in the conditioner 460 is not limited to the illustrated example. For example, an annular conditioning member or a disk conditioning member may be used in the conditioner 460.

The conditioner 460 is pressed against the polishing surface 32 while it is rotated. Thus, the conditioning members 478 and the polishing surface 32 are brought into sliding contact with each other to condition and flatten the polishing surface 32. At that time, it is desirable that a rotational speed of the conditioner 460 is lower than a rotational speed of the polishing table 34, preferably lower than a half of a rotational speed of the polishing table 34. For example, a pressing force of the conditioner 460 is set to be 10 N or less so as to condition the polishing surface 32 under a low pressure.

During conditioning, the conditioner 460 may be swung from a central area of the polishing surface 32 to a peripheral area of the polishing surface 32 or from the peripheral area of the polishing surface 32 to the central area of the polishing surface 32. Further, the conditioner 460 may be swung repeatedly between the central area of the polishing surface 32 and the peripheral area of the polishing surface 32. When the conditioner 460 is swung, it is desirable that a speed (swing speed) to swing the conditioner 460 is varied according to a distance between the center of the polishing surface 32 and the center of the conditioner 460 in order to condition and flatten the polishing surface 32 uniformly.

More specifically, a speed of the motor 468 is controlled so that a swing speed V of the conditioner 460 is represented by V=A×R^{(-C)} where R is a distance between the center of the conditioner 460 and the center of the polishing surface 32, and A and C are constants. The constant C is preferably in a range of 0.8 to 1.2.

Further, surface roughness of the polishing surface 32, which exerts an influence on polishing performance after conditioning, can be optimized according to the workpiece by properly adjusting a ratio of rotational speeds of the polishing table 34 and the conditioner 460, a swing speed of the conditioner 460, and the removal amount of the polishing surface 32 by the conditioner 460.

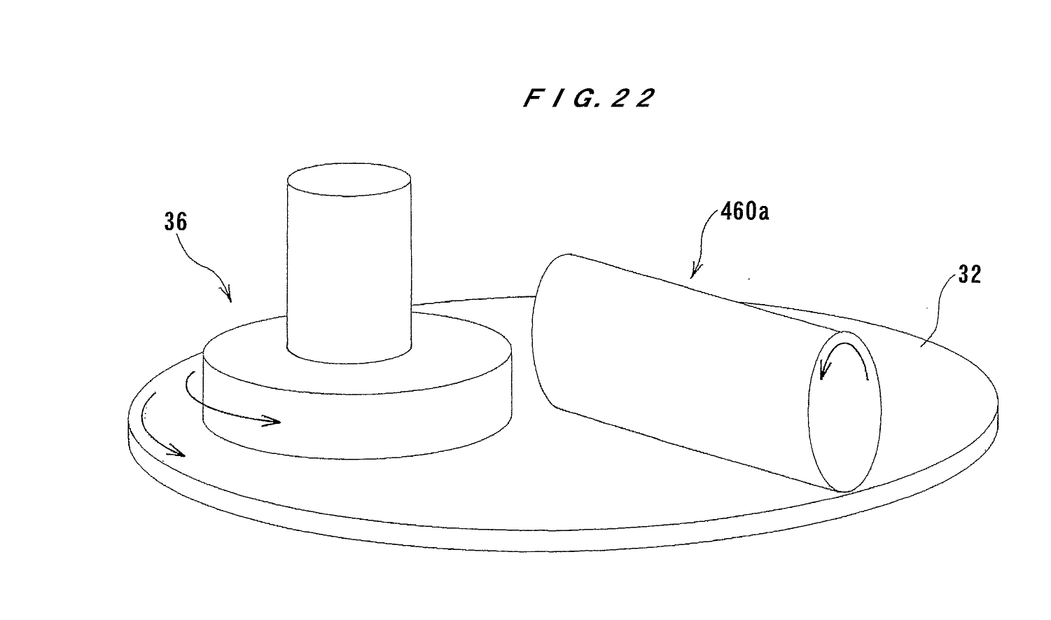

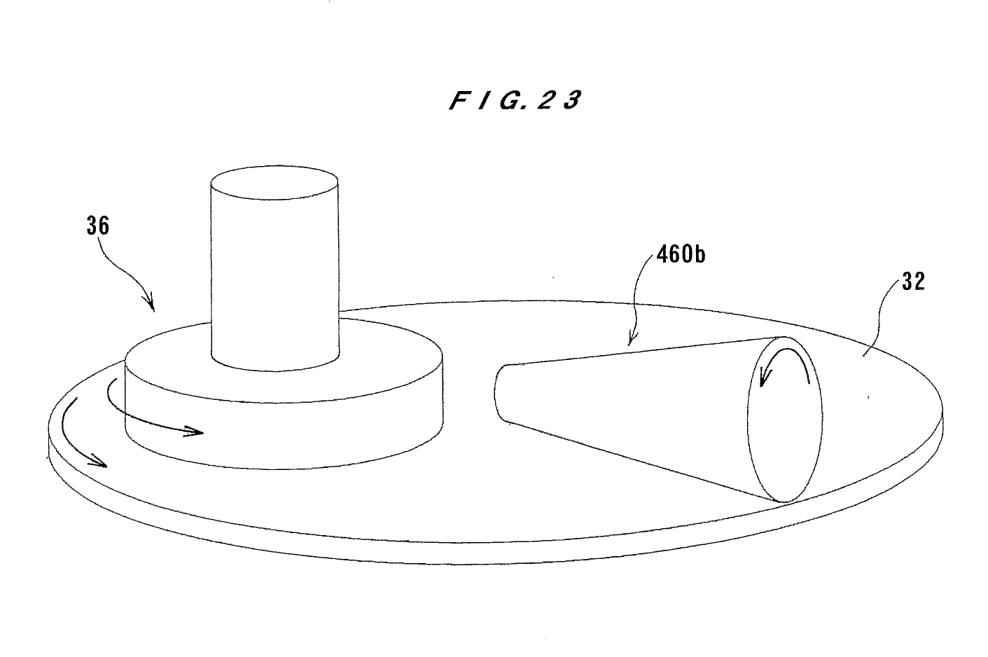

The form of the conditioner 460 is not limited to the above examples. For example, a roll-type conditioner may be used as the conditioner 460. For example, a conditioner 460a in the form of a cylinder as shown in FIG. 22, a conditioner 460b in the form of a truncated cone as shown in FIG. 23, or a conditioner in the form of a cone may be used as the conditioner 460. In these cases, abrasive particles such as diamond or brushes made of resin are attached to an outer surface of the cylinder, the cone, or the truncated cone. At that time, a rotation axis of the cylinder, the cone, or the truncated cone may be inclined with respect to the polishing surface 32. With these conditioners, the polishing surface 32 can be conditioned and flattened.

Further, the roll-type conditioner may be rotated about a rotation axis. At that time, it is desirable that a rotational speed of the conditioner is controlled so as to reduce the removal amount of the polishing surface 32. Such control of the rotational speed of the conditioner can prolong a lifetime of the polishing surface 32. For example, when a relative speed is increased at a portion of the conditioner which contacts the polishing surface 32, the removal amount is increased. When a relative speed is decreased, the removal amount is decreased. Accordingly, a rotational speed of the conditioner is properly adjusted so as to reduce a removal amount of polishing surface 32.

Further, in the case of the roll-type conditioner, conditioning may be conducted while the conditioner 460 is fixed in position with respect to the polishing surface 32. In this case, it is necessary to remove polishing wastes attached to an outer surface (conditioning surface) of the conditioner 460. The following methods may be used to remove polishing wastes attached to the conditioning surface of the conditioner 460. For example, a conditioning liquid may be supplied to the conditioning surface of the conditioner 460. Ultrasonic vibration may be applied to the conditioning surface of the conditioner 460. One or more grooves may be formed in the conditioning surface of the conditioner 460 to discharge polishing wastes. Alternatively, a portion of the conditioning surface of the conditioner 460 that is not brought into contact with the polishing surface 32 may be cleaned with water. With these configurations, conditioning can be conducted continuously.

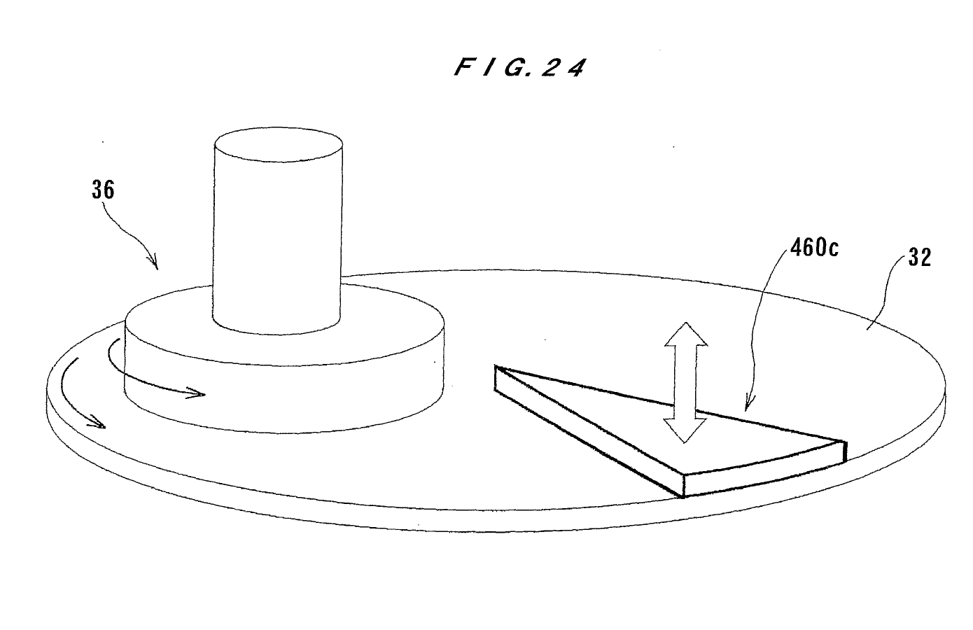

Further, a sectorial conditioner 460c as shown in FIG. 24 may be used as the conditioner 460. The sectorial conditioner 460c is disposed fixedly at a predetermined location on the polishing surface 32 and pressed against the polishing surface 32 to condition and flatten the polishing surface 32. Pressing of the sectorial conditioner 460c can be controlled by pressure control or height control. Further, a fan-shaped conditioner may be employed instead of the sectorial conditioner 460c.

The method of removing polishing by-products (e.g., complexes) on the polishing surface 32 without degraded flatness of the polishing surface 32 is not limited to the aforementioned conditioning with the mechanical conditioner. For example, a jet of pure water or a chemical liquid may be ejected to the polishing surface 32 to remove complexes. Powder of abrasive particles may be ejected to the polishing surface 32 to remove complexes. Pure water or a chemical liquid to which ultrasonic vibration is applied may be supplied to the polishing surface 32 to remove complexes. An ultrasonic transducer may be brought into contact with the polishing surface 32 to remove complexes. Solid powder of frozen water, frozen chemical liquid, or frozen slurry may be ejected to the polishing surface 32 to remove complexes. Solid powder of argon, oxygen, or carbon dioxide may be ejected to the polishing surface 32 to remove complexes. Thus, complexes may be removed by applying physical forces to the polishing surface 32. Alternatively, thermal shock may be applied to the polishing surface 32 by electromagnetic forces such as light or infrared radiation to remove complexes. Thermal shock may be applied to the polishing surface 32 by bringing a heat source into contact with the polishing surface 32 to remove complexes. In these case, it is effective to apply thermal shock after cooling a portion to which the thermal shock is to be applied, preferably down to 0 to 30° C. Further, some of the above methods may be combined with each other.

Complexes removed from the surface of the polishing surface 32 by the mechanical conditioner or the like are discharged to the exterior of the polishing table 34 according to rotation of the polishing table 34. When the polishing liquid comprises a liquid having a high viscosity, the complexes may be discharged to the exterior of the polishing table 34 by vacuuming the complexes, ejecting pure water or a chemical liquid to the polishing surface, or ejecting the aforementioned solid powder to the polishing surface 32. Further, when the complexes are electrostatically charged, an electrode may be brought close to the polishing surface 32 so as to adsorb or deposit the complexes into the electrode.

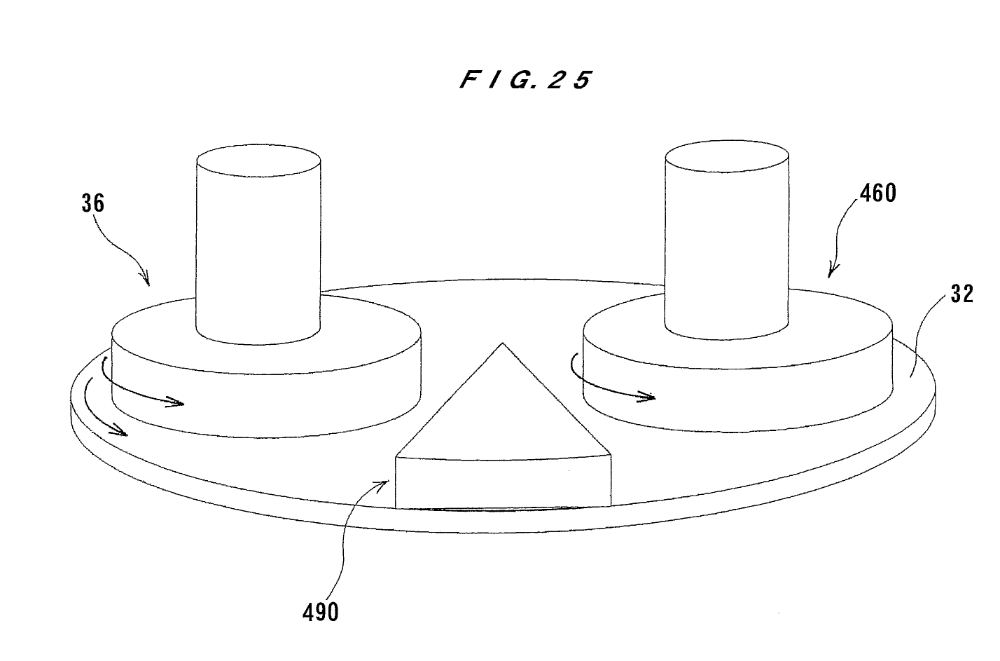

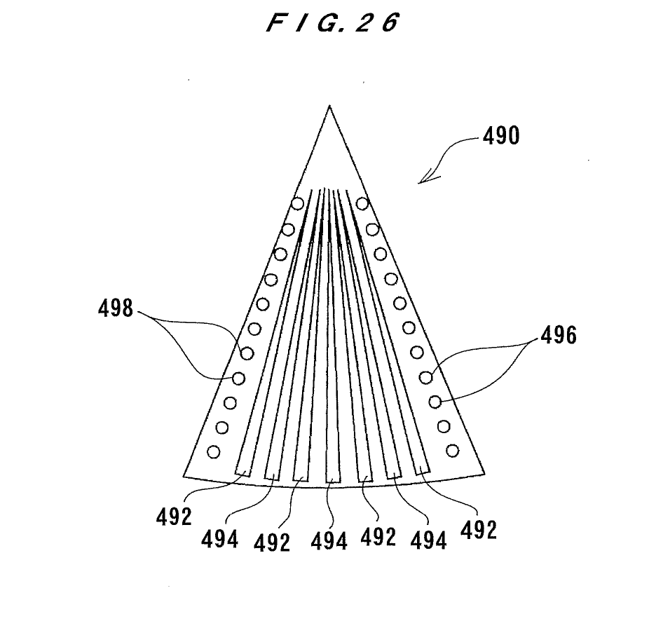

Further, as shown in FIG. 25, an ion exchange resin 490 (e.g., chelating resin) is brought into contact with the polishing surface 32 to move complexes from the polishing surface 32 to the ion exchange resin 490 by electrolysis. As shown in FIG. 26, the ion exchange resin 490 has anodes 492 and cathodes 494 alternately disposed on a lower surface thereof. The ion exchange resin 490 also includes electrolytic solution supply ports 496 disposed at an upstream side in a direction of rotation of the polishing surface 32 and electrolytic solution suction ports 498 disposed at an downstream side in the direction of rotation of the polishing surface 32. The ion exchange resin 490 is brought into contact with an area of the polishing surface 32 that is apart from a polishing area of the polishing surface 32. Thus, complexes are removed from the polishing surface 32.

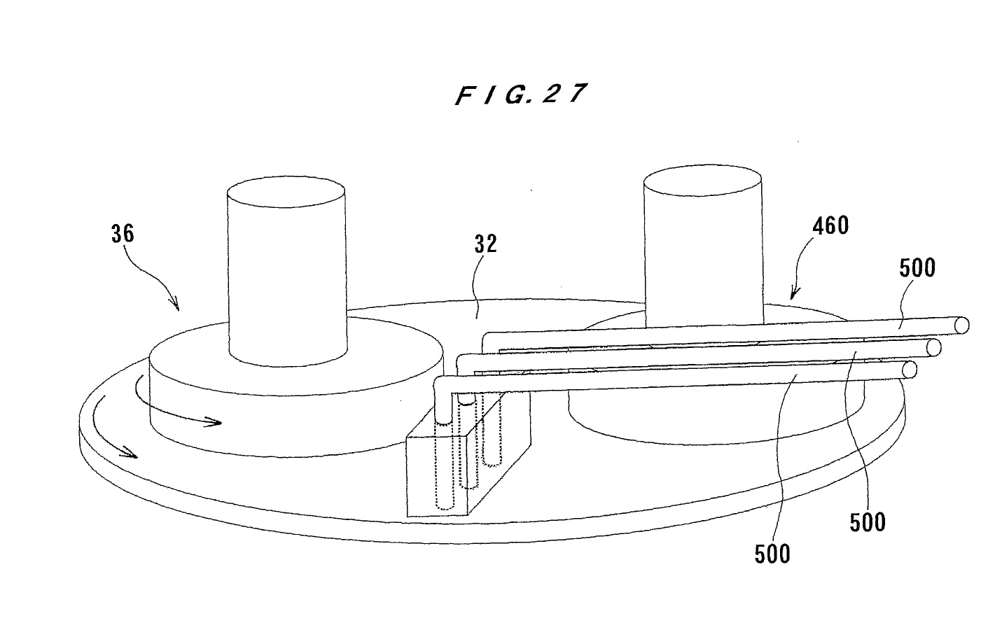

A chemical liquid may be applied to the polishing surface 32 so as to convert an insoluble complex into a soluble complex. In this case, the soluble complex can be discharged to the exterior of the polishing table 34 together with the polishing liquid and the conditioning liquid. For example, as shown in FIG. 27, a plurality of nozzles 500 may be provided for ejecting a chemical liquid to the polishing surface 32 to remove polishing by-products from the polishing surface 32. For example, when organic acid such as citric acid or oxalic acid is applied to the polishing surface 32, the above effects can be achieved.

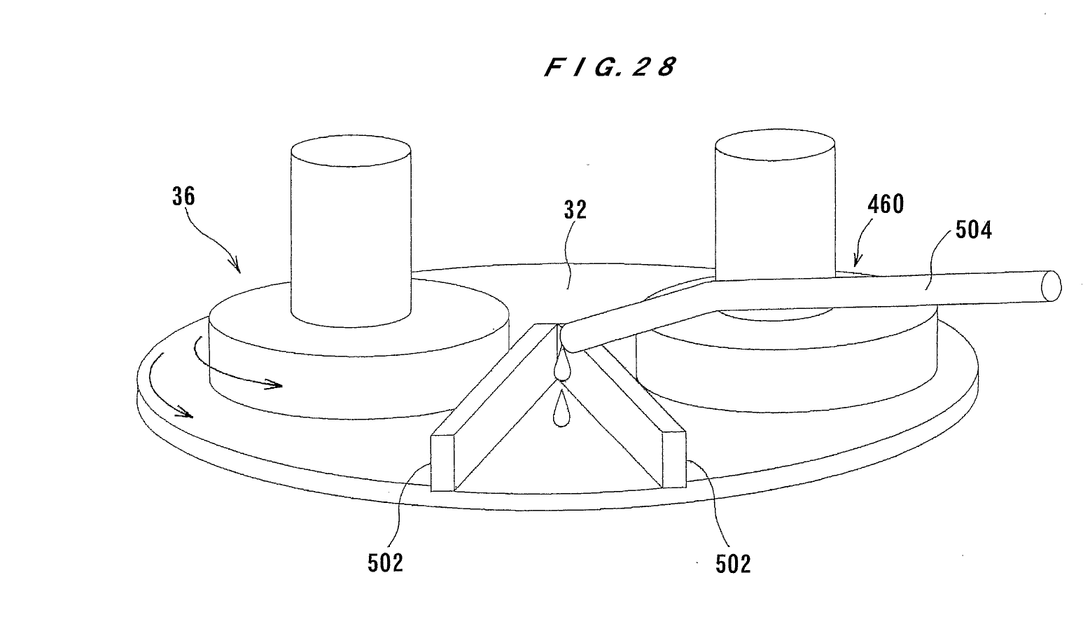

Further, a chelating agent or a chelating resin may be used as the chemical liquid. In this case, as shown in FIG. 28, two shield plates 502 are disposed on the polishing surface 32. A chelating agent or a chelating resin is supplied through a nozzle 504 to an area defined by the shield plates 502. By-products (complex) attached to the polishing surface 32 can be adsorbed into the chelating agent or the chelating resin and discharged to the exterior of the system.

The chelating agent or the chelating resin may comprise a chelating agent or a chelating resin of amino carboxylic acid, preferably iminodiacetic acid, more preferably ethylenediaminetetraacetic acid.

Chelating resin of iminodiacetic acid has a stability constant pK (25° C.) of 10.54 for chelate formation with respect to metal ions of Cu²⁺ (C. Eger, W. N. Anspach, J. A. Marinsky, J. Inorg. Nucl. Chem., 30, 1911(1968)). Such chelating resin can adsorb complexes having a stability constant smaller than 10.54 (substitution). Further, ethylenediaminetetraacetic acid (EDTA) has a stability constant pK (25° C.) of 18.83 for chelate formation with respect to metal ions of Cu²⁺ and can adsorb complexes more effectively According to properties of chelating resin (the Chemical Society of Japan, Handbook of Chemistry, volume of applied chemistry, 3rd edition, Maruzen, FIG. 10.122), it is desirable to conduct the following method in order to enhance capability of adsorption of polishing by-products and polishing performance. Conditions are changed from an acid atmosphere into a weakly acid atmosphere before a chelating resin is applied to the polishing surface 32. Then, by-products are adsorbed (substitution) into the chelating resin under the weakly acid atmosphere. Thereafter, conditions are changed into the acid atmosphere, which is suitable for polishing. It is effective to supply an oxidizer required for polishing after the chelating resin has been applied to the polishing surface 32.

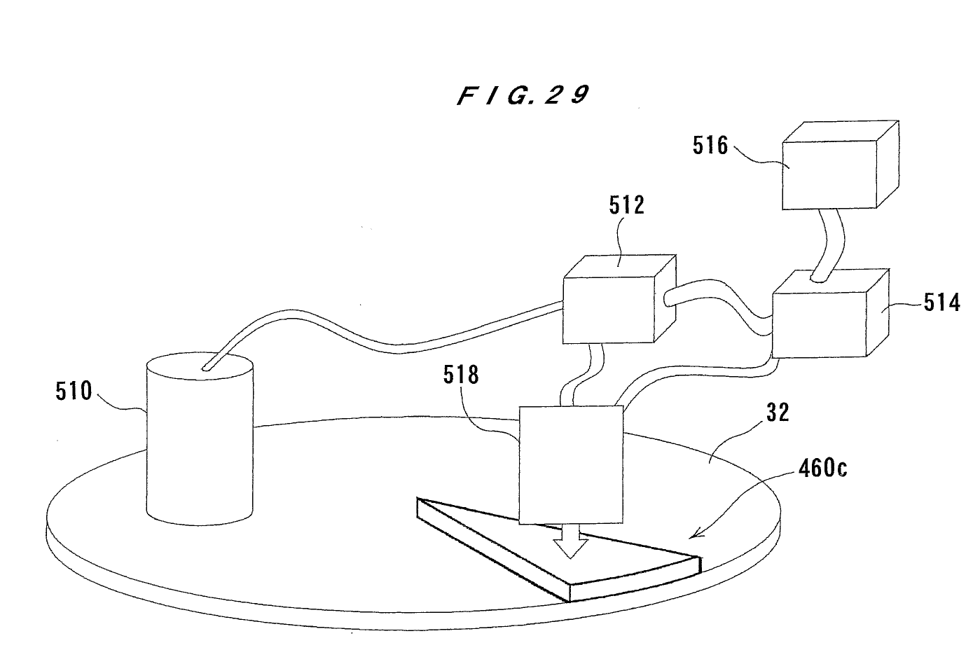

It is desirable that the amount of polishing by-products attached onto the polishing surface 32 is monitored and fed back to the aforementioned control of operation of the conditioner 460. FIG. 29 is a schematic view showing an arrangement for feed back control of the sectorial conditioner 460c shown in FIG. 24. As shown in FIG. 29, the polishing apparatus has a measurement device 510 for measuring a state of the polishing surface 32, an arithmetic processing unit 512, a process management unit 514, an input interface 516, and a conditioner controller 518 for controlling a pressing force, a rotational speed, and a height of the conditioner 460.

For example, light may be applied to the polishing surface 32 by the measurement device 510, and the reflected light may be measured so as to monitor the amount of polishing by-products attached to the polishing surface 32. Alternatively, the measurement device 510 may comprise a CCD camera for capturing an image of the polishing surface 32. The image of the polishing surface 32 is analyzed in the arithmetic processing unit 512 so as to monitor the amount of polishing by-products attached to the polishing surface 32. Alternatively, the measurement device 510 may comprise a light-receiving element for detecting variation of the amount of received light so as to monitor the amount of polishing by-products attached to the polishing surface 32.

A pressing force, a conditioning time, a swing speed, a height (position) of the conditioner 460, or rotational speeds of various motors may be subjected to feed back control. Further, in the cases of conditioners other than mechanical conditioners, it is possible to control a flow rate of the jet of pure water or a chemical liquid, the amount or an ejection pressure of abrasive particles ejected to the polishing surface 32, a frequency or output of an ultrasonic wave, the amount, an ejection pressure, or a size of powder ejected to the polishing surface 32, a temperature of a heat source to apply thermal shock, a period of time to apply thermal shock, or the like.

Thus, it is possible to control a maximum tolerance of the amount of polishing by-products attached to the polishing surface 32 or suitably control the amount of polishing by-products attached to the polishing surface 32. Accordingly, for example, properties of the polishing surface 32 can suitably be controlled so as to harden an excessively soft surface of a polishing pad.

Further, a CMP process to form copper interconnections generally includes a step height removal step, a bulk process step, a copper clear step, a barrier metal exposure step, and the like. It is desirable to control properties of the polishing surface so as to be optimal for each step.

The amount of polishing by-products attached to the polishing surface 32 may not be monitored directly. For example, a rate of polishing a wafer (polishing rate) may be monitored to estimate the amount of polishing by-products attached to the polishing surface 32. The estimated amount of polishing by-products can be fed back to the control of operation of the conditioner 460. Alternatively, a feed back control of the conditioner 460 may be performed based on a threshold value calculated by experience or a threshold value calculated from the polishing rate.

The measurement device for measuring a polishing rate of a semiconductor wafer may comprise an optical monitor for applying light to the semiconductor wafer to measure a film thickness of the semiconductor wafer. For example, a light-emitting element and a light-receiving element are provided in the measurement device. Light is applied to the surface of the semiconductor wafer from the light-emitting element. The light-receiving element receives light reflected from the surface of the semiconductor wafer. In the example shown in FIG. 19, an optical monitor 56 is embedded in the polishing table 34 for measuring a film thickness of the semiconductor wafer W.

When the conductive film (Cu film) of the semiconductor wafer becomes a thin film having a certain thickness, a portion of light applied from the light-emitting element to the surface of the semiconductor wafer permeates the conductive film. Thus, reflected light includes light reflected from the oxide film (SiO₂) below the conductive film and light reflected from the surface of the conductive film. The light-receiving element receives and processes these two types of reflected light to measure the film thickness of the semiconductor wafer. Further, not only monochromatic light, but also light having a plurality of wavelengths such as white light may be used. In a case of light having a plurality of wavelengths, measurement can be performed for each wavelength. Films (materials) having various optical properties can be measured by such an optical monitor.

Further, the measurement device for measuring a polishing rate of a semiconductor wafer may comprise an eddy-current monitor for detecting an eddy current produced in the semiconductor wafer to measure a film thickness of the semiconductor wafer, a torque detection monitor for detecting rotation torque of the polishing table 34 to measure a film thickness of the semiconductor wafer, or an ultrasonic sensor for applying an ultrasonic wave to the semiconductor wafer to measure a film thickness of the semiconductor wafer.

As described above, the amount of polishing by-products attached to the polishing surface 32 is measured or estimated and fed back to the control of operation of the conditioner 460. It is possible to control the amount of polishing by-products attached to the polishing surface 32. Such control can be applied not only to polishing under conditions in a non-Preston range, but also to polishing under conditions in a Preston range.

From the viewpoint of supply, discharge, replacement of the chemical liquid, it is desirable that the polishing pad forming the polishing surface 32 has a plurality of concentric grooves or a helical groove. Further, when the polishing table 34 is rotated at a high speed, the chemical liquid may flow out of the polishing table 34 due to centrifugal forces so as to inhibit uniform processing. Accordingly, a polishing pad having one or more grooves is effective in such a case. Further, from the viewpoint of holding the chemical liquid, it is desirable that the polishing table 34 has concentric grooves or a helical groove. It is desirable that the polishing pad is made of a material having properties effective in holding the chemical liquid or a hydrophilic material.

Further, the polishing surface 32 may be formed by the polishing pad 250 having a helical groove 252 as shown in FIG. 15. Alternatively, the polishing pad may have a helical groove of a logarithmic spiral. Generally, Archimedean spirals are desirable for the helical groove in the polishing pad. Nevertheless, equiangular spirals may be used. Equiangular spirals are spirals having a constant angle between a line interconnecting a desired point on a spiral and the center of the polishing pad and a tangential line of the spiral (Bernoulli spirals). In Bernoulli spirals, intervals between spirals are increased at an outer portion. A Bernoulli spiral has a line defined by
X=a×exp(bT)×cos(T)
Y=a×exp(bT)×sin(T)
where a and b are desired constants.

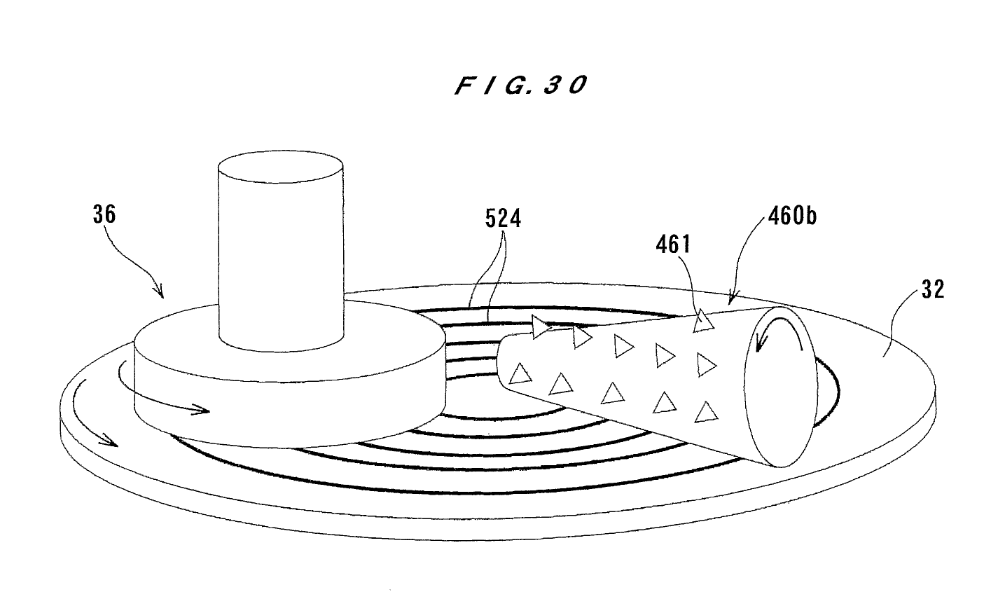

As shown in FIG. 30, when the conditioner 460b in the form of a truncated cone as shown in FIG. 23 is used, the conditioner 460b may have abrasive particles 461 such as diamond attached to an outer surface so as to form concentric grooves 524 in the polishing surface 32. With this configuration, concentric grooves 524 can be formed in the polishing surface 32 while the polishing surface 32 is being conditioned by the conditioner 460b. The abrasive particles 461 such as diamond may be arranged so as to form a helical groove in the polishing surface 32. As shown in FIG. 31, a conditioner 460d having a rod 526 and abrasive particles 461 such as diamond attached at a lower portion of the rod 526 may be used to form concentric grooves 524 or a helical groove in the polishing surface 32.

In order to condition and flatten the polishing surface 32, an area of the polishing surface 32 ranging from a central area to a holding ring of the top ring 36 for holding a semiconductor wafer may be polished at least 1 μm deeper than other areas. In this case, supply of a polishing liquid to the semiconductor wafer is facilitated without concentric grooves or a helical groove. Accordingly, the semiconductor wafer can be polished with a small amount of polishing liquid. Further, a polishing liquid likely to deteriorate can readily be used.

When a film having a thickness of 1000 nm or less is to be polished, polishing can be conducted without conditioning by the conditioner 460 because the amount of polishing by-products attached to the polishing surface during polishing is small. In this case, conditioning may be conducted by the conditioner 460 before polishing a semiconductor wafer (ex-situ conditioning). Ex-situ conditioning can be conducted in a state such that the conditioner 460 is rotated at a low rotational speed which is about 0.5 to 2 times a rotational speed of the polishing table 34. At the time of ex-situ conditioning, a large amount of polishing by-products is accumulated on the polishing surface. The aforementioned method of measuring or estimating the amount of attached polishing by-products to feed back to operation control of the conditioner 460 may be employed to enhance productivity.

Chemical reaction has a great influence on processing copper. Accordingly, processing is suppressed when the temperature is lowered. On the other hand, a barrier metal layer, which is located below a copper layer, is generally processed by a physical method. Accordingly, in a copper clear step and a barrier metal exposure step, by cooling an atmosphere in which polishing is conducted, the polishing surface 32, the polishing liquid, the semiconductor wafer W, or the top ring 36 to, for example, about 0 to 30° C., the barrier metal can be processed while dishing is prevented at copper interconnections.

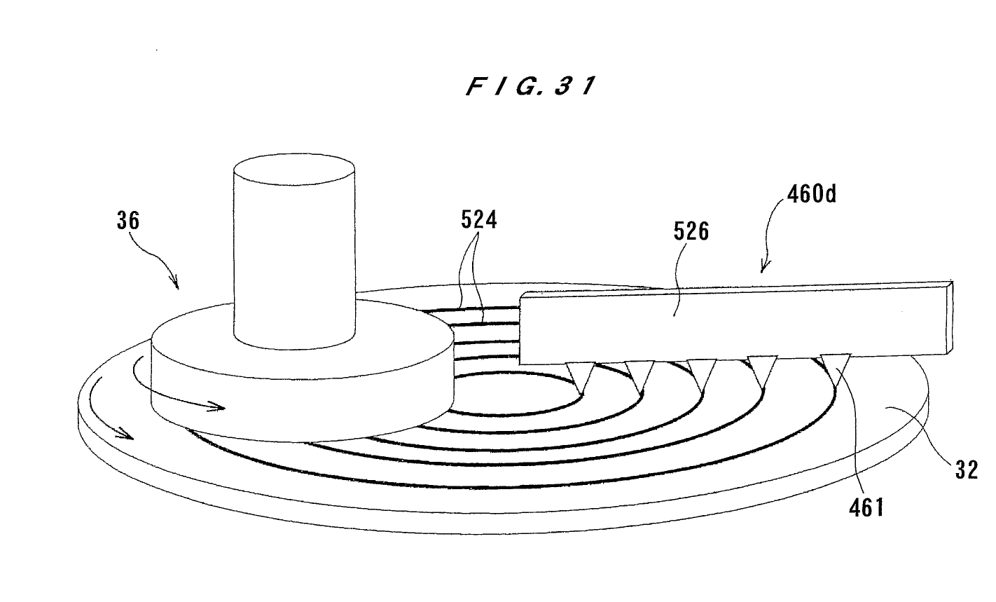

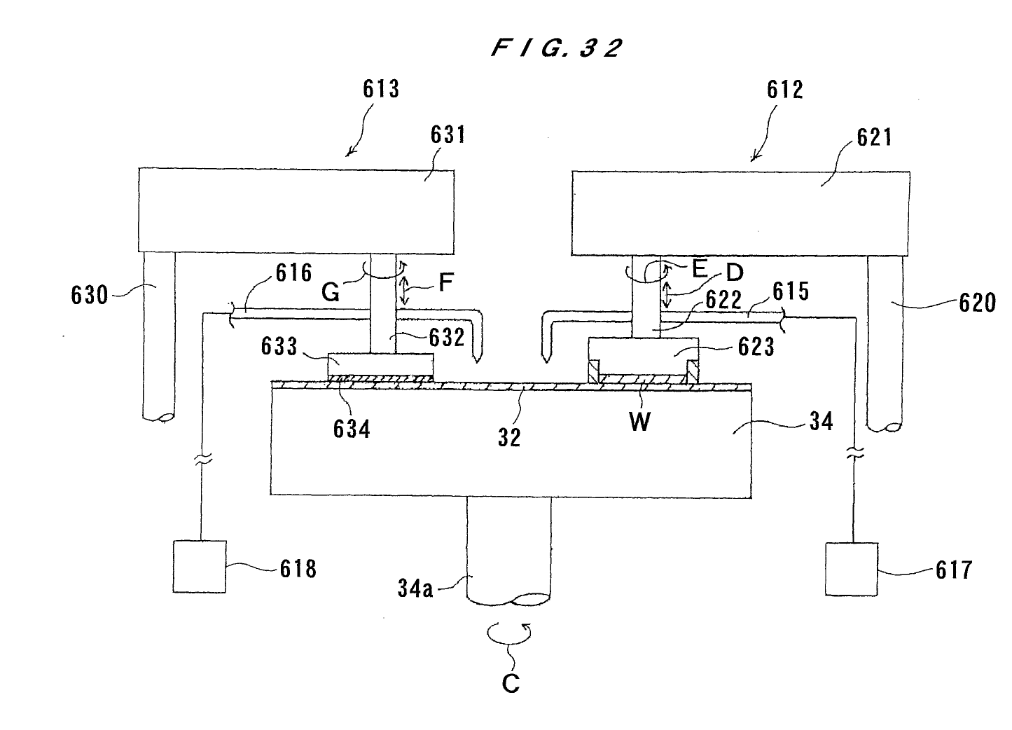

FIG. 32 is a side view showing a main portion of a polishing apparatus according to a fourth embodiment of the present invention. As shown in FIG. 32, the polishing apparatus has a polishing table 34 having a polishing pad 32 attached on an upper surface thereon, a top ring unit 612 for holding a semiconductor wafer (substrate) W by vacuum suction and pressing the semiconductor wafer W against an upper surface (polishing surface) of the polishing pad 32 to polish the semiconductor wafer W, and a dressing unit 613 for dressing (conditioning) the polishing pad 32. The polishing table 34 is coupled via a table shaft 34a to a motor (not shown) and is thus rotatable about the table shaft 34a as indicated by arrow C in FIG. 32. For example, the polishing pad 32 is formed by a non-woven fabric. In the present embodiment, the semiconductor wafer W has a low-k film as an insulating film, and a barrier layer and a Cu film formed on the low-k film.

The polishing apparatus includes a polishing liquid supply nozzle 615 and a dressing liquid supply nozzle 616 disposed above the polishing table 34. The polishing liquid supply nozzle 615 is connected through a pipe to a polishing liquid reservoir tank 617. The dressing liquid supply nozzle 616 is connected through a pipe to a dressing liquid reservoir tank 618. Thus, a polishing liquid is supplied onto the polishing pad 32 from the polishing liquid supply nozzle 615, and a dressing liquid (e.g., pure water) is supplied onto the polishing pad 32 from the dressing liquid supply nozzle 616.

The top ring unit 612 has a rotatable support shaft 620, a swing arm 621 connected to an upper end of the support shaft 620, a top ring shaft 622 extending downward from a free end of the swing arm 621, and a top ring (substrate holding device) 623 connected to a lower end of the top ring shaft 622. The top ring 623 is substantially in the form of a disk. The top ring 623 is horizontally moved by swing motion of the swing arm 621, which is rotated by the support shaft 620. Thus, the top ring 623 can be reciprocated between a pusher (not shown) and a polishing position on the polishing pad 32. Further, the top ring 623 is coupled via the top ring shaft 622 to a motor and a cylinder (not shown) provided in the swing arm 621. Thus, the top ring 623 is movable in a vertical direction as indicated by arrow D in FIG. 32 and is rotatable about the top ring shaft 622 as indicated by arrow E in FIG. 32.

While the top ring 623 is rotated, the semiconductor wafer W held on a lower surface of the top ring 623 is pressed against the polishing surface on the polishing pad 32 under a desired pressing pressure. At that time, a polishing liquid is supplied from the polishing liquid supply nozzle 615 onto the polishing pad 32. For example, the polishing liquid comprises a liquid containing fine abrasive particles such as silica which is suspended in a mixture solution of a chelating agent or a surface-active agent. The semiconductor wafer W is polished to a flat mirror finish by composite chemical mechanical action including chemical polishing action of alkali and mechanical polishing action of abrasive particles.

When a polishing process is continued in the polishing apparatus, the polishing performance of the polishing pad 32 is lowered. Accordingly, the polishing apparatus has the dressing unit 613 to recover the polishing performance of the polishing pad 32. The dressing unit 613 has a rotatable support shaft 630, a swing arm 631 connected to an upper end of the support shaft 630, a dresser shaft 632 extending downward from a free end of the swing arm 631, and a dresser (conditioner) 633 connected to a lower end of the dresser shaft 632. The dresser 633 is horizontally moved by swing motion of the swing arm 631, which is rotated by the support shaft 630. Thus, the dresser 633 can be reciprocated between a dressing position on the polishing pad 32 and a dresser cleaning device (not shown) positioned outside of the polishing table 34.

The dresser 633 has a dressing member 634 attached to a lower surface thereof. The dressing member 634 is brought into sliding contact with the upper surface (polishing surface) of the polishing pad 32 to dress the polishing pad 32. The dresser 633 presses the dressing member 634 against the rotating polishing pad 32 under a desired pressure and rotates the dressing member 634 to dress (condition) the polishing pad 32. The dressing member 634 has a large number of fine diamond particles electrodeposited on a lower surface thereof.

A dressing process using the dresser 633 is performed as follows. Specifically, while a dressing liquid such as pure water is supplied from the dressing liquid supply nozzle 616 onto the polishing pad 32, the dresser 633 and the polishing table 34 are rotated, respectively. The dressing member 634 of the dresser 633 is pressed against the polishing pad 32 to remove polishing wastes such as a polishing liquid or a polished material (e.g., Cu as an interconnection material) remaining on the surface of the polishing pad 32 and to flatten and condition the surface of the polishing pad 32. Thus, the polishing pad 32 is regenerated.

FIG. 33 is a cross-sectional view schematically showing a polishing pad after the dressing process. As shown in FIG. 33, the polishing pad 32 has projections 32a formed on the upper surface thereof. The projections 32a have substantially the same height so that tops of the projections 32a are located substantially on the same plane. During polishing, the lower surface of the semiconductor wafer W is pressed via abrasive particles 27 contained in the polishing liquid 26 against the projections 32a. Thus, since the projections 32a have uniform heights, the polishing pad 32 can be brought into contact with the semiconductor wafer W in a state such that more abrasive particles 27 are present between the polishing pad 32 and the semiconductor wafer W as compared to a polishing pad having uneven surface roughness. Accordingly, an actual contact area between the polishing pad 32 and the semiconductor wafer W can be increased so that stress concentration produced in the semiconductor wafer W is suppressed.

In order to dress the polishing pad 32 so that the projections 32a have uniform heights, diamond particles attached onto the lower surface of the dressing member 634 should have uniform heights. Configuration to uniformize the heights of the diamond particles will be described with reference to FIG. 34.

FIG. 34 is an enlarged view showing an example of the dresser shown in FIG. 32. As shown in FIG. 34, a plate 635 is attached to a lower surface of the dressing member 634. The plate 635 has a plurality of through-holes 635a for holding diamond particles 636. Thus, the plate 635 prevents the diamond particles 636 from being detached from the dressing member 634. The through-holes 635a have the same diameter. Since the diamond particles 636 are held in the through-holes 635a, the sizes (heights) of the diamond particles 636 electrodeposited on the dressing member 634 can be made substantially the same.

Another method of increasing an actual contact area between the polishing pad and the semiconductor wafer comprises regulating heights of diamond particles projecting from the lower surface of the dresser so that the heights of the diamond particles are smaller than a certain value. Specifically, the heights of the diamond particles in the dresser 633 are adjusted so that projections 32a formed on the surface of the polishing pad 32 after the dressing process have heights of 0.3 to 10 μm.

FIG. 35 is a cross-sectional view schematically showing a polishing pad dressed by a dresser in which heights of diamond particles are regulated so as to be lower than a certain value. As shown in FIG. 35, the projections 32a formed on the surface of the polishing pad 32 have small heights (roughness) H. Accordingly, the lower surface of the semiconductor wafer W is pressed not only by abrasive particles above the projections 32a, but also by abrasive particles in recesses between the projections 32a. Thus, the polishing pad 32 can be brought into contact with the semiconductor wafer W in a state such that more abrasive particles 27 are present between the polishing pad 32 and the semiconductor wafer W as compared to a polishing pad having a large surface roughness. Accordingly, an actual contact area between the polishing pad 32 and the semiconductor wafer W can be increased. In this case, the heights of the projections 32a are not necessarily required to be uniform. However, it is desirable to uniformize the heights of the projections 32a from the viewpoint of increase of the actual contact area, as with the example shown in FIG. 33.

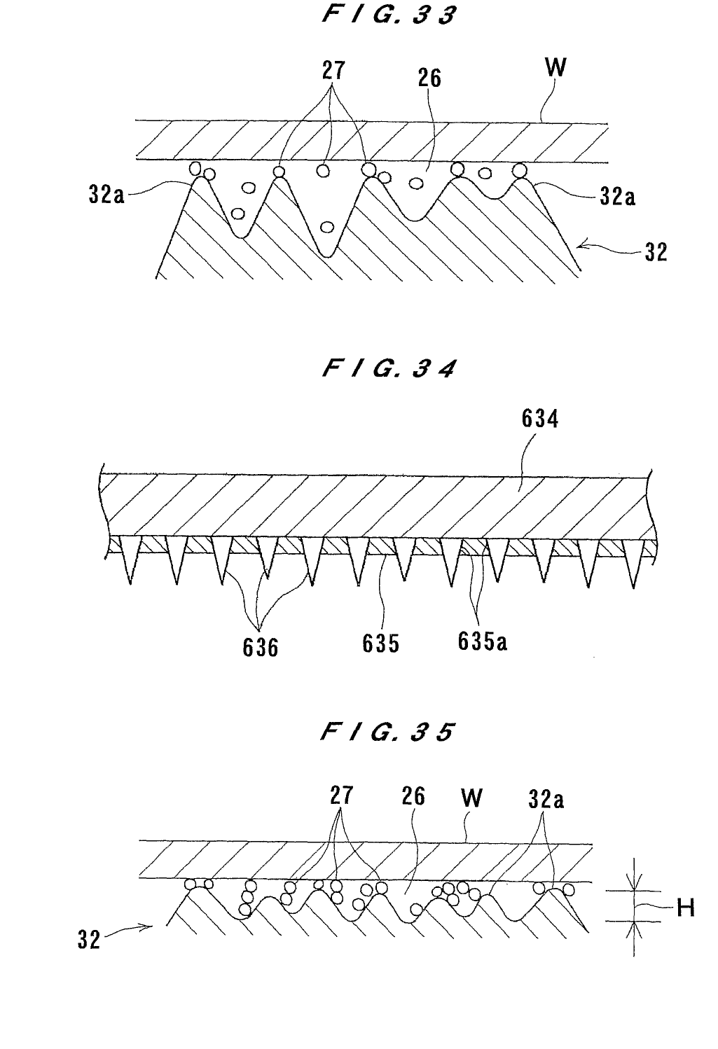

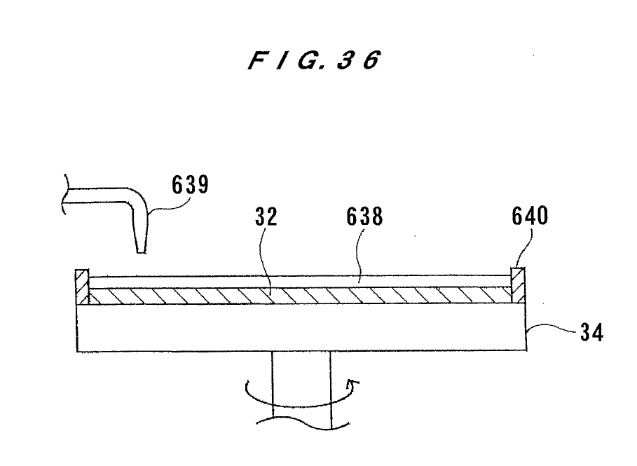

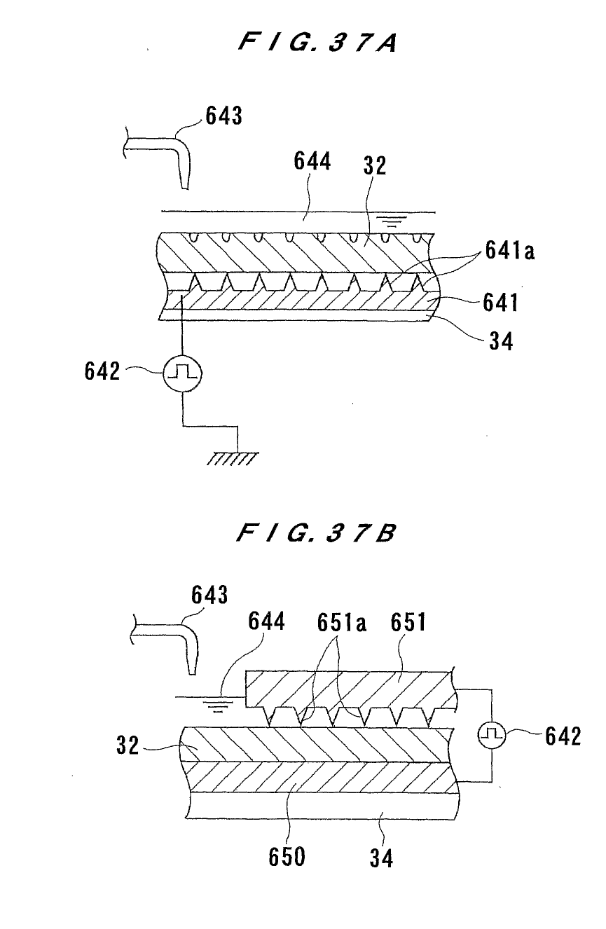

The aforementioned dresser 633 mechanically dresses the polishing pad 32. Instead of such a mechanical dresser, a chemical dresser to chemically dress the polishing pad 32 may be used in the polishing apparatus. Some variations of the dresser will be described with reference to FIGS. 36, 37A, and 37B.

FIG. 36 is a schematic view showing an example of a chemical dresser for chemically dressing the polishing pad 32. As shown in FIG. 36, an etchant supply nozzle 639 for supplying an etchant onto the polishing pad 32 is provided above the polishing table 34. Thus, an etchant 638 is supplied from the etchant supply nozzle 639 onto the polishing pad 32. The polishing table 34 has an annular weir 640 surrounding a peripheral portion of the polishing pad 32.

The etchant 638 supplied from the etchant supply nozzle 639 is held on the polishing pad 32 for a certain period of time and then discharged through an outlet (not shown) formed in the weir 640. Thus, a surface of the polishing pad 32 is etched by chemical action of the etchant 638. In this case, by adjusting a period of time during which the etchant 638 is brought into contact with the polishing pad 32, sizes (heights) and shapes of the projections 32a formed on the surface of the polishing pad 32 can be controlled.

FIG. 37A is a schematic view showing another example of a dresser for chemically dressing the polishing pad 32. As shown in FIG. 37A, an electrode 641 is embedded in the polishing table 34 and connected to a pulse power source 642. The electrode 641 has a plurality of fine projections 641a projecting upward from an upper surface thereof. Tip ends of the projections 641a are brought into contact with a lower surface of the polishing pad 32. A chemical liquid supply nozzle 643 for supplying an electrolytic solution (chemical liquid) onto the polishing pad 32 is provided above the polishing table 34. The polishing table 34 has an annular weir (see FIG. 36) surrounding a peripheral portion of the polishing pad 32 to hold an electrolytic solution 644 on the polishing pad 32. A pulsed voltage is applied from the pulse power source 642 to the electrode 641 in a state such that the electrolytic solution 644 is held on the polishing pad 32. Thus, portions of the polishing pad 32 which are located at positions corresponding to the projections 641a of the electrode 641 are selectively etched to produce a plurality of projections 32a (see FIGS. 33 and 35) on the surface of the polishing pad 32. With this configuration, by properly adjusting a pulse width and an amplitude of the pulsed voltage and shapes and positions of the projections 641a of the electrode 641, projections 32a having desired shapes (see FIGS. 33 and 35) can be formed on the surface of the polishing pad 32.

FIG. 37B is a schematic view showing another example of a dresser for chemically dressing the polishing pad 32. As shown in FIG. 37B, a first electrode 650 is disposed between the polishing table 34 and the polishing pad 32, and a second electrode 651 is disposed above the polishing pad 32. The electrodes 650 and 651 are connected to a pulse power source 642. The second electrode 651 has a plurality of fine projections 651a projecting downward from a lower surface thereof The second electrode (process electrode) 651 is located at a retracting position outside of the polishing table 34 when a polishing process is performed on the polishing pad 32. A chemical liquid supply nozzle 643 for supplying an electrolytic solution (chemical liquid) onto the polishing pad 32 is disposed above the polishing table 34. The polishing table 34 has an annular weir 640 (see FIG. 36) surrounding a peripheral portion of the polishing pad 32 to hold an electrolytic solution 644 on the polishing pad 32.

When a dressing process is performed, the second electrode 651 is moved to a position above the polishing table 34. A plurality of projections 651a of the second electrode 651 are brought into contact with the surface of the polishing pad 32. At that time, an electrolytic solution 644 is supplied onto the polishing pad 32, and a pulse voltage is applied between the electrodes 650 and 651 by the pulse power source 642. Thus, portions of the polishing pad 32 which are brought into contact with the projections 65 la are selectively etched. In this case, by properly adjusting a pulse width and an amplitude of the pulsed voltage and shapes and positions of the projections 651a of the second electrode 651, projections 32a having desired shapes (see FIGS. 33 and 35) can be formed on the surface of the polishing pad 32. Other types of dressers, e.g., dressers disclosed by Japanese laid-open patent publication Nos. 2001-129755 and 2004-34159, may be employed instead of the above dressers.

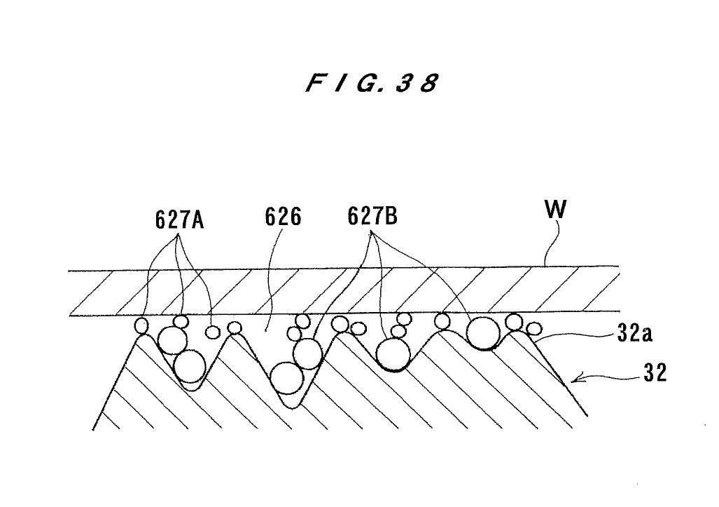

Another method of increasing an actual contact area between the polishing pad and the semiconductor wafer comprises supplying a polishing liquid containing various types of abrasive particles having different sizes onto the polishing pad. This method will be described with reference to FIG. 38. FIG. 38 is a schematic view showing a semiconductor wafer W polished with a polishing liquid 626 containing two types of abrasive particles having different sizes. The polishing liquid 626 contains two types of abrasive particles 627A and 627B, which are present between the polishing pad 32 and the semiconductor wafer W. In this case, the amounts of abrasive particles 627A and 627B to be mixed are adjusted so that a distribution of particle sizes of the abrasive particles 627A and 627B is close to a distribution of surface roughness of the polishing pad 32. If the distribution of surface roughness of the polishing pad 32 substantially accords with the distribution of particle sizes of the abrasive particles 627A and 627B in the polishing liquid 626, then, as shown in FIG. 38, small abrasive particles 627A are distributed at higher portions of the polishing pad 32 (near the semiconductor wafer W) while large abrasive particles 627B are distributed at lower portions of the polishing pad 32. Specifically, the large abrasive particles 627B are filled in recesses between the projections 32a, and the small abrasive particles 627A are diffused above the large abrasive particles 627B. Accordingly, the surface roughness of the polishing pad 32 substantially becomes smaller so as to increase an actual contact area between the polishing pad 32 and the semiconductor wafer W.

It is desirable that the small abrasive particles 627A, which contribute to a polishing process of the semiconductor wafer W, have diameter as small as possible. Specifically, the small abrasive particles 627A preferably have a diameter smaller than about 100 nm, more preferably a diameter in a range of about 10 to 30 nm. Silica (SiO₂) is suitably employed as the small abrasive particles 627A. The large abrasive particles 627B preferably have a diameter in a rage of 0.1 to 1 μm. It is desirable that the large abrasive particles 627B are soft. Specifically, the large abrasive particles 627B preferably have a Young's modulus smaller than the Young's modulus of Cu, i.e., 129.8 GPa.

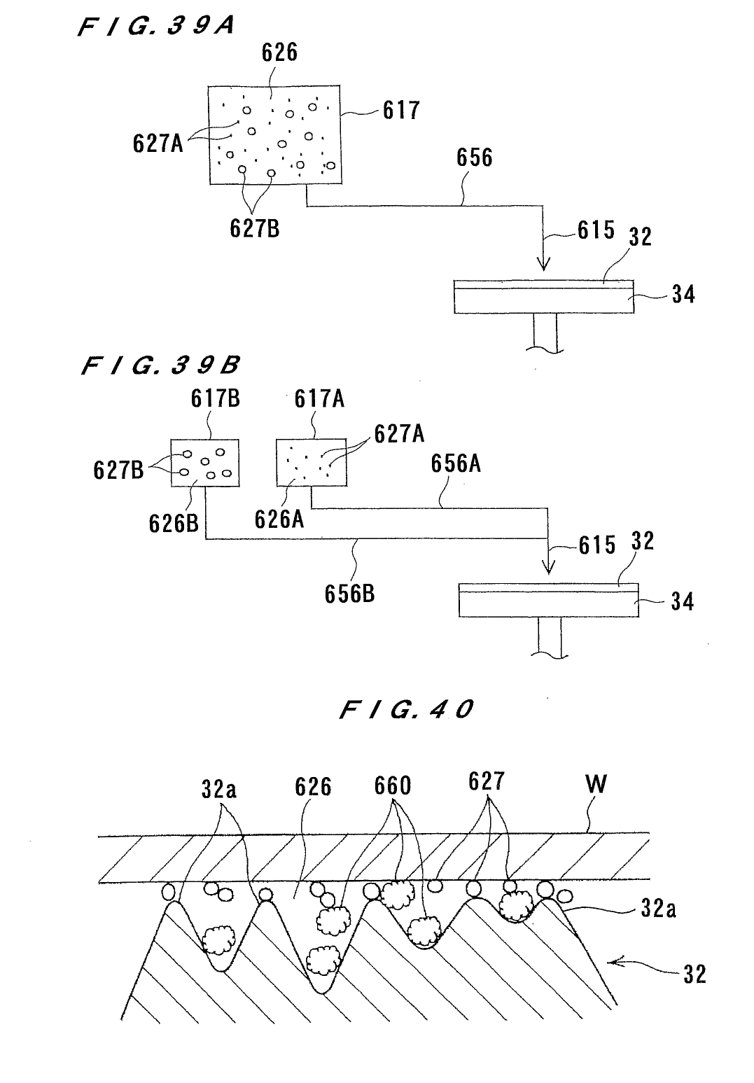

The polishing liquid may be produced by previously mixing abrasive particles having different sizes. FIG. 39A is a schematic view showing a polishing liquid supply mechanism for this purpose. Alternatively, plural types of polishing liquids each containing abrasive particles having different sizes may be mixed immediately before they are supplied onto the polishing pad 32. FIG. 39B is a schematic view showing a polishing liquid supply mechanism for this purpose. In the polishing liquid supply mechanism shown in FIG. 39A, two types of abrasive particles 627A and 627B having different sizes are introduced into a single polishing liquid reservoir tank 617 and mixed by an agitator (not shown) to produce a polishing liquid 626. Then, the polishing liquid 626 is supplied through a supply pipe 656 from the polishing liquid supply nozzle 615 onto the polishing pad 32. In the polishing liquid supply mechanism shown in FIG. 39B, a polishing liquid 626A containing abrasive particles 627A is stored in a polishing liquid reservoir tank 617A, and a polishing liquid 626B containing abrasive particles 627B having different sizes from the abrasive particles 627A is stored in a polishing liquid reservoir tank 617B. The polishing liquids 626A and 626B are introduced from the polishing liquid reservoir tanks 617A and 617B into supply pipes 656A and 656B and mixed with each other immediately before they are supplied onto the polishing pad 32. Thus, either one of the polishing liquid supply mechanisms shown in FIGS. 39A and 39B may be employed. Alternatively, other polishing liquid supply mechanisms may be employed to produce a polishing liquid containing abrasive particles having different sizes. Although abrasive particles having different sizes and hardnesses are used in the examples shown in FIGS. 39A and 39B, three or more types of abrasive particles may be used.

Another method of increasing an actual contact area between the polishing pad and the semiconductor wafer comprises employing a polishing liquid containing fine bubbles in addition to abrasive particles. Gas may be supplied into a polishing liquid to form bubbles therein. In this case, it is desirable to use gases other than O₂ in order to avoid adverse influence on Cu interconnections from bubbles. If bubbles of O₂ are mixed into a polishing liquid, O₂ reacts with Cu interconnections in the semiconductor wafer W to produce CuOₓ, which may deteriorate the Cu interconnections. From this point of view, it is desirable to mix an inert gas such as N₂ gas or Ar gas into a polishing liquid.

FIG. 40 is a schematic view showing a state in which a semiconductor wafer W is polished with a polishing liquid 626 containing bubbles 660. As shown in FIG. 40, fine bubbles 660 mixed into a polishing liquid 626 are introduced into recesses between the projections 32a of the polishing pad 32. Thus, the projections 32a of the polishing pad 32 can be fluffed. Accordingly, it is possible to increase an actual contact area between the polishing pad 32 and the semiconductor wafer W. The bubbles 660 preferably have sizes larger than those of abrasive particles 627. Specifically, the bubbles 660 preferably have diameters of several micrometers to several tens of micrometers.

Various devices can be employed to mix bubbles into a polishing liquid. FIG. 41 is a schematic view showing an example of a polishing liquid supply mechanism for supplying a polishing liquid containing bubbles onto the polishing pad 32. As shown in FIG. 41, the polishing liquid supply mechanism has a polishing liquid reservoir tank 617 for storing a polishing liquid 626, a bubbling tank 661 for mixing bubbles into the polishing liquid 626, and a gas supply source 662 for supplying a gas such as an inert gas to the bubbling tank 661. The polishing liquid 626 stored in the polishing liquid reservoir tank 617 is supplied through a supply pipe 656 into the bubbling tank 661. In the bubbling tank 661, a gas from the gas supply source 662 is blown into the polishing liquid 626 to form fine bubbles and diffuse the fine bubbles into the polishing liquid 626. The polishing liquid 626 containing the bubbles is supplied from the polishing liquid supply nozzle 615 onto the polishing pad 32.

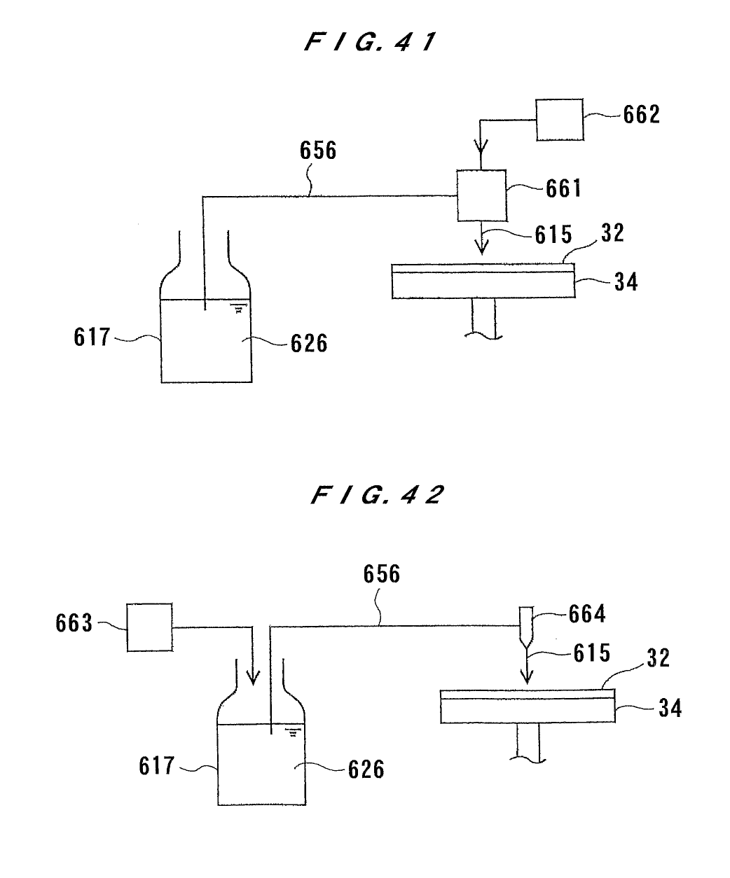

FIG. 42 is a schematic view showing another example of a polishing liquid supply mechanism for supplying a polishing liquid containing bubbles onto the polishing pad 32. As shown in FIG. 42, the polishing liquid supply mechanism has a pure water tank 663 for storing pure water (DIW) in which a small amount of inert gas (e.g., N₂ gas) has previously been dissolved, a polishing liquid reservoir tank 617 for storing a polishing liquid 626, and a decompression device 664 (e.g., an ejector or a venturi tube) connected through a supply pipe 656 to the polishing liquid reservoir tank 617. Pure water is introduced from the pure water tank 663 into the polishing liquid reservoir tank 617 to dilute the polishing liquid 626 stored in the polishing liquid reservoir tank 617. Then, the polishing liquid 626 is introduced through the supply pipe 656 into the decompression device 664, which reduces a pressure of the polishing liquid 626 to produce fine bubbles of the inert gas in the polishing liquid 626. The polishing liquid 626 containing bubbles is supplied from the polishing liquid supply nozzle 615 onto the polishing pad 32.

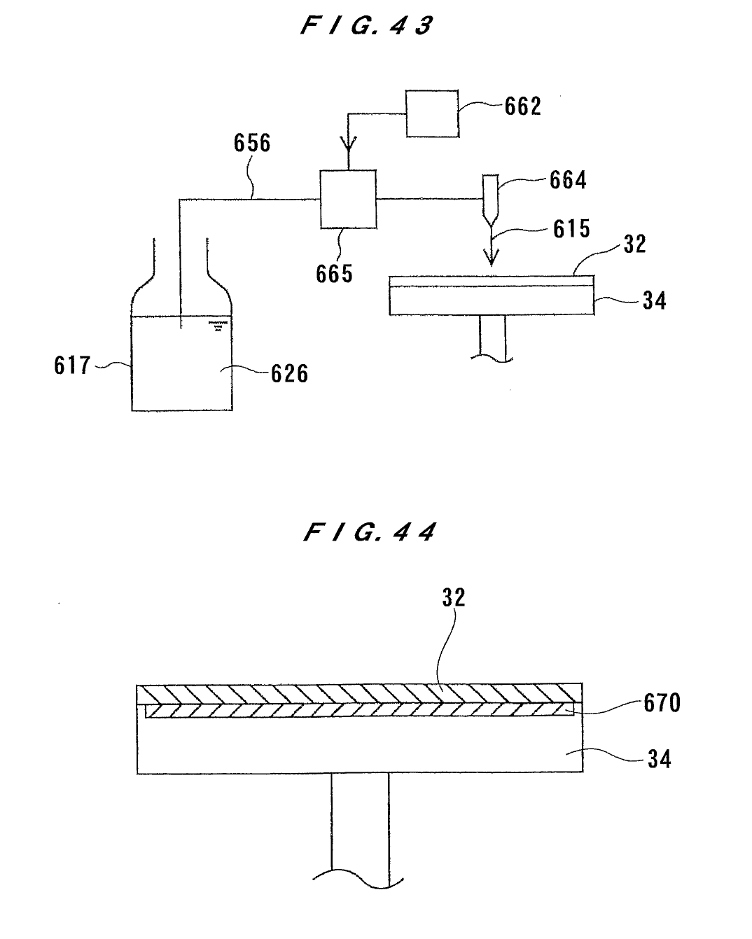

FIG. 43 is a schematic view showing another example of a polishing liquid supply mechanism for supplying a polishing liquid containing bubbles onto the polishing pad 32. As shown in FIG. 43, the polishing liquid supply mechanism has a polishing liquid reservoir tank 617 for storing a polishing liquid 626, a gas dissolution device 665 for dissolving an inert gas (e.g., N₂ gas) into the polishing liquid 626, a gas supply source 662 for supplying an inert gas to the gas dissolution device 665, and a decompression device 664 (e.g., an ejector or a venturi tube) connected to the gas dissolution device 665. The polishing liquid 626 stored in the polishing liquid reservoir tank 617 is introduced through a supply pipe 656 into the gas dissolution device 665, where an inert gas from the gas supply source 662 is dissolved into the polishing liquid 626. Then, the polishing liquid 626 is introduced into the decompression device 664, which reduces a pressure of the polishing liquid 626 to produce fine bubbles of the inert gas in the polishing liquid 626. The polishing liquid 626 containing bubbles is supplied from the polishing liquid supply nozzle 615 onto the polishing pad 32. The gas dissolution device 665 may comprise a commercially available gas dissolution filter. According to a method disclosed by Japanese laid-open patent publication No. 2003-136405, ultrasonic vibration may be applied to a polishing liquid in a pipe to produce bubbles in the polishing liquid.

Another method of increasing an actual contact area between the polishing pad and the semiconductor wafer comprises applying ultrasonic waves to the polishing pad. FIG. 44 is a schematic view showing a main portion of a polishing apparatus having an ultrasonic wave application device. As shown in FIG. 44, the polishing table 34 has an ultrasonic vibrator 670 provided therein for applying ultrasonic waves to the polishing pad 32. Ultrasonic waves are applied from the ultrasonic vibrator 670 to the polishing pad 32 to vibrate projections 32a formed on the polishing pad 32. Accordingly, projections 32a (see FIGS. 33 and 35) that have fallen down during polishing can be fluffed (raised) to increase an actual contact area between the polishing pad 32 and the semiconductor wafer.

Methods of preventing defects (cracking) from being caused in Cu interconnections during polishing include a method of suppressing a pressing force applied from a polishing pad to a semiconductor wafer with use of abrasive particles, in addition to a method of increasing an actual contact area between the polishing pad and the semiconductor wafer. For example, a polishing liquid for this purpose may contain at least one of abrasive particles having an elasticity, hollow abrasive particles, and abrasive particles which are broken under a certain pressure.

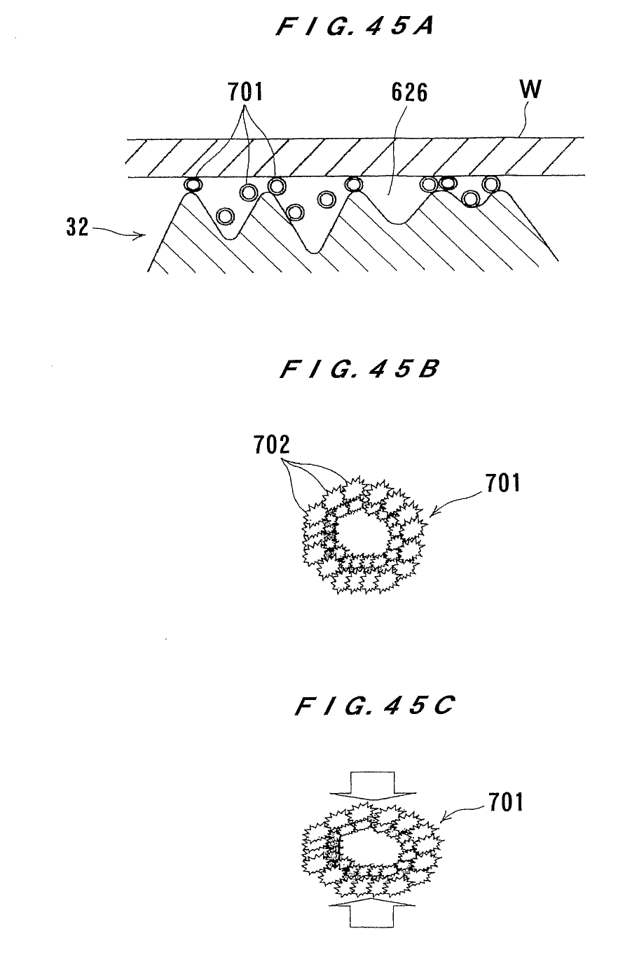

FIG. 45A is a schematic view showing a state in which a semiconductor wafer W is polished with a polishing liquid 626 containing hollow abrasive particles 701. FIG. 45B is an enlarged cross-sectional view showing the hollow abrasive particle 701 shown in FIG. 45A, and. FIG. 45C is an enlarged cross-sectional view showing the hollow abrasive particle 701 that is deformed under forces. Arrows shown in FIG. 45C represent forces applied to the hollow abrasive particle 701.

Hollow abrasive particles as shown in FIG. 45B can be produced by sintering or pressing a plurality of fine particles such as SiO₂ to bind each other. Alternatively, hollow abrasive particles may be produced by chemosynthesis using resin. As shown in FIGS. 45A and 45C, the hollow abrasive particle 701 is deformed so as to suppress a pressing force applied from the polishing pad 32 to the semiconductor wafer W when the hollow abrasive particle 701 is sandwiched between the polishing pad 32 and the semiconductor wafer W. Further, if excessive forces are applied to the hollow abrasive particle 701, the hollow abrasive particle 701 is broken to prevent damage to devices formed on the semiconductor wafer W.

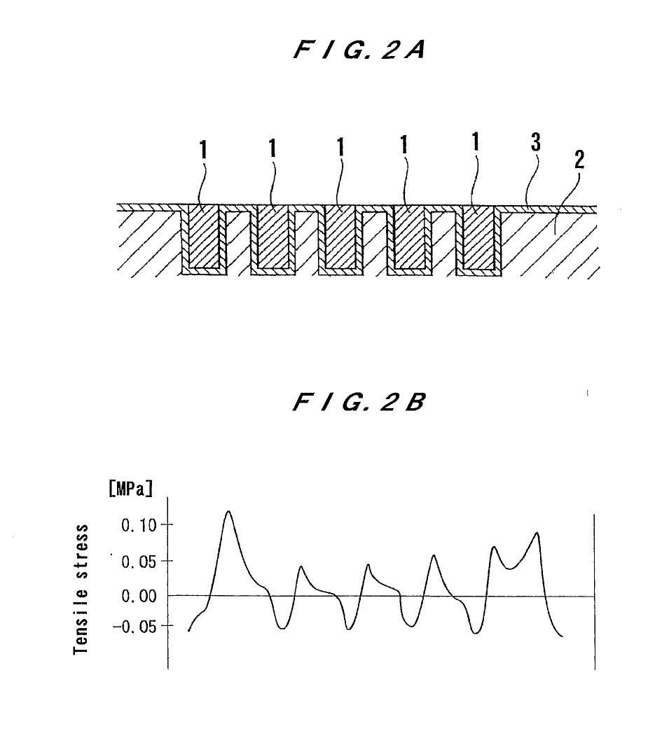

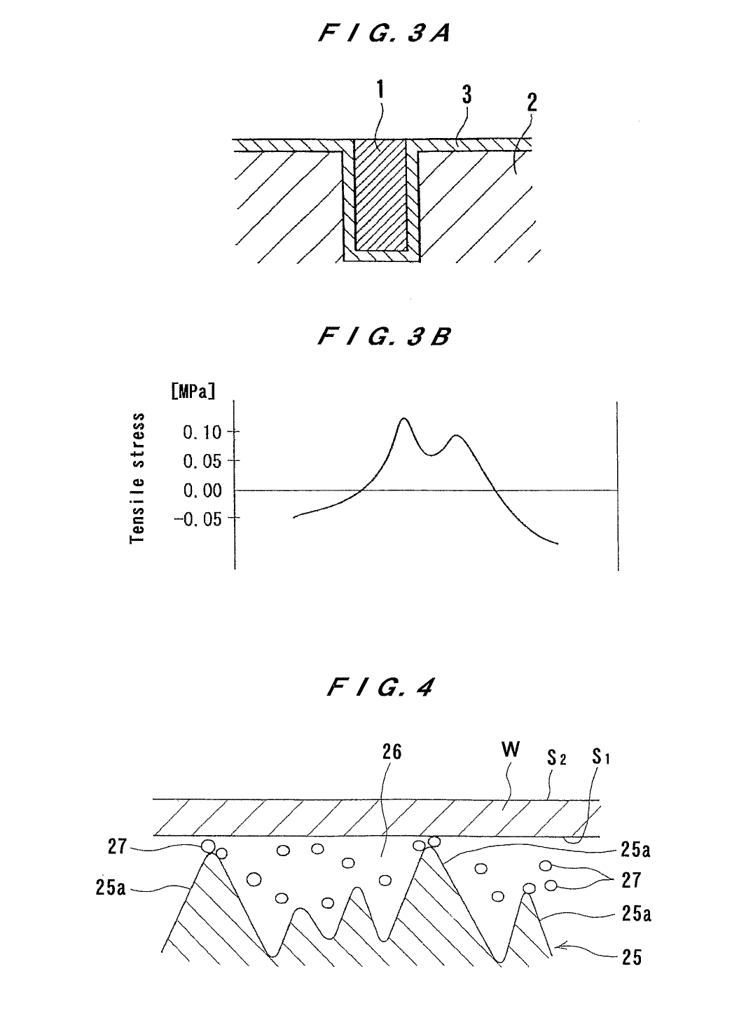

The abrasive particles may not be hollow. For example, abrasive particles which are broken under a certain pressure (e.g., 100 kPa or more) may be employed instead of the hollow abrasive particles. In the examples shown in FIGS. 2B and 3B, a pressure applied to a surface having devices is 13.8 kPa. In this case, a tensile stress applied to the isolated Cu interconnection is calculated to be about 30 MPa when an actual contact area between the polishing pad and the semiconductor wafer is 0.4%. Accordingly, defects are caused in the Cu interconnections. When abrasive particles which are broken under about 100 kPa are employed in order to increase an actual contact area between the polishing pad and the semiconductor wafer to ten times thereof, defects of Cu interconnections are considered to be prevented.

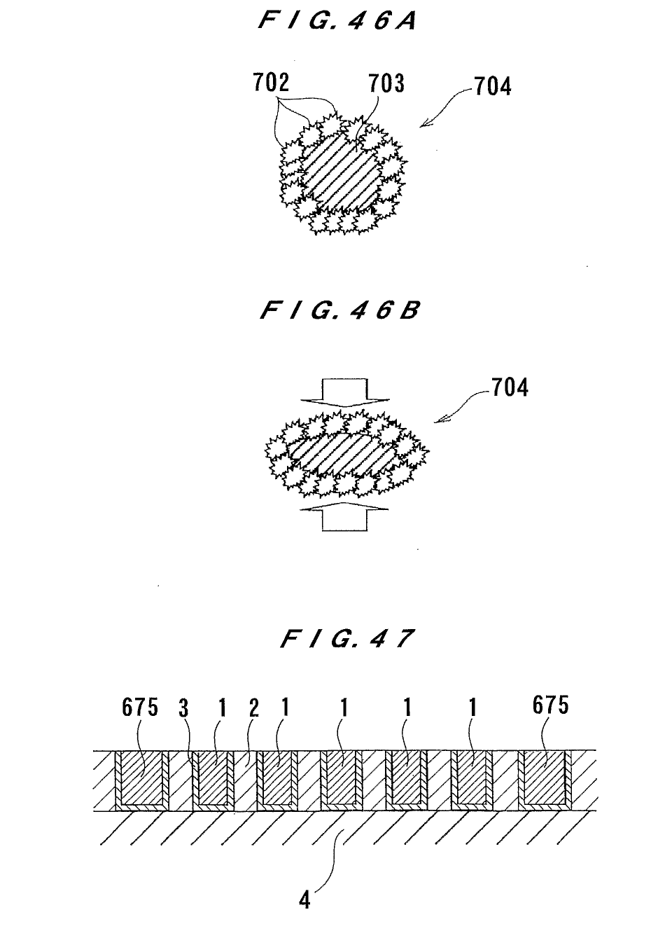

As shown in FIG. 46A, an abrasive particle 704 having an elastic body 703 and a large number of fine particles 702 fixed on the elastic body 703 may be employed instead of the hollow abrasive particle 701. Resin (porous resin) having a high porosity is suitably used as the elastic body 703. Further, the elastic body 703 may be formed by inert resin (PMMA or polymethyl methacrylate) disclosed by Japanese laid-open patent publication No. 2001-15462. In this case, as shown in FIG. 46B, when forces are applied to the abrasive particle 704, the abrasive particle 704 is deformed so as to suppress a pressing force applied from the polishing pad to the semiconductor wafer.

Methods of preventing defects (cracking) from being caused in Cu interconnections during polishing include a method of using a polishing liquid containing no abrasive particles. Generally, when a polishing liquid containing abrasive particles is used to polish a semiconductor wafer, only considerably limited portions of abrasive particles are brought into contact with the semiconductor wafer. Accordingly, a relatively large pressure is applied to local portions of the semiconductor wafer. On the other hand, when a polishing liquid containing no abrasive particles, the projections of the polishing pad are brought into direct contact with the semiconductor wafer. In this case, radii of curvatures of the projections are much greater than those of the abrasive particles. Hardness of the polishing pad is also much lower than that of the abrasive particles. Accordingly, it is possible to suppress a pressing force applied from the polishing pad to the semiconductor wafer.

When a polishing liquid containing no abrasive particles is used, removal effect of a surface of a wafer due to scratches by the abrasive particles is eliminated so as to lower a polishing rate. Accordingly, it is more desirable to combine a method of using a polishing liquid containing no abrasive particles with the aforementioned other methods of increasing an actual contact area between the polishing pad and the semiconductor wafer.

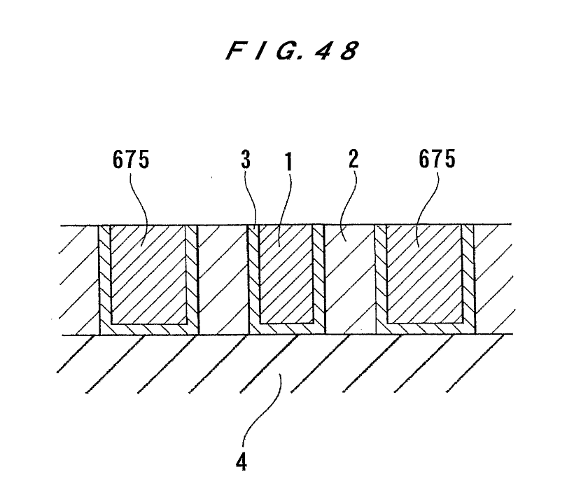

The aforementioned methods of preventing defects (cracking) from being caused in Cu interconnections have been described in connection with a dresser and a polishing liquid. Defects can be prevented from being caused in Cu interconnections by reinforcing an interconnection pattern, i.e., a low-k film. Methods of reinforcing a low-k film will be described with reference to FIGS. 47 and 48.

FIG. 47 is a cross-sectional view showing a group of Cu interconnections (dense interconnections) 1 embedded in a low-k film 2. As shown in FIG. 47, a low-k film 2 is formed as an insulating film on an underlying insulating film 4. Further, Ta layers 3 are formed as barrier layers on the low-k film 2, and Cu interconnections 1 are formed as metal interconnections on the Ta layers 3 at equal intervals.

As shown in FIG. 47, dummy interconnections 675 extending in parallel to the Cu interconnections 1 are formed on both sides of a group of five Cu interconnections 1 (dense interconnections). As described with reference to FIGS. 2A and 2B, large tensile stresses are produced at peripheral edges of the outermost metal interconnections in the group of interconnections during polishing. Accordingly, the dummy interconnections 675 are disposed adjacent to the outermost Cu interconnections 1. Thus, the low-k film 2 can be reinforced near the outermost Cu interconnections 1 with the dummy interconnections 675. It is desirable that distances between the outermost Cu interconnections 1 and the dummy interconnections 675 are substantially the same as intervals between adjacent Cu interconnections 1.

FIG. 48 is a cross-sectional view showing a Cu interconnection (isolated interconnection) 1 embedded in a low-k film 2. In this example, a low-k film 2 is formed as an insulating film on an underlying insulating film 4. Further, a Ta layer 3 is formed as a barrier layer on the low-k film 2, and a Cu interconnection I is formed as a metal interconnection on the Ta layer. As shown in FIG. 48, dummy interconnections 675 extending in parallel to the Cu interconnection 1 are formed on both sides of the isolated Cu interconnection 1.

The dummy interconnections 675 can be formed in the same manner as the Cu interconnections 1. Specifically, a low-k film is formed on an underlying insulating film (or a semiconductor wafer). Grooves for Cu interconnections are formed in the low-k film. Simultaneously, grooves for dummy interconnections are formed in the low-k film. Then, a Ta layer is formed as a barrier layer on the low-k film, and Cu films are formed on the Ta layer. Thus, Cu is filled into grooves for Cu interconnections and grooves for dummy interconnections to form Cu interconnections and dummy interconnections in the low-k film. Then, the semiconductor wafer is polished with a CMP apparatus to produce a semiconductor device having an interconnection pattern as shown in FIGS. 47 and 48.

As described above, a low-k film used as an insulating film for Cu interconnections has a low mechanical strength. Accordingly, when a semiconductor wafer is pressed against a polishing pad during polishing, the low-k film is deformed to cause defects in Cu interconnections. Such defects are likely to be caused when Cu interconnections have small widths. According to experiments, defects were likely to be caused in dense interconnections or an isolated interconnection having a width of 0.18 μm while no defects were caused in dense interconnections or an isolated interconnection having a width of 1.0 μm.

In the above examples, the dummy interconnections are provided adjacent to the dense interconnections and the isolated interconnection (hereinafter simply referred to as metal interconnections) which form an interconnection pattern. Accordingly, it is possible to enhance the mechanical strength of the low-k film. As a result, the low-k film is prevented from being deformed during polishing, and defects are prevented from being caused in the metal interconnections. The dummy interconnections preferably have a width larger than widths of the metal interconnections to efficiently radiate heat produced at device portions through the dummy interconnections. Instead of provision of the dummy interconnections, portions of the insulating film which correspond to the dummy interconnections may be hardened by an electron beam described later to prevent defects of interconnections.

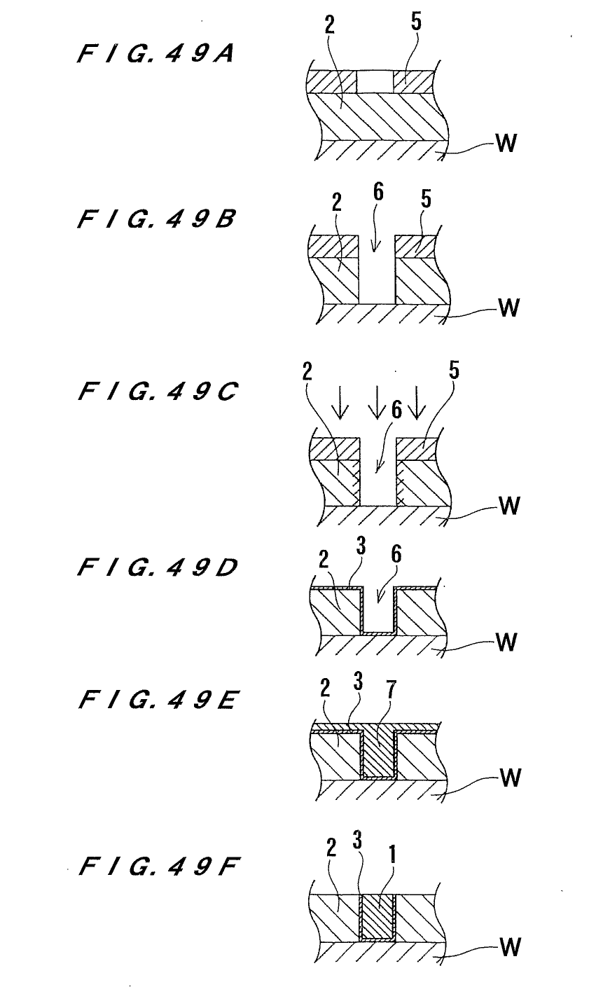

Methods of reinforcing a low-k film include a method of hardening a low-k film. Such a method will be described with reference to FIGS. 49A through 49F. FIGS. 49A through 49F are schematic views showing a process to form a Cu interconnection 1 on a surface of a semiconductor wafer W. As shown in FIG. 49A, a low-k film 2 is formed as an interlayer dielectric on a semiconductor wafer W. Then, a resist 5 is applied to an upper surface of the low-k film 2. The resist 5 is selectively removed according to an interconnection pattern. Next, as shown in FIG. 49B, a trench (groove) 6 is formed in the low-k film 2 by etching. Then, as shown in FIG. 49C, an electron beam is applied to the semiconductor wafer W from above the resist 5 to harden both side walls of the trench 6 (EB cure process). Thereafter, as shown in FIG. 49D, the resist 5 is removed, and a barrier layer 3 is formed on the low-k film 2 by sputtering. As shown in FIG. 49E, a Cu film 7 is formed on the barrier layer 3 by plating to fill Cu into the trench 6. Then, as shown in FIG. 49F, the Cu film 7 and the barrier layer 3 formed on the upper surface of the low-k film 2 are removed by chemical mechanical polishing (CMP) to form a semiconductor device having a Cu interconnection 1.

Thus, the side walls of the trench 6 made of a low-k material are hardened to enhance the mechanical strength of the low-k film 2. Accordingly, a tensile stress produced at an interface between the Cu interconnection 1 and the barrier layer 3 does not become large. As a result, defects are prevented from being caused in the Cu interconnection 1. In this case, a thin insulating film having a high mechanical strength may be deposited on the side walls of the trench 6 to obtain the same effects.

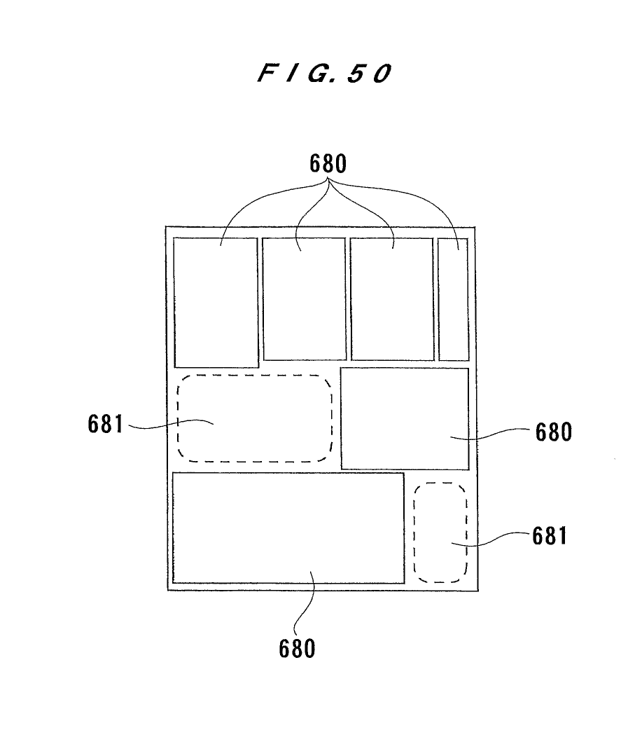

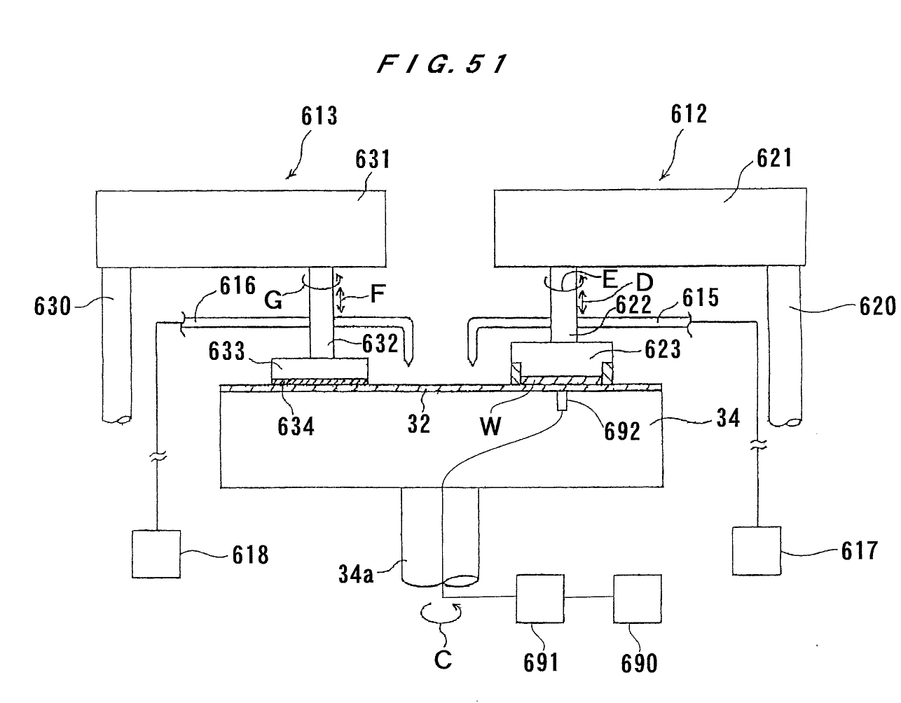

Another method of reinforcing a low-k film will be described with reference to FIG. 50. FIG. 50 is a plan view showing a chip (integrated circuit) formed on a semiconductor wafer. As shown in FIG. 50, the integrated circuit generally includes a plurality of pattern areas 680. Non-pattern areas 681 which have no interconnection patterns are formed between the pattern areas 680. An electron beam is applied to the non-pattern areas 681 to harden an exposed low-k film in the non-pattern areas 681.

Specifically, after a trench is formed on a low-k film according to interconnection patterns, an electron beam is applied to the non-pattern areas 681 to harden the low-k film in the non-pattern areas 681. Then, a barrier layer and a Cu film are formed on the low-k film, and the semiconductor substrate is polished with a polishing apparatus. According to this method, the mechanical strength of the low-k film adjacent to the interconnection patterns can be enhanced to prevent defects from being caused in Cu interconnections of the interconnection patterns during polishing.

FIG. 51 is a schematic view showing a polishing apparatus according to a fourth embodiment of the present invention. The polishing apparatus has the same structure as the polishing apparatus shown in FIG. 32 unless otherwise specified. In the present embodiment, the polishing apparatus polishes a laminated structure made of materials having different Young's moduli, more specifically a semiconductor wafer having a Cu film (Young's modulus of 129.8 GPa), a Ta layer (Young's modulus of 185.7 GPa), and a low-k material (interlayer dielectric) formed thereon. In the present embodiment, the interlayer dielectric has a laminated structure including D-MSQ (high-density methylsiloxane low-k film) and P-MSQ (porous methylsiloxane low-k film).

As shown in FIG. 51, the polishing apparatus has a shape measurement unit 690 for measuring a surface shape of a Cu film to be polished, and a controller 691 for controlling a polishing pressure (a pressure to press the semiconductor wafer W against the polishing surface). The shape measurement unit 690 is configured to measure a film thickness distribution (profile) with use of a sensor 692 such as an eddy-current sensor or an optical sensor and to analyze a surface shape of the Cu film. The shape measurement unit 690 is connected to the controller 691 So that data representing a surface shape of the Cu film is transmitted to the controller 691. The shape measurement unit 690 is configured to detect the type (material) of an exposed portion of the semiconductor wafer W with use of an eddy-current sensor, an optical sensor, or the like.

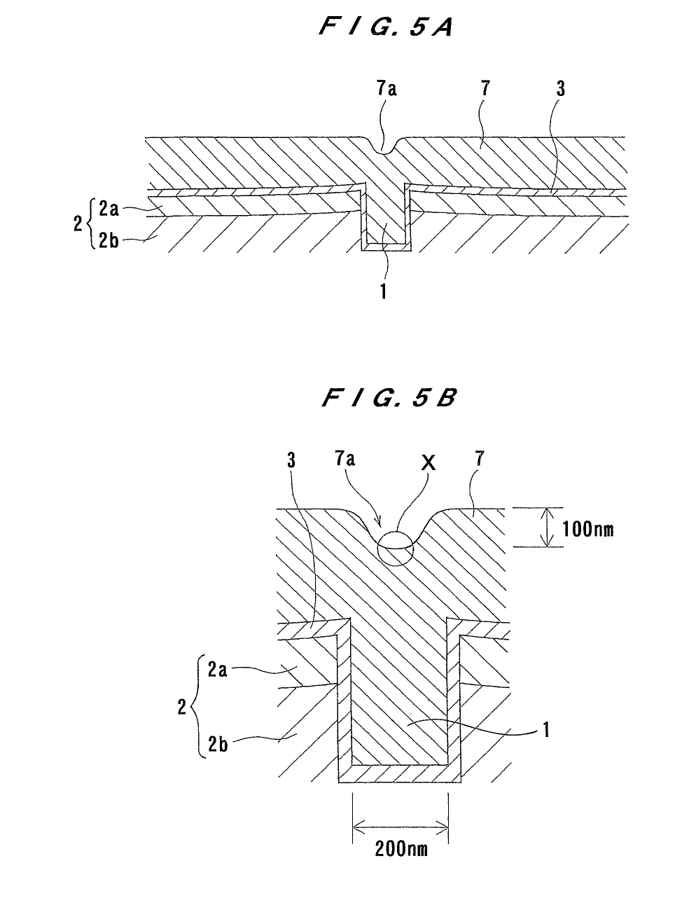

When recesses are formed in the surface of the Cu film, as shown in FIG. 5B, stresses are concentrated at the recesses during polishing. Accordingly, stress corrosion cracking is likely to be caused at the recesses. In the present embodiment, before a polishing process, sizes of the recesses relative to interconnections are measured in the following manner. If the recesses have a size larger than a predetermined size, a polishing pressure during polishing is lowered.

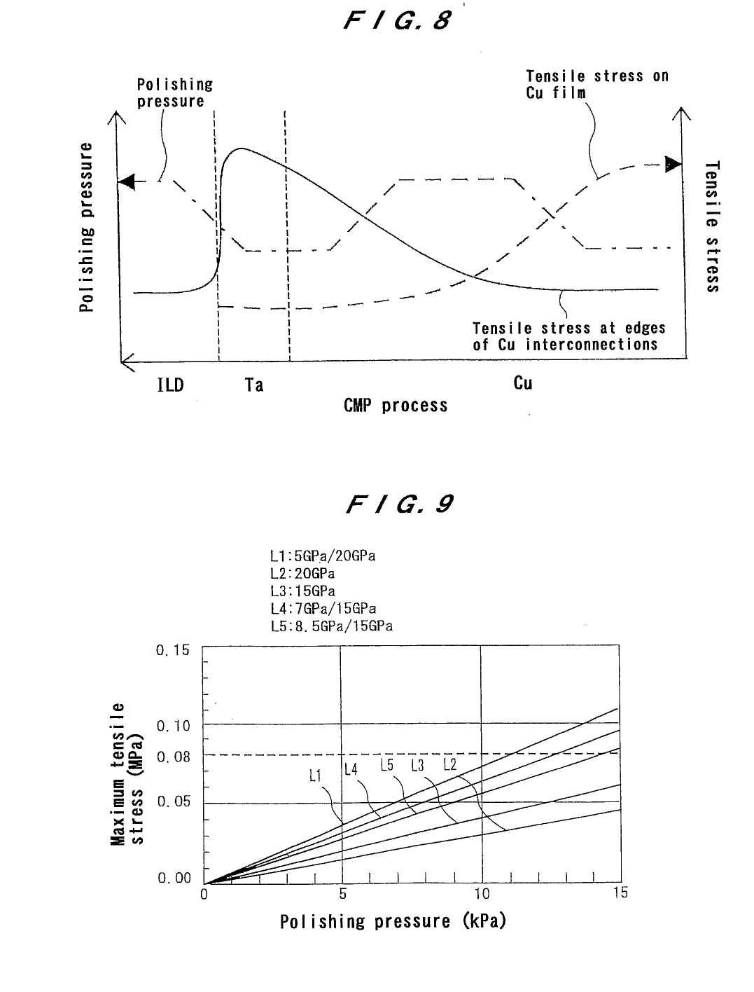

First, the semiconductor wafer W is transferred to the shape measurement unit 690 before the polishing process. The shape measurement unit 690 measures a film thickness distribution of a Cu film to calculate a surface shape (profile) of the Cu film, i.e., sizes of the recesses. Data obtained in the shape measurement unit 690 is sent to the controller 691, which calculates a ratio of a depth of the recesses and an interconnection width. The interconnection width is previously inputted into the controller 691 to calculate a ratio of a depth of the recesses and the interconnection width. As described with reference to FIG. 5B, if a ratio of a depth of the recesses and the interconnection width is not more than 0.25, then stress corrosion cracking is hardly caused. Accordingly, a polishing process is performed under a normal polishing pressure when the calculated ratio is not more than 0.25 (reference value). When the calculated ratio is larger than 0.25, the controller 691 sets a polishing pressure at an initial stage of the polishing process so as to be lower than the normal polishing pressure (see FIG. 8). Thus, stress corrosion cracking is prevented from being caused at the recesses in the surface of the Cu film.

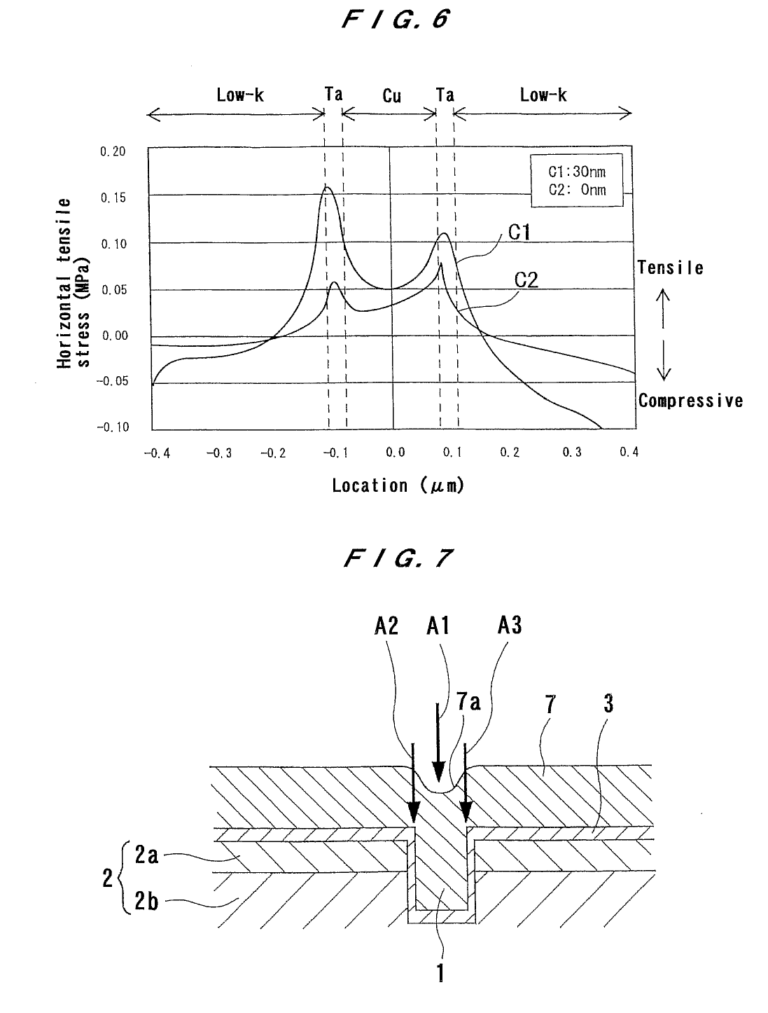

When the Cu film is removed by polishing, stress concentration is caused at peripheral edges of the Cu interconnections. In this case, as described with reference to FIG. 6, a maximum value is varied according to a thickness of a Ta layer. Specifically, a maximum tensile stress is large when the Ta layer is thick. As the Ta layer is removed by polishing, a maximum tensile stress decreases. Accordingly, when a polishing pressure is lowered at the beginning of or immediately after polishing the Ta layer, a maximum tensile stress can be made small.

In the present embodiment, the film thickness measurement sensor (film thickness measurement device) 692 such as an eddy-current sensor or an optical sensor is embedded in the polishing table 34 to measure a variation of a film thickness of a wafer during polishing. Output signals from the film thickness measurement sensor 692 are sent to the controller 691. Based on the output signals from the film thickness measurement sensor 692, the controller 691 controls the cylinder in the swing arm 621 so as to lower a polishing pressure before the Cu film is completely removed or the Ta layer is exposed (see FIG. 8). In this case, a polishing pressure may be lowered when the Cu film is removed. Thus, it is possible to lower a maximum tensile stress caused at the peripheral edges of the Cu interconnections. Further, the controller 691 controls the cylinder so as to increase a polishing pressure immediately before the Ta layer is removed by polishing. A polishing pressure may be increased when the Ta layer is removed.

As described above, in the present embodiment, a polishing pressure is lowered when a tensile stress is expected to increase. Accordingly, a tensile stress can be maintained at a low value throughout the polishing process. As a result, stress corrosion cracking is prevented from being caused in the Cu interconnections.

Although various methods of preventing defects of the metal interconnections have been described above, these methods can be combined with each other. For example, it is possible to combine methods of increasing an actual contact area between the polishing pad and the semiconductor wafer (FIGS. 33 through 44), methods of suppressing a pressing force applied from the polishing pad to the semiconductor wafer (FIGS. 45A through 46B), methods of enhancing the mechanical strength of the insulating film, i.e., the low-k film (FIGS. 47 through 50), and methods of varying a polishing pressure (FIGS. 8 and 51) with each other to prevent defects from being caused in the metal interconnections.

Although certain preferred embodiments of the present invention have been shown and described in detail, it should be understood that various changes and modifications may be made therein without departing from the scope of the appended claims.

### INDUSTRIAL APPLICABILITY

The present invention is suitable for use in a polishing apparatus for polishing and planarizing a substrate such as a semiconductor wafer having an insulating film such as a low-k film and metal interconnections such as copper interconnections embedded in the insulating film.

1-107. (canceled)

108. A polishing apparatus comprising:
a polishing surface;
a top ring for holding a workpiece;
a drive mechanism configured to move said polishing surface and the workpiece held by said top ring relative to each other at a relative speed;
a press mechanism configured to press the workpiece held by said top ring against said polishing surface under a pressing pressure;
a chemical liquid supply mechanism configured to supply a chemical liquid to a surface of the workpiece held by said top ring, the chemical liquid being capable of oxidizing the surface of the workpiece at a reaction rate; and
a controller operable to adjust a concentration or a temperature of the chemical liquid so that the reaction rate is lower than a process rate calculated from the pressing pressure and the relative speed by Preston equation.

109. The polishing apparatus as recited in claim 108, wherein said controller is operable to adjust the concentration or the temperature of the chemical liquid so that a polishing rate of the surface of the workpiece is at least 500 nm/min.

110. The polishing apparatus as recited in claim 108, wherein the chemical liquid includes a first chelating agent capable of producing a first complex which is removable under 3.4 kPa or less by a reaction with the surface of the workpiece.

111. The polishing apparatus as recited in claim 110, wherein the chemical liquid includes a second chelating agent capable of producing a second complex which is a different type from the first complex.

112. The polishing apparatus as recited in claim 111, wherein the second chelating agent has a stability constant of complex which is larger than the first chelating agent with respect to metal,
wherein the second complex has a solubility lower than a solubility of the first complex.

113. The polishing apparatus as recited in claim 111, wherein the second chelating agent has a concentration lower than a concentration of the first chelating agent.

114. The polishing apparatus as recited in claim 111, further comprising a mixer for mixing the first chelating agent and the second chelating agent to prepare the chemical liquid to be supplied to said chemical liquid supply mechanism.

115. The polishing apparatus as recited in claim 114, further comprising a mixing adjustment unit operable to adjust an amount of at least one of the first chelating agent and the second chelating agent.

116. The polishing apparatus as recited in claim 111, wherein said chemical liquid supply mechanism is configured to respectively supply the first chelating agent and the second chelating agent.

117. The polishing apparatus as recited in claim 116, further comprising a mixing adjustment unit operable to adjust an amount of at least one of the first chelating agent and the second chelating agent.

118. The polishing apparatus as recited in claim 108, further comprising a mixer for mixing an oxidizer, a chelating agent, an abrasive dispersion liquid, and pure water to prepare the chemical liquid to be supplied to said chemical liquid supply mechanism.

119. The polishing apparatus as recited in claim 118, further comprising a mixing adjustment unit operable to adjust an amount of at least one of the oxidizer, the chelating agent, the abrasive dispersion liquid, and the pure water.

120. The polishing apparatus as recited in claim 108, wherein said chemical liquid supply mechanism is configured to respectively supply the oxidizer, the chelating agent, the abrasive dispersion liquid, and the pure water.

121. The polishing apparatus as recited in claim 120, further comprising a mixing adjustment unit operable to adjust an amount of at least one of the oxidizer, the chelating agent, the abrasive dispersion liquid, the pure water.

122. The polishing apparatus as recited in claim 108, further comprising a measurement device for measuring a state of the surface of the workpiece.

123. The polishing apparatus as recited in claim 122, wherein said measurement device comprises at least one of an optical monitor for applying light to the workpiece to measure a film thickness of the workpiece, an eddy-current monitor for detecting an eddy current produced in the workpiece to measure a film thickness of the workpiece, a torque detection monitor for detecting rotation torque of said polishing surface to measure a film thickness of the workpiece, and an ultrasonic sensor for applying an ultrasonic wave to the workpiece to measure a film thickness of the workpiece.

124. The polishing apparatus as recited in claim 108, further comprising a liquid adjustment mechanism configured to maintain a predetermined amount of chemical liquid supplied from said chemical liquid supply mechanism during polishing.

125. The polishing apparatus as recited in claim 108, wherein the workpiece has a metal film formed on the surface thereof.

126. The polishing apparatus as recited in claim 108, wherein said drive mechanism includes a rotation mechanism operable to rotate said top ring at a rotational speed,
wherein said controller is operable to control said rotation mechanism so that the rotational speed is 20 min⁻¹ or less.

127. The polishing apparatus as recited in claim 108, wherein said drive mechanism includes a first rotation mechanism operable to rotate said polishing surface at a first rotational speed and a second rotation mechanism operable to rotate said top ring at a second rotational speed,
wherein said controller is operable to control said first rotation mechanism and said second rotation mechanism so that a ratio of the first rotational speed to the second rotational speed is at least 5.

128. The polishing apparatus as recited in claim 108, wherein said drive mechanism includes a first rotation mechanism operable to rotate said polishing surface in a first direction and a second rotation mechanism operable to rotate said top ring in a second direction opposite to the first direction.

129. The polishing apparatus as recited in claim 108, wherein said controller is operable to control said drive mechanism so that a relative speed between said polishing surface and a center of the workpiece is at least 1.7 m/s.

130. The polishing apparatus as recited in claim 108, wherein said polishing surface comprises a polishing pad having concentric grooves formed in an upper surface of said polishing pad.

131. The polishing apparatus as recited in claim 108, wherein said polishing surface comprises a polishing pad having a helical groove formed in an upper surface of said polishing pad.

132. The polishing apparatus as recited in claim 131, wherein an angle between a line perpendicular to a line interconnecting a desired point on said helical groove and a center of said polishing pad and a tangential line of said helical groove at the desired point is 30° or less.

133. A polishing apparatus comprising:
a polishing surface;
a top ring for holding a workpiece;
a drive mechanism configured to move said polishing surface and the workpiece held by said top ring relative to each other at a relative speed;
a press mechanism configured to press the workpiece held by said top ring against said polishing surface under a pressing pressure;
a chemical liquid supply mechanism configured to supply a chemical liquid to a surface of the workpiece held by said top ring, the chemical liquid being capable of oxidizing the surface of the workpiece at a reaction rate; and
a controller operable to adjust at least one of the relative speed and the pressing pressure so that a polishing rate calculated from a product of the relative speed and the pressing pressure by Preston equation is higher than the reaction rate.

134. The polishing apparatus as recited in claim 133, wherein said controller is operable to adjust the pressing pressure to 3.4 kPa or less.

135. The polishing apparatus as recited in claim 133, wherein the chemical liquid includes a first chelating agent capable of producing a first complex which is removable under 3.4 kPa or less by a reaction with the surface of the workpiece.

136. The polishing apparatus as recited in claim 135, wherein the chemical liquid includes a second chelating agent capable of producing a second complex which is a different type from the first complex.

137. The polishing apparatus as recited in claim 136, wherein the second chelating agent has a stability constant of complex which is larger than the first chelating agent with respect to metal,
wherein the second complex has a solubility lower than a solubility of the first complex.

138. The polishing apparatus as recited in claim 136, wherein the second chelating agent has a concentration lower than a concentration of the first chelating agent.

139. The polishing apparatus as recited in claim 136, further comprising a mixer for mixing the first chelating agent and the second chelating agent to prepare the chemical liquid to be supplied to said chemical liquid supply mechanism.

140. The polishing apparatus as recited in claim 139, further comprising a mixing adjustment unit operable to adjust an amount of at least one of the first chelating agent and the second chelating agent.

141. The polishing apparatus as recited in claim 136, wherein said chemical liquid supply mechanism is configured to respectively supply the first chelating agent and the second chelating agent.

142. The polishing apparatus as recited in claim 141, further comprising a mixing adjustment unit operable to adjust an amount of at least one of the first chelating agent and the second chelating agent.

143. The polishing apparatus as recited in claim 133, further comprising a mixer for mixing an oxidizer, a chelating agent, an abrasive dispersion liquid, and pure water to prepare the chemical liquid to be supplied to said chemical liquid supply mechanism.

144. The polishing apparatus as recited in claim 143, further comprising a mixing adjustment unit operable to adjust an amount of at least one of the oxidizer, the chelating agent, the abrasive dispersion liquid, and the pure water.

145. The polishing apparatus as recited in claim 133, wherein said chemical liquid supply mechanism is configured to respectively supply the oxidizer, the chelating agent, the abrasive dispersion liquid, and the pure water.

146. The polishing apparatus as recited in claim 145, further comprising a mixing adjustment unit operable to adjust an amount of at least one of the oxidizer, the chelating agent, the abrasive dispersion liquid, the pure water.

147. The polishing apparatus as recited in claim 133, further comprising a measurement device for measuring a state of the surface of the workpiece.

148. The polishing apparatus as recited in claim 147, wherein said measurement device comprises at least one of an optical monitor for applying light to the workpiece to measure a film thickness of the workpiece, an eddy-current monitor for detecting an eddy current produced in the workpiece to measure a film thickness of the workpiece, a torque detection monitor for detecting rotation torque of said polishing surface to measure a film thickness of the workpiece, and an ultrasonic sensor for applying an ultrasonic wave to the workpiece to measure a film thickness of the workpiece.

149. The polishing apparatus as recited in claim 133, further comprising a liquid adjustment mechanism configured to maintain a predetermined amount of chemical liquid supplied from said chemical liquid supply mechanism during polishing.

150. The polishing apparatus as recited in claim 133, wherein the workpiece has a metal film formed on the surface thereof.

151. The polishing apparatus as recited in claim 133, wherein said drive mechanism includes a rotation mechanism operable to rotate said top ring at a rotational speed,
wherein said controller is operable to control said rotation mechanism so that the rotational speed is 20 min⁻¹ or less.

152. The polishing apparatus as recited in claim 133, wherein said drive mechanism includes a first rotation mechanism operable to rotate said polishing surface at a first rotational speed and a second rotation mechanism operable to rotate said top ring at a second rotational speed,
wherein said controller is operable to control said first rotation mechanism and said second rotation mechanism so that a ratio of the first rotational speed to the second rotational speed is at least 5.

153. The polishing apparatus as recited in claim 133, wherein said drive mechanism includes a first rotation mechanism operable to rotate said polishing surface in a first direction and a second rotation mechanism operable to rotate said top ring in a second direction opposite to the first direction.

154. The polishing apparatus as recited in claim 133, wherein said controller is operable to control said drive mechanism so that a relative speed between said polishing surface and a center of the workpiece is at least 1.7 m/s.

155. The polishing apparatus as recited in claim 133, wherein said polishing surface comprises a polishing pad having concentric grooves formed in an upper surface of said polishing pad.

156. The polishing apparatus as recited in claim 133, wherein said polishing surface comprises a polishing pad having a helical groove formed in an upper surface of said polishing pad.

157. The polishing apparatus as recited in claim 156, wherein an angle between a line perpendicular to a line interconnecting a desired point on said helical groove and a center of said polishing pad and a tangential line of said helical groove at the desired point is 30° or less.

158. A polishing method comprising:
moving a polishing surface and a workpiece relative to each other at a relative speed while pressing the workpiece against the polishing surface under a pressing pressure;
supplying a chemical liquid to a surface of the workpiece, the chemical liquid being capable of oxidizing the surface of the workpiece at a reaction rate; and
adjusting a concentration or a temperature of the chemical liquid so that the reaction rate is lower than a process rate calculated from the pressing pressure and the relative speed by Preston equation.

159. The polishing method as recited in claim 158, wherein said adjusting operation comprises adjusting the concentration or the temperature of the chemical liquid so that a polishing rate of the surface of the workpiece is at least 500 nm/min.

160. The polishing method as recited in claim 158, wherein the chemical liquid includes a first chelating agent capable of producing a first complex which is removable under 3.4 kPa or less by a reaction with the surface of the workpiece.

161. The polishing method as recited in claim 160, wherein the chemical liquid includes a second chelating agent capable of producing a second complex which is a different type from the first complex.

162. The polishing method as recited in claim 161, wherein the second chelating agent has a stability constant of complex which is larger than the first chelating agent with respect to metal,
wherein the second complex has a solubility lower than a solubility of the first complex.

163. The polishing method as recited in claim 161, wherein the second chelating agent has a concentration lower than a concentration of the first chelating agent.

164. The polishing method as recited in claim 161, wherein said supplying operation comprises mixing the first chelating agent and the second chelating agent to prepare the chemical liquid to be supplied.

165. The polishing method as recited in claim 164, wherein said adjusting operation comprises adjusting an amount of at least one of the first chelating agent and the second chelating agent.

166. The polishing method as recited in claim 161, wherein said supplying operation comprises respectively supplying the first chelating agent and the second chelating agent.

167. The polishing method as recited in claim 166, wherein said supplying operation comprises adjusting an amount of at least one of the first chelating agent and the second chelating agent.

168. The polishing method as recited in claim 158, wherein said supplying operation comprises mixing an oxidizer, a chelating agent, an abrasive dispersion liquid, and pure water to prepare the chemical liquid to be supplied.

169. The polishing method as recited in claim 168, wherein said supplying operation further comprises adjusting an amount of at least one of the oxidizer, the chelating agent, the abrasive dispersion liquid, and the pure water.

170. The polishing method as recited in claim 158, wherein said supplying operation comprises respectively supplying the oxidizer, the chelating agent, the abrasive dispersion liquid, and the pure water.

171. The polishing method as recited in claim 170, wherein said supplying operation comprises adjusting an amount of at least one of the oxidizer, the chelating agent, the abrasive dispersion liquid, the pure water.

172. The polishing method as recited in claim 158, further comprising measuring a state of the surface of the workpiece.

173. The polishing method as recited in claim 158, further comprising maintaining a predetermined amount of chemical liquid supplied during polishing.

174. The polishing method as recited in claim 158, wherein the workpiece has a metal film formed on the surface thereof.

175. The polishing method as recited in claim 158, wherein said moving operation comprises rotating the workpiece at a rotational speed of 20 min⁻¹ or less.

176. The polishing method as recited in claim 158, wherein said moving operation comprises rotating the polishing surface and the workpiece, respectively, so that a ratio of a rotational speed of the polishing surface to a rotational speed of the workpiece is at least 5.

177. The polishing method as recited in claim 158, wherein said moving operation comprises rotating the polishing surface and the workpiece in opposite directions, respectively.

178. The polishing method as recited in claim 158, wherein said moving operation comprises moving the polishing surface and the workpiece relative to each other so that a relative speed between the polishing surface and a center of the workpiece is at least 1.7 m/s.

179. A polishing method comprising:
moving a polishing surface and a workpiece relative to each other at a relative speed while pressing the workpiece against the polishing surface under a pressing pressure;
supplying a chemical liquid to a surface of the workpiece, the chemical liquid being capable of oxidizing the surface of the workpiece at a reaction rate; and
adjusting at least one of the relative speed and the pressing pressure so that a polishing rate calculated from a product of the relative speed and the pressing pressure by Preston equation is higher than the reaction rate.

180. The polishing method as recited in claim 179, wherein said adjusting operation comprises adjusting the pressing pressure to 3.4 kPa or less.

181. The polishing method as recited in claim 179, wherein the chemical liquid includes a first chelating agent capable of producing a first complex which is removable under 3.4 kPa or less by a reaction with the surface of the workpiece.

182. The polishing method as recited in claim 181, wherein the chemical liquid includes a second chelating agent capable of producing a second complex which is a different type from the first complex.

183. The polishing method as recited in claim 182, wherein the second chelating agent has a stability constant of complex which is larger than the first chelating agent with respect to metal,
wherein the second complex has a solubility lower than a solubility of the first complex.

184. The polishing method as recited in claim 182, wherein the second chelating agent has a concentration lower than a concentration of the first chelating agent.

185. The polishing method as recited in claim 182, wherein said supplying operation comprises mixing the first chelating agent and the second chelating agent to prepare the chemical liquid to be supplied.

186. The polishing method as recited in claim 185, wherein said adjusting operation comprises adjusting an amount of at least one of the first chelating agent and the second chelating agent.

187. The polishing method as recited in claim 182, wherein said supplying operation comprises respectively supplying the first chelating agent and the second chelating agent.

188. The polishing method as recited in claim 187, wherein said supplying operation comprises adjusting an amount of at least one of the first chelating agent and the second chelating agent.

189. The polishing method as recited in claim 179, wherein said supplying operation comprises mixing an oxidizer, a chelating agent, an abrasive dispersion liquid, and pure water to prepare the chemical liquid to be supplied.

190. The polishing method as recited in claim 189, wherein said supplying operation further comprises adjusting an amount of at least one of the oxidizer, the chelating agent, the abrasive dispersion liquid, and the pure water.

191. The polishing method as recited in claim 179, wherein said supplying operation comprises respectively supplying the oxidizer, the chelating agent, the abrasive dispersion liquid, and the pure water.

192. The polishing method as recited in claim 191, wherein said supplying operation comprises adjusting an amount of at least one of the oxidizer, the chelating agent, the abrasive dispersion liquid, the pure water.

193. The polishing method as recited in claim 179, further comprising measuring a state of the surface of the workpiece.

194. The polishing method as recited in claim 179, further comprising maintaining a predetermined amount of chemical liquid supplied during polishing.

195. The polishing method as recited in claim 179, wherein the workpiece has a metal film formed on the surface thereof.

196. The polishing method as recited in claim 179, wherein said moving operation comprises rotating the workpiece at a rotational speed of 20 min⁻¹ or less.

197. The polishing method as recited in claim 179, wherein said moving operation comprises rotating the polishing surface and the workpiece, respectively, so that a ratio of a rotational speed of the polishing surface to a rotational speed of the workpiece is at least 5.

198. The polishing method as recited in claim 179, wherein said moving operation comprises rotating the polishing surface and the workpiece in opposite directions, respectively.

199. The polishing method as recited in claim 179, wherein said moving operation comprises moving the polishing surface and the workpiece relative to each other so that a relative speed between the polishing surface and a center of the workpiece is at least 1.7 m/s.
